(19) United States
(12) Patent Application Publication
(10) Pub. No.: US 2013/0338954 A1
(43) Pub. Date: Dec. 19, 2013

(54) ALTERNATING-CURRENT ELECTRICAL QUANTITY MEASURING APPARATUS AND ALTERNATING-CURRENT ELECTRICAL QUANTITY MEASURING METHOD

(71) Applicant: Kempei Seki, Chiyoda-ku (JP)

(72) Inventor: Kempei Seki, Chiyoda-ku (JP)

(73) Assignee: Mitsubishi Electric Corporation, Chiyoda-ku (JP)

(21) Appl. No.: 14/002,479

(22) PCT Filed: Mar. 3, 2011
(86) PCT No.: PCT/JP2011/054899

§ 371 Date: Aug. 30, 2013

(51) Int. Cl. G01R 23/02

(52) U.S. Cl. CPC G01R 23/02
USPC 702/75

(57) ABSTRACT

An alternating-current electrical quantity measuring apparatus calculates, as a frequency coefficient, a value obtained by normalizing, with a differential voltage instantaneous value at intermediate time, a mean value of a sum of differential voltage instantaneous values at times other than the intermediate time among differential voltage instantaneous value data at three points each representing an inter-point distance between voltage instantaneous value data at adjacent two points in voltage instantaneous value data at continuous at least four points obtained by sampling an alternating voltage set as a measurement target at a sampling frequency twice or more as high as a frequency of the alternating voltage.

### FIELD

The present invention relates to an alternating-current electrical quantity measuring apparatus and alternating-current electrical quantity measuring method.

### BACKGROUND

In recent years, as a power flow in a power system becomes more and more complicated, supply of electric power with higher reliability and quality is demanded. In particular, necessity of performance improvement of an alternating-current electrical quantity measuring apparatus that measures an electrical quantity (an alternating-current electrical quantity) of the power system is becoming higher.

As the alternating-current electrical quantity measuring apparatus of this type, for example, there have been apparatuses disclosed in Patent Literatures 1 and 2 described below. Patent Literature 1 (a protection control measuring system) and Patent Literature 2 (a wide area protection control measuring system) disclose a method of calculating a frequency of an actual system using a change component (a differential component) of a phase angle as a change from a rated frequency (50 Hz or 60 Hz).

These literatures disclose the following formulas as calculation formulas for calculating the frequency of the actual system. However, these calculation formulas are also calculation formulas presented by Non-Patent Literature 1 described below.

2πΔf=dφ/dt

f(Hz)=60+Δf

Patent Literatures 3 and 4 described below are the earlier filed patent inventions by the inventor of this application. Contents of these inventions are explained below as appropriate.

### CITATION LIST

### Patent Literature

Patent Literature 1: Japanese Patent Application Laid-open No. 2009-65766
Patent Literature 2: Japanese Patent Application Laid-open No. 2009-71637
Patent Literature 3: Japanese Patent No. 4038484
Patent Literature 4: Japanese Patent No. 4480647

### Non Patent Literature

Non Patent Literature 1: “IEEE Standard for Synchrophasors for Power Systems” page 30, IEEE Std C37. 118-2005.

### SUMMARY

### Technical Problem

As explained above, the method disclosed in Patent Literatures 1 and 2 and Non-Patent Literature 1 is a method of calculating a change component of a phase angle using a differential calculation. However, a change in a frequency instantaneous value of the actual system is frequent and complicated and the differential calculation is extremely unstable. Therefore, for example, concerning frequency measurement, there is a problem in that sufficient calculation accuracy is not obtained.

The method has a problem in that, because the calculation is performed using the rated frequency (50 Hz or 60 Hz) as an initial value, when a measurement target is operating at a frequency deviating from the system rated frequency at the start of the calculation, a measurement error occurs and, when a degree of the deviation from the system rated frequency is large, the measurement error is extremely large.

The present invention has been devised in view of the above and it is an object of the present invention to provide an alternating-current electrical quantity measuring apparatus and an alternating-current electrical quantity measuring method that enable highly accurate measurement of an alternating-current electrical quantity even when a measurement target is operating at a frequency deviating from a system rated frequency.

### Solution to Problem

In order to solve the aforementioned problem, an alternating-current electrical quantity measuring apparatus according to one aspect of the present invention is configured to include: a frequency-coefficient calculating unit configured to calculate, as a frequency coefficient, a value obtained by normalizing, with a differential voltage instantaneous value at intermediate time, a mean value of a sums of differential voltage instantaneous values at times other than the intermediate time among differential voltage instantaneous value data at three points each representing an inter-point distance between voltage instantaneous value data at adjacent two points in voltage instantaneous value data at continuous at least four points obtained by sampling an alternating voltage set as a measurement target at a sampling frequency twice or more as high as a frequency of the alternating voltage; and a frequency calculating unit configured to calculate a frequency of the alternating voltage using the sampling frequency and the frequency coefficient.

### Advantageous Effects of Invention

According to the present invention, there is an effect that highly accurate measurement is enabled even when a measurement target is operating at a frequency deviating from a system rated frequency.

### BRIEF DESCRIPTION OF DRAWINGS

FIG. 1 is a diagram of a gauge differential voltage group (with a direct-current offset) on a complex plane.

FIG. 2 is a diagram of a gauge voltage group (with a direct-current offset) on a complex plane.

FIG. 3 is a diagram of a gauge voltage group (without a direct-current offset) on a complex plane.

FIG. 4 is a diagram of a gauge power group on a complex plane.

FIG. 5 is a diagram of a gauge differential power group on a complex plane.

FIG. 6 is a diagram of a gauge dual voltage group on a complex plane.

FIG. 7 is a diagram of a gauge dual differential voltage group on a complex plane.

FIG. 8 is a diagram of a synchronized phasor group on a complex plane.

FIG. 9 is a diagram of a differential synchronized phasor group on a complex plane.

FIG. 10 is a diagram of a functional configuration of a power measuring apparatus according to a first embodiment.

FIG. 11 is a flowchart for explaining a flow of processing in the power measuring apparatus according to the first embodiment.

FIG. 12 is a diagram of a functional configuration of a distance protection relay according to a second embodiment.

FIG. 13 is a flowchart for explaining a flow of processing in the distance protection relay according to the second embodiment.

FIG. 14 is a diagram of a functional configuration of an out-of-step protection relay according to a third embodiment.

FIG. 15 is a flowchart for explaining a flow of processing in the out-of-step protection relay according to the third embodiment.

FIG. 16 is a diagram of a functional configuration of a time-synchronized-phasor measuring apparatus according to a fourth embodiment.

FIG. 17 is a flowchart for explaining a flow of processing in the time-synchronized-phasor measuring apparatus according to the fourth embodiment.

FIG. 18 is a diagram of a functional configuration of a space-synchronized-phasor measuring apparatus according to a fifth embodiment.

FIG. 19 is a flowchart for explaining a flow of processing in the space-synchronized-phasor measuring apparatus according to the fifth embodiment.

FIG. 20 is a diagram of a functional configuration of a power transmission line parameter measuring system according to a sixth embodiment.

FIG. 21 is a flowchart for explaining a flow of processing in the power transmission line parameter measuring system according to the sixth embodiment.

FIG. 22 is a diagram of a functional configuration of an automatic synchronizer according to a seventh embodiment.

FIG. 23 is a flowchart for explaining a flow of processing in the automatic synchronizer according to the seventh embodiment.

FIG. 24 is a graph of a frequency coefficient calculated using parameters of a case 1.

FIG. 25 is a graph of a rotation phase angle calculated using the parameters of the case 1.

FIG. 26 is a gain graph of frequency measurement calculated using the parameters of the case 1.

FIG. 27 is a graph of a frequency coefficient calculated using parameters of a case 2.

FIG. 28 is a graph of an instantaneous voltage, a direct-current offset, a gauge voltage, and a voltage amplitude calculated using the parameters of the case 2.

FIG. 29 is a graph of a rotation phase angle and a measurement frequency calculated using the parameters of the case 2.

FIG. 30 is a graph of a gauge active synchronized phasor and a gauge reactive synchronized phasor calculated using the parameters of the case 2.

FIG. 31 is a graph of a synchronized phasor of this application calculated using the parameters of the case 2 compared with an instantaneous value synchronized phasor in the past.

FIG. 32 is a graph of a time synchronized phasor calculated using the parameters of the case 2.

FIG. 33 is a graph of a frequency coefficient calculated using parameters of a case 3.

FIG. 34 is a graph of instantaneous voltage, gauge differential voltage, and voltage amplitude measurement results calculated using the parameters of the case 3.

FIG. 35 is a graph of a synchronized phasor of a cosine method, a synchronized phasor of a tangent method, and a symmetry breaking discrimination flag calculated using the parameters of the case 3.

FIG. 36 is a graph of a synchronized phasor calculated using the parameters of the case 3.

FIG. 37 is a graph of a voltage amplitude measurement result calculated using the parameters of the case 3.

FIG. 38 is a graph of a time synchronized phasor calculated using the parameters of the case 3.

FIG. 39 is a graph of a frequency coefficient calculated using parameters of a case 4.

FIG. 40 is a graph of an instantaneous voltage, a gauge differential voltage, and a voltage amplitude calculated using the parameters of the case 4.

FIG. 41 is a graph of a synchronized phasor of a cosine method, a synchronized phasor of a tangent method, and a symmetry breaking discrimination flag calculated using the parameters of the case 4.

FIG. 42 is a graph of a synchronized phasor calculated using the parameters of the case 4.

FIG. 43 is a graph of a time synchronized phasor calculated using the parameters of the case 4.

FIG. 44 is a graph of a frequency coefficient calculated using parameters of a case 5.

FIG. 45 is a graph of an instantaneous voltage, a gauge differential voltage, and a voltage amplitude calculated using the parameters of the case 5.

FIG. 46 is a graph of a synchronized phasor of a cosine method, a synchronized phasor of a tangent method, and a symmetry breaking discrimination flag calculated using the parameters of the case 5.

FIG. 47 is a graph of a synchronized phasor calculated using the parameters of the case 5.

FIG. 48 is a graph of a rotation phase angle calculated using the parameters of the case 5.

FIG. 49 is a graph of an actual frequency calculated using the parameters of the case 5.

FIG. 50 is a graph of a time synchronized phasor calculated using the parameters of the case 5.

FIG. 51 is an automatic synchronizer operation graph during execution of a simulation performed using parameters of a case 6.

### DESCRIPTION OF EMBODIMENTS

An alternating-current electrical quantity measuring apparatus and an alternating-current electrical quantity measuring method according to an embodiment of the present invention are explained below with reference to the accompanying drawings. The present invention is not limited by the embodiment explained below.

### GIST OF THE PRESENT INVENTION

The present invention is an invention concerning an alternating-current electrical quantity measuring apparatus, which is a basic technology of a smart grid (a smart power network). The greatest characteristic of the invention is that the structure of an alternating voltage and current is modeled using a symmetrical group. In the conventional theory, analyses are separately performed in a frequency domain and a time domain. However, in the present invention, analyses of frequency dependent amounts (a rotation phase angle, an amplitude, a voltage-current phase angle, and a phase angle difference) and time dependent amounts (voltage and current instantaneous values and a synchronized phasor) are simultaneously performed using a vector symmetry group on a complex plane. The inventor of this application already proposed an algorism of synchronized phasor calculation by an instantaneous value synchronized phasor measuring method. The algorithm has been patented in Japan and the United States (Patent Literature 3). However, in the method according to Patent Literature 3 (the instantaneous value synchronized phasor measuring method), an inverted region (a phase angle changes counterclockwise or clockwise between 0 and π) is present in a local absolute phase angle. In the inverted region, a phase angle difference (a time synchronized phasor and a space synchronized phasor) cannot be decided. It is necessary to latch a phase angle difference measured at the preceding step.

On the other hand, the inventor of this application found the symmetry of an alternating voltage/current after the application of Patent Literature 3 and introduced the group theory of the symmetry theory into an alternating-current system (there are a plurality of unpublished prior applications). The present invention introduces the group theory of the symmetry theory into synchronized phasor measurement. Consequently, in the synchronized phasor measuring method according to the present invention, because the rotation phase angle always changes counterclockwise between −π and π, it is unnecessary to latch the phase angle difference in the inverted region. Therefore, it is possible to decide an accurate angle difference. The method is effective for increasing the speed of protection control processing.

The method according to the present invention is considered to be applicable to calculations of various alternating-current electrical quantities such as frequency coefficient measurement, rotation phase angle measurement, frequency measurement, amplitude measurement, direct-current offset measurement, synchronized phasor measurement, a time synchronized phasor, and a space synchronized phasor.

### MEANINGS OF TERMS

In explaining the alternating-current electrical quantity measuring apparatus and the alternating-current electrical quantity measuring method according to the embodiment, first, terms used in the specification of this application are explained.

Complex number: A number represented in a form of a+jb using real numbers a and b and an imaginary unit j. In the electrical engineering, because i is a current sign, the imaginary unit is represented by j=√(−1). In this application, a rotation vector is represented using the complex number.

Complex plane: A plane having the complex number as a point on a two-dimensional plane and representing the complex number using rectangular coordinates with a real part (Re) set on the abscissa and an imaginary part (Im) set on the ordinate.

Rotation vector: A vector that rotates counterclockwise on a complex plane concerning an electrical quantity (a voltage or an electric current) of a power system. A real part of the rotation vector is an instantaneous value.

Differential rotation vector: A difference vector between rotation vectors at two points before and after one cycle of a sampling frequency. A real part of the differential rotation vector is a difference between instantaneous values at the two points before and after one cycle of the sampling frequency.

Sampling frequency: According to the sampling theorem, a sampling frequency is limited to be twice or more as high as a real frequency. In the case of Japan, 30-degree sampling is often used for a monitoring protection apparatus of the power system. In this case, the sampling frequency is 600 Hz in a 50 Hz system and is 720 Hz in a 60 Hz system. In this application, it is recommended to adopt a sampling frequency four times as high as a rated frequency (200 Hz for the 50 Hz system and 240 Hz for the 60 Hz system). In a smart meter applied to the smart grid, a great advantage is obtained by using the sampling frequency and a related measurement formula proposed for a protection control apparatus of the power system.

System frequency: The system frequency basically means a rated frequency in a power system. There are two types of 50 Hz and 60 Hz.

Real frequency: A real frequency in the power system. The real frequency slightly fluctuates in the vicinity of the rated frequency even if the power system is stable. This application is adapted to all half frequencies of the sampling frequency. For example, when a generator of the power system is started, a frequency of the generator rises from 0 Hz to the rated frequency. It is possible to cause the frequency of the generator to follow the measuring method of this application at high speed and high accuracy.

Rotation phase angle: A phase angle of rotation of a voltage rotation vector (hereinafter simply referred to as “voltage vector”) or a current rotation vector (hereinafter simply referred to as “current vector”) on a complex plane in one cycle of the sampling frequency. The rotation phase angle is a frequency dependent amount. Therefore, the rotation phase angle is considered to have no large change among several sampling points. If the rotation phase angle has a large change among several sampling points, it is determined that a sudden change (symmetry breaking) has occurred. A symmetry index is used for the determination.

Breaking of symmetry: When an input waveform is a pure sine wave, the input waveform has symmetry. However, the symmetry of the input waveform is broken by an amplitude sudden change, a phase sudden change, or a frequency sudden change of the input waveform. To detect the breaking of symmetry, this application proposes several symmetry indexes. By providing a set point for the symmetry indexes, the breaking of symmetry is not discriminated for a small measurement error and additive Gaussian noise. When the symmetry is broken, the input waveform is not a pure alternating-current waveform any more. Measurement is considered to be impossible and a value already measured is latched. When the symmetry is present, to reduce the influence of the small measurement error and the additive Gaussian noise, it is desirable to increase the number of symmetry groups used for a calculation and improve measurement accuracy of a calculation result through moving average processing.

Gauge voltage group: A symmetry group formed by three voltage vectors continuous in time series. The same concept of the symmetry group can be defined concerning an electric current and electric power (active power and reactive power) other than the voltage.

Gauge voltage: A voltage invariable calculated from the gauge voltage group.

Gauge differential voltage group: A symmetry group formed by three differential voltage vectors continuous in time series.

Gauge differential voltage: A differential voltage invariable calculated using the gauge differential voltage group.

Frequency coefficient: A frequency measurement formula proposed by this application for the first time. The frequency coefficient is a parameter calculated using three members of the gauge differential voltage group. A value of the frequency coefficient is a cosine value of the rotation phase angle. Because a differential voltage is used, a measurement result is not affected by a direct-current offset of the input waveform.

Direct-current offset: A direct-current component of the input waveform.

Gauge dual voltage group: A symmetry group formed by continuous three voltage vectors of a terminal 1 and continuous two voltage vectors of a terminal 2. The same concept of the symmetry group can be defined concerning an electric current.

Gauge dual active voltage group: A symmetry group formed by former two voltage vectors of the terminal 1 and continuous two voltage vectors of the terminal 2 of the gauge dual voltage group.

Gauge dual reactive voltage group: A symmetry group formed by latter two voltage vectors of the terminal 1 and continuous two voltage vectors of the terminal 2 of the gauge dual voltage group.

Gauge dual active voltage: An invariable calculated using the gauge dual active voltage group.

Gauge dual reactive voltage: An invariable calculated using the gauge dual reactive voltage group.

Gauge dual differential voltage group: A symmetry group formed by continuous three differential voltage vectors of the terminal 1 and continuous two differential voltage vectors of the terminal 2.

Gauge dual differential active voltage group: A symmetry group formed by former two differential voltage vectors of the terminal 1 and continuous two differential voltage vectors of the terminal 2 of the gauge dual differential voltage group.

Gauge dual differential reactive voltage group: A symmetry group formed by latter two differential voltage vectors of the terminal 1 and continuous two differential voltage vectors of the terminal 2 of the gauge dual differential voltage group.

Gauge dual differential active voltage: An invariable calculated using the gauge dual differential active voltage group.

Gauge dual differential reactive voltage: An invariable calculated using the gauge dual differential reactive voltage group.

Gauge power group: A symmetry group formed by continuous three voltage vectors and continuous two current vectors.

Gauge active power group: A symmetry group formed by former two voltage vectors and continuous two current vectors of the gauge power group.

Gauge reactive power group: A symmetry group formed by latter two voltage vectors and continuous two current vectors of the gauge power group.

Gauge active power: An invariable calculated using the gauge active power group.

Gauge reactive power: An invariable calculated using the gauge reactive power group.

Gauge differential power group: A symmetry group formed by continuous three differential voltage vectors and continuous two differential current vectors.

Gauge differential active power group: A symmetry group formed by former two differential voltage vectors and continuous two differential current vectors of the gauge differential power group.

Gauge differential reactive power group: A symmetry group formed by latter two differential voltage vectors and continuous two differential current vectors of the gauge differential power group.

Gauge differential active power: An invariable calculated using the gauge differential active power group.

Gauge differential reactive power: An invariable calculated using the gauge differential reactive power group.

Synchronized phasor: An absolute phase angle of a voltage vector or a current vector rotating counterclockwise on a complex plane in a range of −180 degrees to +180 degrees at rotating speed corresponding to a real frequency is defined as synchronized phasor. Phasor often indicates a display method for representing a sine signal (a cosine signal) as a complex number. However, in this specification, phasor means an absolute phase angle of rotation. The synchronized phasor has two characteristics. A first characteristic is that the size of the synchronized phasor is in a range of −180 degrees to +180 degrees. A second characteristic is that the synchronized phasor increases unidirectionally in a direction from −180 degrees to +180 degrees (counterclockwise). As the synchronized phasor, there are a voltage synchronized phasor and a current synchronized phasor. The synchronized phasor is a time dependent amount. The synchronized phasor changes at each sampling point.

Voltage absolute phase angle: In this application, the voltage absolute phase angle means the voltage synchronized phasor.

Current absolute phase angle: In this application, the current absolute phase angle means the current synchronized phasor.

Gauge synchronized phasor group: A symmetry group formed by three voltage vectors and two fixed unit vectors on a complex plane.

Gauge active synchronized phasor: A calculation result of a calculation formula in which a member of the gauge synchronized phasor group defined in this application is used.

Gauge reactive synchronized phasor: A calculation result of a calculation formula in which another member of the gauge synchronized phasor group defined in this application is used.

Gauge differential synchronized phasor group: A symmetry group formed by three differential voltage vectors and two fixed difference unit vectors.

Gauge differential active synchronized phasor: A calculation result of a calculation formula in which a member of a gauge differential synchronized phasor group defined in this application is used.

Gauge differential reactive synchronized phasor: A calculation result of a calculation formula in which another member of the gauge differential synchronized phasor group defined in this application is used.

Time synchronized phasor: A difference between a synchronized phasor at the present point and a synchronized phasor at designated time (e.g., a point one cycle before the rated frequency of the power system). Like the synchronized phasor, a fluctuation range is −180 degrees to +180 degrees. The time synchronized phasor is a frequency dependent amount. When the real frequency does not fluctuate, the time synchronized phasor is a fixed value and does not fluctuate either. Like the synchronized phasor, as the time synchronized phasor, there are a voltage time synchronized phasor and a current time synchronized phasor.

Space synchronized phasor: A difference between a synchronized phasor at an own end and a synchronized phasor at the other end. A fluctuation range is −180 degrees to +180 degrees. The time synchronized phasor is a frequency dependent amount. When real frequencies at both the ends are the same and do not simultaneously fluctuate, the space synchronized phasor is a fixed value and does not fluctuate either. Like the synchronized phasor, as the space synchronized phasor, there are a voltage space synchronized phasor and a current space synchronized phasor.

Fixed unit vector group: A plurality of unit vectors (an amplitude is 1) on a complex plane set to calculate the synchronized phasor.

Voltage-current phase angle: A phase angle between a voltage vector and a current vector. Voltage THD index: An index representing power quality using total harmonic distortion (THD) of a voltage.

Current THD index: An index representing power quality using total harmonic distortion (THD) of an electric current.

Automatic synchronizer: An apparatus that operates separated systems to link with each other under fixed conditions (a frequency difference, a voltage amplitude difference, and a phase difference are set to values equal to or smaller than fixed values). In a seventh embodiment explained below, a new automatic synchronizer is proposed.

Islanding detecting apparatus: When a circuit breaker is opened because of an accident or the like in a system to which a distributed power supply is linked, the separated system supplies electric power to consumers through only the distributed power supply. This state is referred to as independent operation. It is necessary to quickly detect the independent operation and surely parallel off the distributed power supply. The islanding detecting apparatus is presented in an eight embodiment explained below.

Distance protection relay: The distance protection relay measures the impedance of a power transmission line, converts a distance to a failure point, and realizes failure protection for the power transmission line.

Out-of-step protection relay: An apparatus that detects out-of-step of a power system.

An instantaneous value synchronized phasor measuring method: A synchronized phasor calculating method presented in Patent Literature 3. A value of an inverse cosine of a value calculated with a present point voltage instantaneous value estimated value, which is estimated by the method of least squares, set as a numerator and a present point voltage amplitude, which is estimated by the method of least squares, set as a denominator is the synchronized phasor. Because a value of the inverse cosine is always plus, a range of change of the synchronized phasor is 0 to π. As a changing direction of the synchronized phasor, there are two kinds of changing directions, i.e., a counterclockwise direction and a clockwise direction.

Group synchronized phasor measuring method: A calculation method for the synchronized phasor presented in this application.

The alternating-current electrical quantity measuring apparatus and the alternating-current electrical quantity measuring method according to this embodiment are explained. In the explanation, first, a concept (an algorithm) of the alternating-current electrical quantity measuring method forming the gist of this embodiment is explained. Thereafter, the configuration and the operation of the alternating-current electrical quantity measuring apparatus according to this embodiment are explained. In the following explanation, among small letter notations of the alphabets, those in parentheses (e.g., “v(t)”) represent vectors and those not in parentheses (e.g., “v₂”) represent instantaneous values. Large letter notations of the alphabets (e.g., “V_{g}”) represent effective values or amplitude values.

(Gauge Differential Voltage Group)

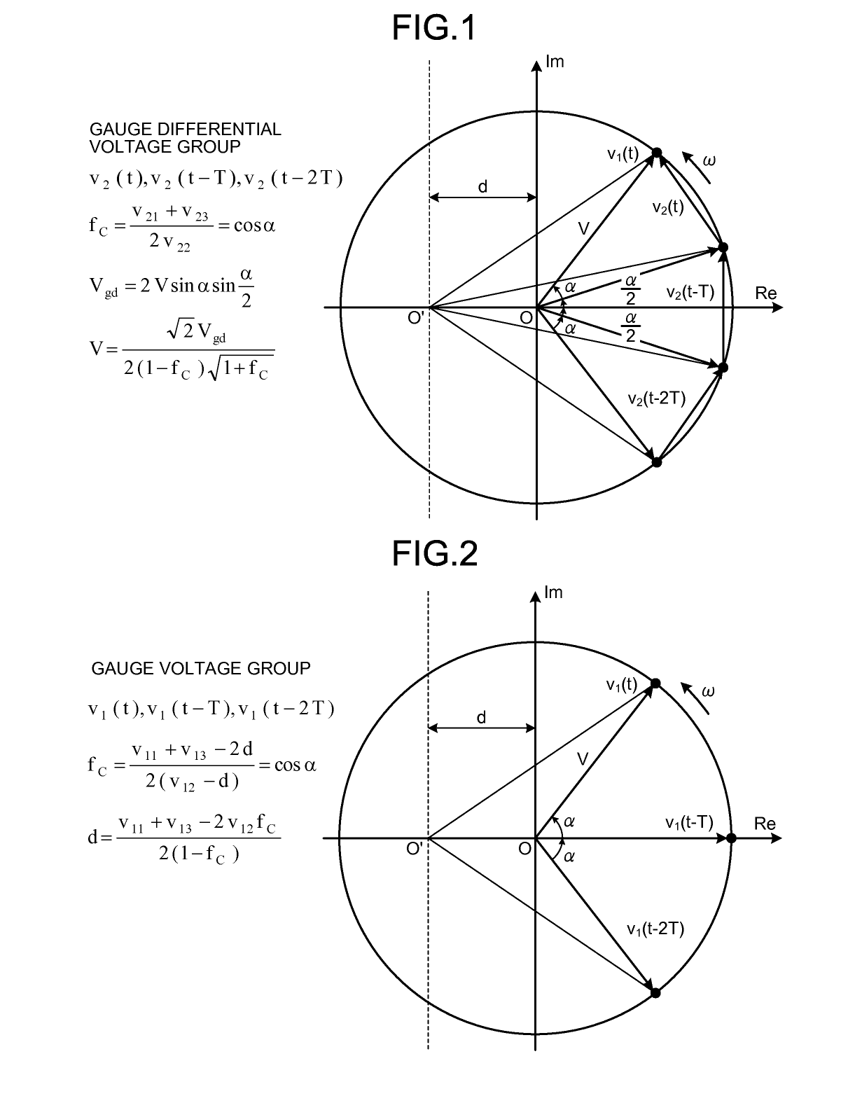

FIG. 1 is a diagram of a gauge differential voltage group on a complex plane. In FIG. 1, three differential voltage vectors v₂(t), v₂(t−T), and V₂(t−2T) rotating counterclockwise at a real frequency on the complex plane are examined. In FIG. 1, d represents a direct-current offset. Because the direct-current offset is included in a voltage instantaneous value, an imaginary number axis Im of the complex plane is moved from O′ to O. The three differential voltage vectors can be represented by the following formula:

$$\{ \begin{matrix}{v}_{2} ( t ) = V {e}^{j ( ω t + \frac{3 α}{2} )} - V {e}^{j ( ω t + \frac{α}{2} )} \\ {v}_{2} ( t - T ) = V {e}^{j ( ω t + \frac{α}{2} )} - V {e}^{j ( ω t - \frac{α}{2} )} \\ {v}_{2} ( t - 2 T ) = V {e}^{j ( ω t - \frac{α}{2} )} - V {e}^{j ( ω t - \frac{3 α}{2} )}\end{matrix} \qquad ( 1 )$$

In the formula, V represents the amplitude of an alternating-current component of an instantaneous voltage and ω represents a rotation angular velocity and is represented by the following formula:

ω=2πf (2)

In the formula, f represents a real frequency. Further, T in Formula (1) is a sampling one period time and represented by the following formula:

$$T = \frac{1}{{f}_{S}} \qquad ( 3 )$$

In the formula, fₛ represents a sampling frequency. Further, α in Formula (1) represents a phase angle of a voltage vector rotated on the complex plane in the T time.

In FIG. 1, it is seen that the three differential voltage vectors have symmetry with respect to the differential voltage vector in the middle. The three differential voltage vectors form a gauge differential voltage group. Because time t can take an arbitrary value, the symmetry of Formula (1) is always retained. A formula for calculating a frequency coefficient is disclosed using the gauge differential voltage group.

(Frequency Coefficient)

In FIG. 1, the first member v₂(t) and the last member v₂(t−2T) of the gauge differential voltage group have symmetry with respect to the intermediate member v₂(t−T). Therefore, the following calculation formula is proposed. A calculation result of the calculation formula is defined as a frequency coefficient.

$${f}_{C} = \frac{{v}_{21} + {v}_{23}}{2 {v}_{22}} \qquad ( 4 )$$

In the formula, v₂₁, v₂₂, and v₂₃ respectively represent real parts or imaginary parts of the members of the gauge differential voltage group. The calculation formula is expanded below.

Real part instantaneous values of the members of the gauge differential voltage group are as explained below.

$$\{ \begin{matrix}{v}_{21} = Re [ {v}_{2} ( t ) ] = V cos ( ω t + \frac{3 α}{2} ) - V cos ( ω t + \frac{α}{2} ) \\ {v}_{22} = Re [ {v}_{2} ( t - T ) ] = V cos ( ω t + \frac{α}{2} ) - V cos ( ω t - \frac{α}{2} ) \\ {v}_{23} = Re [ {v}_{2} ( t - 2 T ) ] = V cos ( ω t - \frac{α}{2} ) - V cos ( ω t - \frac{3 α}{2} )\end{matrix} \qquad ( 5 )$$

In the formula, Re represents a real part of a complex number. When the real parts of the differential voltage vectors are substituted in the numerator of Formula (4), a calculation is performed as indicated by the following formula:

$$\begin{matrix}{v}_{21} + {v}_{23} = V [ \begin{matrix}cos ( ω t + \frac{3 α}{2} ) - cos ( ω t + \frac{α}{2} ) + \\ cos ( ω t - \frac{α}{2} ) - cos ( ω t - \frac{3 α}{2} )\end{matrix} ] \\ = V [ \begin{matrix}\begin{matrix}cos ( ω t ) cos \frac{3 α}{2} - sin ( ω t ) sin \frac{3 α}{2} - \\ cos ( ω t ) cos \frac{α}{2} + sin ( ω t ) sin \frac{α}{2} +\end{matrix} \\ \begin{matrix}cos ( ω t ) cos \frac{α}{2} + sin ( ω t ) sin \frac{α}{2} - \\ cos ( ω t ) cos \frac{3 α}{2} - sin ( ω t ) sin \frac{3 α}{2}\end{matrix}\end{matrix} ] \\ = 2 V sin ( ω t ) ( sin \frac{α}{2} - sin \frac{3 α}{2} ) \\ = 2 V sin ( ω t ) ( 4 {sin}^{3} \frac{α}{3} - 2 sin \frac{α}{2} ) \\ = - 4 V sin ( ω t ) sin \frac{α}{2} cos α\end{matrix} \qquad ( 6 )$$

When the real part of the differential voltage vector is substituted in the denominator of Formula (4), a calculation is performed as indicated by the following formula:

$$\begin{matrix}2 {v}_{22} = 2 V [ cos ( ω t + \frac{α}{2} ) - cos ( ω t - \frac{α}{2} ) ] \\ = 2 V [ \begin{matrix}cos ( ω t ) cos \frac{α}{2} - sin ( ω t ) sin \frac{α}{2} - \\ cos ( ω t ) cos \frac{α}{2} - sin ( ω t ) sin \frac{α}{2}\end{matrix} ] \\ = - 4 V sin ( ω t ) sin \frac{α}{2}\end{matrix} \qquad ( 7 )$$

From Formulas (6) and (7) above, a frequency coefficient is calculated as indicated by the following formula:

$${f}_{C} = \frac{{v}_{21} + {v}_{23}}{2 {v}_{22}} = \frac{- 4 V sin ( ω t ) sin \frac{α}{2} cos α}{- 4 V sin ( ω t ) sin \frac{α}{2}} = cos α \qquad ( 8 )$$

That is, the frequency coefficient is a cosine value of a rotation phase angle.

The frequency coefficient can be calculated from the imaginary parts of the differential voltage vectors as well. Imaginary part instantaneous values of the members of the gauge differential voltage group are as follows:

$$\{ \begin{matrix}{v}_{21} = Im [ {v}_{2} ( t ) ] = V sin ( ω t + \frac{3 α}{2} ) - V sin ( ω t + \frac{α}{2} ) \\ {v}_{22} = Im [ {v}_{2} ( t - T ) ] = V sin ( ω t + \frac{α}{2} ) - V sin ( ω t - \frac{α}{2} ) \\ {v}_{23} = Im [ {v}_{2} ( t - 2 T ) ] = V sin ( ω t - \frac{α}{2} ) - V sin ( ω t - \frac{3 α}{2} )\end{matrix} \qquad ( 9 )$$

In the formula, Im represents an imaginary part of a complex number. When the imaginary parts of the differential voltage vectors are substituted in the numerator of Formula (4), a calculation is performed as indicated by the following formula:

$$\begin{matrix}{v}_{21} + {v}_{23} = V [ \begin{matrix}sin ( ω t + \frac{3 α}{2} ) - sin ( ω t + \frac{α}{2} ) + \\ sin ( ω t - \frac{α}{2} ) - sin ( ω t - \frac{3 α}{2} )\end{matrix} ] \\ = V [ \begin{matrix}\begin{matrix}sin ( ω t ) cos \frac{3 α}{2} + cos ( ω t ) sin \frac{3 α}{2} - \\ sin ( ω t ) cos \frac{α}{2} - cos ( ω t ) sin \frac{α}{2} +\end{matrix} \\ \begin{matrix}sin ( ω t ) cos \frac{α}{2} - cos ( ω t ) sin \frac{α}{2} - \\ sin ( ω t ) cos \frac{3 α}{2} + cos ( ω t ) sin \frac{3 α}{2}\end{matrix}\end{matrix} ] \\ = 2 V cos ( ω t ) ( sin \frac{3 α}{2} - sin \frac{α}{2} ) \\ = 2 V sin ( ω t ) ( 2 sin \frac{α}{2} - 4 {sin}^{3} \frac{α}{3} ) \\ = 4 V cos ( ω t ) sin \frac{α}{2} cos α\end{matrix} \qquad ( 10 )$$

When the imaginary parts of the differential voltage vectors are substituted in the denominator of Formula (4), a calculation is performed as indicated by the following formula:

$$\begin{matrix}2 {v}_{22} = 2 V [ sin ( ω t + \frac{α}{2} ) - sin ( ω t - \frac{α}{2} ) ] \\ = 2 V [ \begin{matrix}sin ( ω t ) cos \frac{α}{2} + cos ( ω t ) sin \frac{α}{2} - \\ sin ( ω t ) cos \frac{α}{2} + cos ( ω t ) sin \frac{α}{2}\end{matrix} ] \\ = 4 V cos ( ω t ) sin \frac{α}{2}\end{matrix} \qquad ( 11 )$$

From Formulas (10) and (11), a frequency coefficient is calculated as indicated by the following formula:

$${f}_{C} = \frac{{v}_{21} + {v}_{23}}{2 {v}_{22}} = \frac{4 V cos ( ω t ) sin \frac{α}{2} cos α}{4 V cos ( ω t ) sin \frac{α}{2}} = cos α \qquad ( 12 )$$

As in the calculation result of the real parts, the frequency coefficient is a cosine value of the rotation phase angle. The above result exactly indicates that the gauge differential voltage group has symmetry and the frequency coefficient is a rotation invariable of the gauge differential voltage group. The calculation method is referred to as frequency coefficient method. The frequency coefficient is an extremely important parameter. In the present invention, the frequency coefficient is a base of subsequent calculations.

(Rotation Phase Angle)

From Formula (8) or Formula (12), the rotation phase angle can be calculated as indicated by the following formula:

α=cos⁻¹ f_{C} (13)

A frequency coefficient f_{C} satisfies a condition of the following formula:

|f_{C}|≦1 (14)

When the above conditional expression is not satisfied, it is determined that the input waveform is not an alternating-current waveform.

(Calculation of a Frequency According to the Rotation Phase Angle)

First, the definition of the rotation phase angle α is as indicated by the following formula:

$$α = 2 π \frac{f}{{f}_{S }} \qquad ( 15 )$$

In the formula, f represents a real frequency and fₛ represents a sampling frequency. From Formulas (13) and (15), a frequency is calculated as follows:

$$f = \frac{{f}_{S}}{2 π} {cos}^{- 1} {f}_{C} \qquad ( 16 )$$

The calculation formula for calculating a frequency using only the gauge differential voltage group is presented above. Before the application of the present invention, the inventor of this application disclosed a calculation formula for calculating a frequency using two symmetry groups, i.e., a gauge voltage group and a gauge differential voltage group (not disclosed as of the date of the application of the present invention). An offset component is included in a gauge voltage, which is a member of the gauge voltage group. However, an offset component is not included in a gauge differential voltage, which is a member of the gauge differential voltage group. Therefore, in the method according to the present invention, it is possible to calculate a frequency irrespective of a direct-current offset of the input waveform. The frequency coefficient is calculated as explained above, whereby it is possible to perform measurement of a frequency at high speed and on-line. Therefore, the method is suitably used for a protection control apparatus of a frequency following type.

Accuracy and characteristics related to the frequency coefficient measuring method are clarified in a section of a simulation of a case 1 explained below. In Table 1 below, several values are shown concerning a relation among a real frequency, a frequency coefficient, and a rotation phase angle. In the table, fₛ represents a sampling frequency.

TABLE 1
List of frequency coefficients and rotation
phase angles

| Real frequency | Frequency | Rotation phase |
|---|---|---|
| (Hz) | coefficient f_{c} | angle (deg) |
| 0 | 1 | 0 |
| fₛ/12 | 0.866 | 30 |
| fₛ/6 | 0.500 | 60 |
| fₛ/4 | 0 | 90 |
| fₛ/3 | −0.500 | 120 |
| 5fₛ/12 | −0.866 | 150 |
| fₛ/2 | −1 | 180 |

(A Sine Value of a Phase Rotation Angle and a Sine Value and a Cosine Value of a Half Rotation Phase Angle)

For an amplitude calculation below, calculation formulas for a sine value of a rotation phase angle and a sine value and a cosine value of a half rotation phase angle are presented.

From the above formulas, a sine value of a rotation phase angle is calculated using the following formula:

sin α=\sqrt{1−cos² α}=\sqrt{1−f_{C}²} (17)

Similarly, a sine value and a cosine value of a half rotation phase angle are calculated using the following formulas:

$$\begin{matrix}sin \frac{α}{2} = \sqrt{\frac{1 - cos α}{2}} = \sqrt{\frac{1 - {f}_{C}}{2}} & ( 18 ) \\ cos \frac{α}{2} = \sqrt{\frac{1 + cos α}{2}} = \sqrt{\frac{1 + {f}_{C}}{2}} & ( 19 )\end{matrix}$$

(Calculation Formula for a Gauge Differential Voltage)

A calculation formula for a gauge differential voltage is presented. A gauge differential voltage V_{gd} is calculated using the following formula:

V_{gd}=\sqrt{v²₂₂−v₂₁v₂₃} (20)

When Formula (5) is substituted in a formula in the square root of Formula (20), the following formula is obtained:

$${V}_{gd} = 2 V sin α sin \frac{α}{2} \qquad ( 21 )$$

(Voltage Amplitude)

When Formulas (17), (18), and (21) are used, a voltage amplitude V is calculated as follows:

$$V = \frac{{V}_{gd}}{2 sin αsin \frac{α}{2}} = \frac{{V}_{gd}}{2 \sqrt{1 - {f}_{C}^{2}} \sqrt{\frac{1 - {f}_{C}}{2}}} = \frac{\sqrt{2} {V}_{gd}}{2 ( 1 - {f}_{C} ) \sqrt{1 + {f}_{C}}} \qquad ( 22 )$$

Formula (22) can be directly calculated using time series instantaneous value data. Further, the gauge differential voltage is calculated using a difference value of a voltage instantaneous value. Therefore, it is possible to perform high-speed and highly accurate measurement without being affected by the influence on a direct-current offset in a voltage waveform. When a sampling frequency is set to a quadruple of a system frequency (a rated frequency) and a real frequency is the rated frequency, the frequency coefficient is zero (see Table 1 above) and the following amplitude calculation formula holds:

$$V = \frac{\sqrt{2} {V}_{gd}}{2} \qquad ( 23 )$$

(Calculation Formulas for Calculating a Frequency Coefficient and a Gauge Differential Voltage Using a Plurality of Sampling Data)

Calculation formulas for a frequency coefficient and a gauge differential voltage used when the alternating-current electrical quantity measuring apparatus has a plurality of sampling data are as indicated by the following formulas:

$$\begin{matrix} {f}_{C} = \frac{1}{n - 2} {\sum }_{k = 2}^{n - 1} \frac{{v}_{2 ( k - 1 )} + {v}_{2 ( k + 1 )}}{2 {v}_{2 k}} , n \geq 3 & ( 24 ) \\ {V}_{gd} = \sqrt{\frac{1}{n - 2} ( {\sum }_{k = 2}^{n - 1} ( {v}_{2 k}^{2} - {v}_{2 ( k - 1 )} {v}_{2 ( k + 1 )} ) )} = 2 V sin α sin \frac{α}{2} , n \geq 3 & ( 25 )\end{matrix}$$

In the formula, v₂ₖ represents a differential voltage instantaneous value. There is an effect of reducing the influence of noise data superimposed on an input waveform by using sampling data at three or more points.

Formulas (20) to (25) are the calculation formulas for performing calculations using voltage data. However, in calculation formulas for performing calculations using current data, the calculations can be performed in the same manner as the calculation formulas for performing calculation using voltage data.

(Calculation Formulas for Calculating a Frequency Coefficient and a Gauge Differential Voltage Using a Plurality of Current Sampling Data)

Calculation formulas for calculating a frequency coefficient and a gauge differential current using a plurality of current sampling data are as indicated by the following formulas:

$$\begin{matrix}{f}_{C} = \frac{1}{n - 2} {\sum }_{k = 2}^{n - 1} \frac{{i}_{2 ( k - 1 )} + {i}_{2 ( k + 1 )}}{2 {i}_{2 k}} , n \geq 3 & ( 26 ) \\ {I}_{gd} = \sqrt{\frac{1}{n - 2} ( {\sum }_{k = 2}^{n - 1} ( {i}_{2 k}^{2} - {i}_{2 ( k - 1 )} {i}_{2 ( k + 1 )} ) )} = 2 I sin α sin \frac{α}{2} , n \geq 3 & ( 27 )\end{matrix}$$

In the formula, i₂ₖ represents a differential current instantaneous value.

(Current Amplitude)

When Formulas (17), (18), and (27) are used, a current amplitude I is calculated as follows:

$$I = \frac{\sqrt{2} {I}_{gd}}{2 ( 1 - {f}_{C} ) \sqrt{1 + {f}_{C}}} \qquad ( 28 )$$

Expression (28) can be directly calculated using time series instantaneous value data. Further, the gauge differential current is calculated using a difference value of a current instantaneous value. Therefore, it is possible to perform high-speed and highly accurate measurement without being affected by the influence on a direct-current offset in a current waveform.

(Direct-Current Offset Calculation Method 1)

A first method for calculating a direct-current offset using a gauge voltage group on a complex plane (a direct-current offset calculating method 1) is explained. FIG. 2 is a diagram of a gauge voltage group on a complex plane with a direct-current offset.

In FIG. 2, three voltage vectors v₁(t), v₁(t−T), and v₁(t−2T) rotating counterclockwise at a real frequency on the complex plane form a gauge voltage group. In FIG. 2, d represents a direct-current offset. Because the direct-current offset is included in a voltage instantaneous value, the voltage instantaneous value is represented by the following formula:

$$\{ \begin{matrix}{v}_{11} = V cos ( ω t + α ) + d \\ {v}_{12} = V cos ( ω t ) + d \\ {v}_{13} = V cos ( ω t - α ) + d\end{matrix} \qquad ( 29 )$$

A frequency coefficient f_{C} of an alternating-current portion of the voltage instantaneous value is calculated using a gauge differential voltage (see Formula (4) above). The three voltage vectors v₁(t), v₁(t−T), and v₁(t−2T), which are members of the gauge voltage group, also have symmetry with respect to the center vector v1(t−T). This characteristic is the same as the characteristic of the gauge differential voltage group. Therefore, the following formula holds based on Formula (4) according to analogy with the gauge differential voltage group.

$${f}_{C} = \frac{( {v}_{11} - d ) + ( {v}_{13} - d )}{2 ( {v}_{12} - d )} = \frac{{v}_{11} + {v}_{13} - 2 d}{2 ( {v}_{12} - d )} = \frac{V cos ( ω t + α ) + V cos ( ω t - α )}{2 V cos ( ω t )} = cos α = {f}_{C} \qquad ( 30 )$$

The direct-current offset d is calculated as follows according to Formula (30):

$$d = \frac{{v}_{11} + {v}_{13} - 2 {v}_{12} {f}_{C}}{2 ( 1 - {f}_{C} )} \qquad ( 31 )$$

A calculation formula for calculating a direct-current offset using a plurality of gauge voltage groups is expanded as indicated by the following formula:

$$d = \frac{1}{n - 2} {\sum }_{k = 2}^{n - 1} \frac{{v}_{1 ( k - 1 )} + {v}_{1 ( k + 1 )} - 2 {v}_{1 k} {f}_{C}}{2 ( 1 - {f}_{C} )} , n \geq 3 \qquad ( 32 )$$

When a sampling frequency is set to a quadruple of a power system rated frequency, if it is assumed that a real frequency is a rated frequency, a frequency coefficient is zero and the following direct-current offset calculation formula holds:

$$d = \frac{1}{n - 2} {\sum }_{k = 2}^{n - 1} \frac{{v}_{1 ( k - 1 )} + {v}_{1 ( k + 1 )}}{2} , n \geq 3 \qquad ( 33 )$$

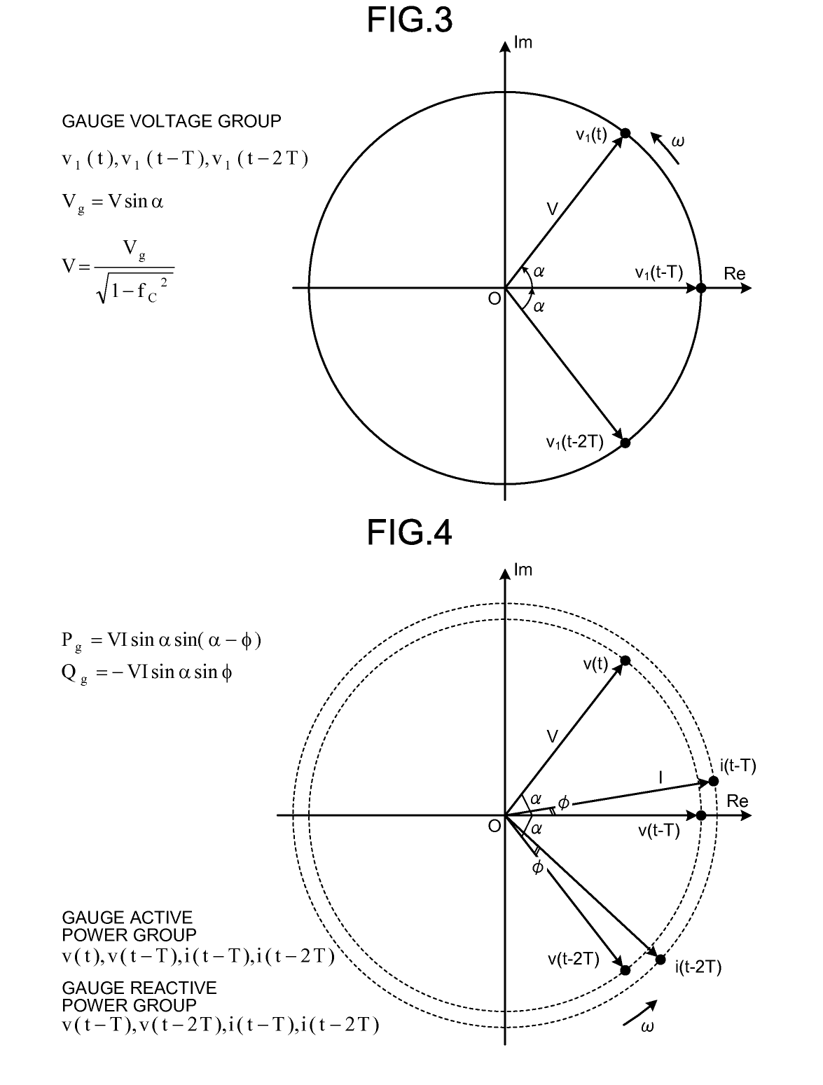

FIG. 3 is a diagram of a gauge voltage group on the complex plane without a direct-current offset. When a direct-current offset of the members of the gauge voltage group is cancelled using the direct-current offset calculated as explained above, a gauge voltage group shown in FIG. 3 can be assumed. The three voltage vectors, which are the members of the gauge voltage group, can be represented by the following formula:

$$\{ \begin{matrix}{v}_{1} ( t ) = V {e}^{j ( ω t + α )} \\ {v}_{1} ( t - T ) = V {e}^{j ω t} \\ {v}_{1} ( t - 2 T ) = V {e}^{j ( ω t - α )}\end{matrix} \qquad ( 34 )$$

When there is a direct-current offset, real part instantaneous values of the members of the gauge voltage group can be represented as indicated by the following formula:

$$\{ \begin{matrix}{v}_{11} - d = Re [ {v}_{1} ( t ) ] = V cos ( ω t + α ) \\ {v}_{12} - d = Re [ {v}_{1} ( t - T ) ] = V cos ( ω t ) \\ {v}_{13} - d = Re [ {v}_{1} ( t - 2 T ) ] = V cos ( ω t - α )\end{matrix} \qquad ( 35 )$$

In the formula, v₁₁, v₁₂, and v₁₃ respectively represent voltage instantaneous values at the present point, at the immediately preceding step, and at the second immediately preceding step and d represents a direct-current offset value.

(Calculation Formula for a Gauge Voltage with a Direct-Current Offset)

A calculation formula for a gauge voltage with a direct-current offset is presented. The first member and the last member of the gauge voltage group have symmetry with respect to the intermediate member. Therefore, a relation same as Formula (20) holds concerning a voltage component from which a direct-current offset is cancelled. Therefore, a gauge voltage V_{g} with a direct-current offset is calculated using the following formula:

V_{g}=\sqrt{(v₁₂−d)²−(v₁₁−d)(v₁₃−d)} (36)

If Formula (35) is substituted in a square root of Formula (36), the following formula is obtained:

V_{g}=V sin α (37)

The gauge voltage Vg is a rotation invariable of an alternating voltage and is an alternating-current electrical quantity unrelated to a direct-current offset.

(Voltage Amplitude Due to a Gauge Voltage)

When Formulas (17) and (37) are used, the voltage amplitude V is calculated as follows:

$$V = \frac{{V}_{g}}{sin α} = \frac{{V}_{g}}{\sqrt{1 - {f}_{C}^{2}}} \qquad ( 38 )$$

(Calculation Formula for Calculating a Gauge Voltage Using a Plurality of Sampling Data)

A calculation formula for calculating a gauge voltage using a plurality of sampling data can be represented as indicated by the following formula in the same manner as the calculation of a gauge differential voltage.

$${V}_{g} = \sqrt{\frac{1}{n - 2} ( {\sum }_{k = 2}^{n - 1} ( {v}_{1 k}^{2} - {v}_{1 ( k - 1 )} {v}_{1 ( k + 1 )} ) )} = V sin α , n \geq 3 \qquad ( 39 )$$

In the formula, V₁ₖ represents a voltage instantaneous value. If a larger number of sampling points are used, it is possible to increase the number of gauge voltage groups and perform averaging processing. Therefore, it is possible to reduce the influence of noise of an input waveform. When a sampling frequency is set to a quadruple of a power system rated frequency, if a real frequency is assumed to be a rated frequency, the frequency coefficient f_{C} is zero. The following amplitude calculation formula is derived from Formula (38):

V=V_{g} (40)

(Direct-Current Offset Calculation Method 2)

A second method of calculating a direct-current offset using a gauge voltage group on a complex plane (a direct-current offset calculation method 2) is explained.

First, the gauge voltage calculation formula of Formula (36) is expanded as follows:

V_{g}²=(v₁₂−d)²−(v₁₁−d)(v₁₃−d)=V² sin² α (41)

When Formula (41) is expanded, the direct-current offset d is calculated as follows:

$$d = \frac{{V}^{2} {sin}^{2} α - {v}_{12}^{2} + {v}_{11} {v}_{13}}{{v}_{11} + {v}_{13} - 2 {v}_{12}} \qquad ( 42 )$$

The following formula holds according to Formula (17) and Formula (22):

$${V}^{2} {sin}^{2} α = {( \frac{\sqrt{2} {V}_{gd}}{2 ( 1 - {f}_{C} ) \sqrt{1 + {f}_{C}}} )}^{2} ( 1 - {f}_{C}^{2} ) = \frac{{V}_{gd}^{2}}{2 ( 1 - {f}_{C} )} \qquad ( 43 )$$

If Formula (43) is substituted in Formula (42), a calculation formula for a direct-current offset is represented as follows:

$$d = \frac{\frac{{V}_{gd}^{2}}{2 ( 1 - {f}_{C} )} - {v}_{12}^{2} + {v}_{11} {v}_{13}}{{v}_{11} + {v}_{13} - 2 {v}_{12}} \qquad ( 44 )$$

If Formula (44) is expanded to a plurality of gauge voltage groups, a calculation formula for a direct-current offset can be represented as indicated by the following formula:

$$d = \frac{1}{n - 2} {\sum }_{k = 2}^{n - 1} \frac{\frac{{V}_{gd}^{2}}{2 ( 1 - {f}_{C} )} - {v}_{1 k}^{2} + {v}_{1 ( k - 1 )} {v}_{1 ( k + 1 )}}{{v}_{1 ( k - 1 )} + {v}_{1 ( k + 1 )} - 2 {v}_{1 k}} , n \geq 3 \qquad ( 45 )$$

When a sampling frequency is set to a quadruple of a power system rated frequency, if a real frequency is assumed to be a rated frequency, the frequency coefficient f_{C} is zero. The following direct-current offset calculation formula is derived from Formula (45):

$$d = \frac{1}{n - 2} {\sum }_{k = 2}^{n - 1} \frac{\frac{{V}_{gd}^{2}}{2} - {v}_{1 k}^{2} + {v}_{1 ( k - 1 )} {v}_{1 ( k + 1 )}}{{v}_{1 ( k - 1 )} + {v}_{1 ( k + 1 )} - 2 {v}_{1 k}} , n \geq 3 \qquad ( 46 )$$

(Calculation Formula for Calculating a Gauge Current Using a Plurality of Sampling Data)

A calculation formula for calculating a gauge current using a plurality of sampling data can be represented as indicated by the following formula in the same manner as the calculation of the gauge differential current:

$${I}_{g} = \sqrt{\frac{1}{n - 2} ( {\sum }_{k = 2}^{n - 1} ( {i}_{1 k}^{2} - {i}_{1 ( k - 1 )} {i}_{1 ( k + 1 )} ) )} = I sin α , n \geq 3 \qquad ( 47 )$$

In the formula, i₁ₖ represents a current instantaneous value. If a larger number of sampling points are used, it is possible to increase the number of gauge current groups and perform averaging processing. Therefore, it is possible to reduce the influence of noise of an input waveform.

(Current Amplitude Due to a Gauge Current)

The current amplitude of a gauge current is calculated by the following formula in the same manner as the gauge voltage:

$$I = \frac{{I}_{g}}{\sqrt{1 - {f}_{C}^{2}}} \qquad ( 48 )$$

(Rotation Phase Angle Symmetry Index 1)

A first index (a rotation phase angle symmetry index 1) of a method of using a rotation phase angle as an index for evaluating the symmetry of an input waveform is explained. The rotation phase angle symmetry index 1 is defined as indicated by the following formula:

α_{sym}=|α_{cos}−αₛᵢₙ| (49)

In the formula, α_{cos} represents a rotation phase angle calculated by a frequency coefficient method and αₛᵢₙ represents a rotation phase angle calculated using a gauge voltage group or a gauge differential voltage group. The rotation phase angles are represented as indicated by the following formula:

$$\{ \begin{matrix}{α}_{cos} = {cos}^{- 1} {f}_{C} \\ {α}_{sin} = 2 {sin}^{- 1} ( \frac{{V}_{gd}}{2 {V}_{g}} )\end{matrix} \qquad ( 50 )$$

A second formula of Formula (50) is obtained from a relation between Formula (21) and Formula (37).

If an input waveform is a pure sine wave, the rotation phase angle symmetry index 1 indicated by Formula (49) is zero.

On the other hand, when the rotation phase angle symmetry index 1 is larger than a predetermined threshold, that is, when the rotation phase angle symmetry index 1 is in a relation of the following formula with respect to a threshold a α_{BRK}, it is determined that the input waveform is not the pure sine wave because the symmetry of the input waveform is broken. In this case, a rotation phase angle and the like, which are measured values, are latched according to necessity.

α_{sym}=|α_{cos}−αₛᵢₙ|>α_{BRK} (51)

(Calculation of a Symmetry Breaking Time)

First, a symmetry breaking time is defined as indicated by the following formula:

t_{BRK1}=t_{BRK0}+T (52)

In the formula, t_{BRK0} represents an integrated value of a continuous symmetry breaking time to the preceding step and t_{BRK1} represents a value of a symmetry breaking time at the present step. In the formula, T represents a pitch width time. When the symmetry is not broken, the symmetry breaking time t_{BRK0} is set to zero.

t_{BRK1}=0 (53)

As the symmetry breaking time is longer, the quality of electric power is considered to be lower. When the symmetry breaking time is used, it is possible to perform quantitative monitoring of power quality in an alternating-current system. It is possible to detect a disturbance and the like of the alternating-current system.

(Rotation Phase Angle Symmetry Index 2)

The rotation phase angle symmetry index 1 always involves calculation of an inverse trigonometric function (see Formulas (49) and (50)). Therefore, a calculation time is necessary. Therefore, a second evaluation index (a rotation phase angle symmetry index 2) not requiring calculation of a trigonometric function is explained. The rotation phase angle symmetry index 2 is defined as indicated by the following formula:

$$s {α}_{sym} = \vert {( sin \frac{α}{2} )}_{cos} - {( sin \frac{α}{2} )}_{sin} \vert \qquad ( 54 )$$

In the formula, (sin(α/2)_{cos}), which is a first term in an absolute value sign, can be calculated by the frequency coefficient method and (sin(α/2)ₛᵢₙ), which is a second term in the absolute value sign, can be calculated using a gauge voltage group or a gauge differential voltage group. Calculation formulas for the first and second terms are indicated by Formula (18) and Formula (50) and described below again.

$$\{ \begin{matrix}{( sin \frac{α}{2} )}_{cos} = \sqrt{\frac{1 - {f}_{C}}{2}} \\ {( sin \frac{α}{2} )}_{sin} = \frac{{V}_{gd}}{2 {V}_{g}}\end{matrix} \qquad ( 55 )$$

If an input waveform is a pure sine wave, the rotation phase angle symmetry index 2 indicated by Formula (54) is zero.

On the other hand, when the rotation phase angle symmetry index 2 is larger than a predetermined threshold, that is, when the rotation phase angle symmetry index 2 is in a relation of the following formula with respect to the threshold α_{BRK}, it is determined that the input waveform is not the pure sine wave because the symmetry of the input waveform is broken. In this case, a rotation phase angle and the like, which are measured values, are latched according to necessity.

$$s {α}_{sym} = \vert {( sin \frac{α}{2} )}_{cos} - {( sin \frac{α}{2} )}_{sin} \vert > s {α}_{BRK} \qquad ( 56 )$$

(Processing Performed when Symmetry is Broken)

When the symmetry of the input waveform is broken, in an application as a protection control apparatus, in some case, it is necessary to latch a value before the breaking of the symmetry. In such a case, for example, a rotation phase angle, a frequency, and a voltage amplitude are respectively latched as follows:

$$\{ \begin{matrix}{α}_{t} = {α}_{t - T} \\ {f}_{t} = {f}_{t - T} \\ {V}_{t} = {V}_{t - T}\end{matrix} \qquad ( 57 )$$

In the formula, aₜ, fₜ, and Vₜ respectively represent a rotation phase angle, a frequency, and a voltage amplitude at the present point and αₜ−T, fₜ−T, and Vₜ−T respectively represent a rotation phase angle, a frequency, and a voltage amplitude at the immediately preceding step.

(Voltage Amplitude Symmetry Index 1)

A first index (a voltage amplitude symmetry index 1) of a method of using a voltage amplitude as an index for evaluating the symmetry of an input waveform is explained. The voltage amplitude symmetry index 1 is defined as indicated by the following formula:

V_{sym1}=V_{gA}−V_{gdA}| (58)

In the formula, V_{gA} and V_{gdA} respectively represent voltage amplitudes calculated using a gauge voltage group and a gauge differential voltage group as follows:

$$\{ \begin{matrix}{V}_{gA} = \frac{{V}_{g}}{\sqrt{1 - {f}_{C}^{2}}} \\ {V}_{gdA} = \frac{\sqrt{2} {V}_{gd}}{2 ( 1 - {f}_{C} ) \sqrt{1 + {f}_{C}}}\end{matrix} \qquad ( 59 )$$

If an input waveform is a pure sine wave, the voltage amplitude symmetry index 1 indicated by Formula (58) is zero.

On the other hand, when the voltage amplitude symmetry index 1 is larger than a predetermined threshold, that is, when the voltage amplitude symmetry index 1 is in a relation of the following formula with respect to a threshold V_{BRK}, it is determined that the input waveform is not the pure sine wave because the symmetry of the input waveform is broken. In this case, a rotation phase angle, a frequency, a voltage amplitude, and the like, which are measured values, are latched according to necessity.

V_{sym1}=|V_{gA}−V_{gdA}|>V_{BRK} (60)

The idea of the voltage amplitude symmetry index 1 can be applied to a current amplitude as well. Expansion of the formula is omitted.

(Gauge Power Group)

FIG. 4 is a diagram of a gauge power group on a complex plane. In FIG. 4, three voltage vectors v(t), v(t−T), and v(t−2T) rotating counterclockwise at a real frequency on the complex plane and two current vectors i(t−T) and i(t−2T) rotating counterclockwise at the real frequency on the complex plane are shown. The three voltage vectors v(t), v(t−T), and v(t−2T) and the two current vectors i(t−T) and i(t−2T) can be respectively represented as indicated by the following formulas:

$$\begin{matrix}\begin{matrix}v ( t ) = V {e}^{j ( ω t + α )} \\ v ( t - T ) = V {e}^{j ( ω t )} \\ v ( t - 2 T ) = V {e}^{j ( ω t - α )}\end{matrix} \} & ( 61 ) \\ \begin{matrix}i ( t - T ) = I {e}^{j ( ω t + φ )} \\ i ( t - 2 T ) = I {e}^{j ( ω t - α + φ )}\end{matrix} \} & ( 62 )\end{matrix}$$

(Gauge Power Group, Gauge Active Power Group, and Gauge Reactive Power Group)

The three voltage vectors v(t), v(t−T), and v(t−2T) and the two current vectors i(t−T) and i(t−2T) are defined as a “gauge power group”. Among the rotation vectors forming the gauge power group, the voltage vectors v(t) and v(t−T) and the two current vectors i(t−T) and i(t−2T) are defined as a “gauge active power group” and the two voltage vectors v(t−T) and v(t−2T) and the two current vectors i(t−T) and i(t−2T) are defined as a “gauge reactive power group”.

(Gauge Active Power)

Gauge active power is defined as indicated by the following formula using the gauge active power group:

P_{g}=v₂i₂−v₁i₃ (63)

In the formula, voltage instantaneous values v₁ and v₂ are respectively real parts of the voltage vectors v(t) and v(t−T) and calculated as indicated by the following formula:

$$\begin{matrix}{v}_{1} = Re [ v ( t ) ] = V cos ( ω t + α ) \\ {v}_{2} = Re [ v ( t - T ) ] = V cos ( ω t )\end{matrix} \} \qquad ( 64 )$$

Similarly, current instantaneous values i₂ and i₃ are respectively real parts of the current vectors i(t−T) and i(t−2T) and calculated as indicated by the following formula:

$$\begin{matrix}{i}_{2} = Re [ i ( t - T ) ] = I cos ( ω t + φ ) \\ {i}_{3} = Re [ i ( t - 2 T ) ] = I cos ( ω t - α + φ )\end{matrix} \} \qquad ( 65 )$$

If Formulas (64) and (65) are substituted in Formula (63), the calculation formula representing the gauge active power is converted as indicated by the following formula:

$$\begin{matrix}{P}_{g} = {v}_{2} {i}_{2} - {v}_{1} {i}_{3} \\ = VI [ cos ( ω t ) cos ( ω t + φ ) - cos ( ω t + α ) cos ( ω t - α + φ ) ] \\ = \frac{VI}{2} [ cos ( 2 ω t + φ ) + cos φ - cos ( 2 ω t + φ ) - cos ( 2 α - φ ) ] \\ = \frac{VI}{2} [ cos ϕ ( 1 - cos 2 α ) - sin ( 2 α ) sin φ ] \\ = VI sin α sin ( α - φ )\end{matrix} \qquad ( 66 )$$

That is, the calculation formula for the gauge active power can be represented as indicated by the following formula:

P_{g}=VI sin α sin(α−φ) (67)

(Gauge Reactive Power)

The gauge active power is defined as indicated by the following formula using the gauge reactive power group.

Q_{g}=v₃i₂−v₂i₃ (68)

In the formula, voltage instantaneous values v₂ and v₃ are respectively real parts of voltage vectors v(t−T) and v(t−2T) and calculated as indicated by the following formula:

$$\begin{matrix}{v}_{2} = Re [ v ( t - T ) ] = V cos ( ω t ) \\ {v}_{3} = Re [ v ( t - 2 T ) ] = V cos ( ω t + α )\end{matrix} \} \qquad ( 69 )$$

Current instantaneous values i₂ and i₃ are defined as indicated by Formula (65). If Formula (65) and Formula (69) are substituted in Formula (68), the calculation formula representing the gauge reactive power is converted as indicated by the following formula:

$$\begin{matrix}{Q}_{g} = {v}_{3} {i}_{2} - {v}_{2} {i}_{3} \\ = VI [ cos ( ω t - α ) cos ( ω t + φ ) - cos ( ω t ) cos ( ω t - α + φ ) ] \\ = \frac{VI}{2} [ cos ( 2 ω t - α + φ ) + cos ( α + φ ) - cos \\ ( 2 ω t - α + φ ) - cos ( α - φ ) ] \\ = \frac{VI}{2} [ cos ( α + φ ) - cos ( α - φ ) ] \\ = - VI sin α sin φ\end{matrix} \qquad ( 70 )$$

That is, the calculation formula for the gauge reactive power can be represented as indicated by the following formula:

Q_{g}=−VI sin α sin φ (71)

From Formula (67) and Formula (71), a cosine value and a sine value of a voltage-current phase angle φ can be calculated using the following formula:

$$\{ \begin{matrix}cos φ = \frac{{P}_{g} - {Q}_{g} cos α}{VI {sin}^{2} α} \\ sin φ = - \frac{{Q}_{g}}{VI sin α}\end{matrix} \qquad ( 72 )$$

Therefore, according to the general definition of electric power, active power and reactive power are calculated as indicated by the following formula:

$$\{ \begin{matrix}P = VI cos φ = \frac{{P}_{g} - {Q}_{g} cos α}{{sin}^{2} α} = \frac{{P}_{g} - {Q}_{g} {f}_{C}}{1 - {f}_{C}^{2}} \\ Q = VI sin φ = - \frac{{Q}_{g}}{sin α} = - \frac{{Q}_{g}}{\sqrt{1 - {f}_{C}^{2}}}\end{matrix} \qquad ( 73 )$$

Similarly, according to the general definition of electric power, apparent power is calculated as indicated by the following formula:

$$\begin{matrix}S = \sqrt{{P}^{2} + {Q}^{2}} \\ = \sqrt{{( \frac{{P}_{g} - {Q}_{g} cos α}{{sin}^{2} α} )}^{2} + {( \frac{{Q}_{g}}{sin α} )}^{2}} \\ = \sqrt{\frac{{P}_{g}^{2} - 2 {P}_{g} {Q}_{g} cos α + {Q}_{g}^{2}}{{sin}^{4} α}} \\ = \frac{\sqrt{{P}_{g}^{2} - 2 {P}_{g} {Q}_{g} {f}_{C} + {Q}_{g}^{2}}}{1 - {f}_{C}^{2}}\end{matrix} \qquad ( 74 )$$

Similarly, a power factor is calculated as indicated by the following formula:

$$\begin{matrix}PF = \frac{P}{S} \\ = \frac{{P}_{g} - {Q}_{g} cos α}{{sin}^{2} α} \sqrt{\frac{{sin}^{4} α}{{P}_{g}^{2} - 2 {P}_{g} {Q}_{g} cos α + {Q}_{g}^{2}}} \\ = \frac{{P}_{g} - {Q}_{g} cos α}{\sqrt{{P}_{g}^{2} - 2 {P}_{g} {Q}_{g} cos α + {Q}_{g}^{2}}} \\ = \frac{{P}_{g} - {Q}_{g} {f}_{C}}{\sqrt{{P}_{g}^{2} - 2 {P}_{g} {Q}_{g} {f}_{C} + {Q}_{g}^{2}}}\end{matrix} \qquad ( 75 )$$

(Gauge Power Symmetry Index)

A method of using gauge power as an index for evaluating the symmetry of an input waveform is explained. A gauge power symmetry index is defined as indicated by the following formula:

S_{sym1}=|(cos φ_{VI}−(cos φ)_{PF}| (76)

In the formula, (cos φ)_{VI} and (cos φ)_{PF} represent cosine values of the voltage-current phase angle φ calculated as follows:

$$\{ \begin{matrix}{( cos φ )}_{VI} = \frac{{P}_{g} - {Q}_{g} cos α}{VI {sin}^{2} α} = \frac{{P}_{g} - {Q}_{g} {f}_{C}}{{V}_{g} {I}_{g}} \\ {( cos φ )}_{PF} = PF = \frac{{P}_{g} - {Q}_{g} {f}_{C}}{\sqrt{{P}_{g}^{2} - 2 {P}_{g} {Q}_{g} {f}_{C} + {Q}_{g}^{2}}}\end{matrix} \qquad ( 77 )$$

In Formula (76), if an input waveform is a pure sine wave, the gauge power symmetry index is zero.

On the other hand, when the gauge power symmetry index is larger than a predetermined threshold, that is, when the gauge power symmetry index is in a relation of the following formula with respect to a threshold S_{BRK1}, it is determined that the input waveform is not the pure sine wave because the symmetry of the input waveform is broken. In this case, a measured value (a calculated value) is latched according to necessity.

S_{sym1}=|(cos φ)_{VI}−(cos φ)_{PF}|≧S_{BRK1} (78)

(Distance Protection Calculation Formula)

A calculation formula for distance protection is presented. First, according to the definition of impedance, the following calculation formula is obtained:

$$\begin{matrix}Z = \frac{v ( t )}{i ( t )} \\ = \frac{V}{I} {e}^{j φ} \\ = \frac{V}{I} ( cos φ + j sin φ ) \\ = \frac{1}{{I}^{2} {sin}^{2} α} ( {P}_{g} - {Q}_{g} cos α - j {Q}_{g} sin α ) \\ = \frac{1}{{I}_{g}^{2}} ( {P}_{g} - {Q}_{g} {f}_{C} - j {Q}_{g} \sqrt{1 - {f}_{C}^{2}} )\end{matrix} \qquad ( 79 )$$

From a real part and an imaginary part of the above formula, resistance and inductance can be calculated as indicated by the following formula:

$$\{ \begin{matrix}R = \frac{{P}_{g} - {Q}_{g} {f}_{C}}{{I}_{g}^{2}} \\ L = \frac{- {Q}_{g} \sqrt{1 - {f}_{C}^{2}}}{2 π {fI}_{g}^{2}}\end{matrix} \qquad ( 80 )$$

In the above formula, I_{g} represents a gauge current and f represents a measured frequency.

(Out-of-Step Protection Calculation Formula)

A calculation formula for out-of-step protection is presented. Because details of the calculation formula for out-of-step protection are disclosed in Patent Literature 4, please refer to the literature. According to Patent Literature 4, out-of-step discrimination for a power system is performed using the following formula:

V_{C}=V cos φᵥᵢ<ΔV_{STEP} (81)

In the formula, V_{C} represents an out-of-step center voltage ahead of a monitoring power transmission line from a transformer substation, V represents an own-end voltage amplitude, φᵥᵢ represents a phase angle between a voltage and an electric current of a power transmission line, and ΔV_{STEP} represents a setting value (e.g., 0.3 PU). When a power system accident occurs in the vicinity of a place where an out-of-step protection relay is arranged, calculated V_{C} suddenly drops. On the other hand, a change in V_{C} in the case of out-of-step changes at fixed speed. If this characteristic is used, it is possible to prevent a malfunction of the out-of-step protection relay.

A calculation formula for the out-of-step center voltage V_{C} is as indicated by the following formula:

$$\begin{matrix}{V}_{C} = V cos {φ}_{vi} \\ = V \frac{{P}_{g} - {Q}_{g} cos α}{VI {sin}^{2} α} = \frac{{P}_{g} - {Q}_{g} cos α}{{I}_{g} sin α} \\ = \frac{{P}_{g} - {Q}_{g} {f}_{C}}{{I}_{g} \sqrt{1 - {f}_{C}^{2}}}\end{matrix} \qquad ( 82 )$$

When it is desired to reduce the influence of noise, a plurality of sampling data only have to be used. A calculation formula for gauge active power in a plurality of gauge active power symmetry groups is as indicated by the following formula:

$${P}_{g} = \frac{1}{n - 2} ( {\sum }_{k = 2}^{n - 1} ( {v}_{k} {i}_{k} - {v}_{k - 1} {i}_{k + 1} ) ) = VI sin α sin ( α - φ ) , \\ n \geq 3 \qquad ( 83 )$$

A calculation formula for gauge reactive power in a plurality of gauge reactive power symmetry groups is as indicated by the following formula:

$${Q}_{g} = \frac{1}{n - 2} ( {\sum }_{k = 2}^{n - 1} ( {v}_{k + 1} {i}_{k} - {v}_{k} {i}_{k + 1} ) ) = - VI sin α sin φ , \\ n \geq 3 \qquad ( 84 )$$

Time series data of voltage instantaneous values and current instantaneous values is calculated using the following formula:

$$\{ \begin{matrix}{v}_{k} = Re \{ v [ t - ( k - 1 ) T ] \} , & k = 1 , 2 , … , n \\ {i}_{k} = Re \{ i [ t - ( k - 1 ) T ] \} , & k = 1 , 2 , … , n\end{matrix} \qquad ( 85 )$$

In the formula, time series data of a voltage vector and a current vector is calculated using the following formula:

$$\{ \begin{matrix}v [ t - ( k - 1 ) T ] = V {e}^{j [ ω t - ( k - 1 ) α ]} , & k = 1 , 2 , … , n \\ i [ t - ( k - 1 ) T ] = I {e}^{j [ ω t - ( k - 1 ) α + φ ]} , & k = 1 , 2 , … , n\end{matrix} \qquad ( 86 )$$

When the present invention is applied to the out-of-step protection relay of Patent Literature 4, frequency fluctuation is also automatically corrected when an out-of-step center voltage is calculated. Therefore, a high-speed and highly accurate out-of-step protection relay can be realized. More detailed explanation of the out-of-step protection relay is explained in a third embodiment below.

(Gauge Differential Power Group)

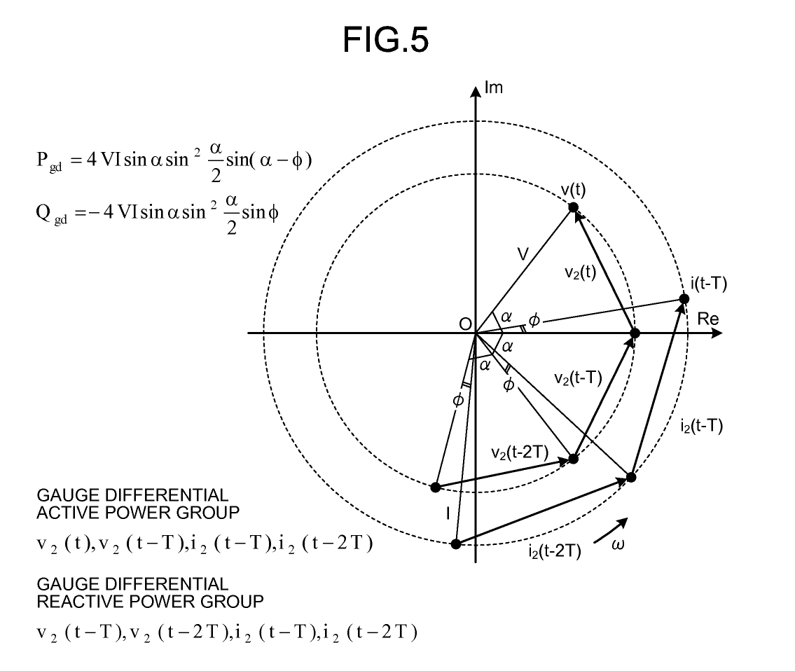

FIG. 5 is a diagram of a gauge differential power group on a complex plane. In FIG. 5, the three differential voltage vectors v₂(t), v₂(t−T), and V₂(t−2T) rotating counterclockwise at a real frequency on the complex plane and two differential current vectors i₂(t−T) and i₂(t−2T) rotating counterclockwise at the real frequency on the complex plane are shown. The three differential voltage vectors v₂(t), v₂(t−T), and V₂(t−2T) and the two differential current vectors i₂(t−T) and i₂(t−2T) can be respectively represented as indicated by the following formulas:

$$\begin{matrix}\{ \begin{matrix}{v}_{2} ( t ) = v ( t ) - v ( t - T ) = V {e}^{j ( ω t + α )} - V {e}^{j ω t} \\ {v}_{2} ( t - T ) = v ( t - T ) - v ( t - 2 T ) = V {e}^{j ω t} - V {e}^{j ( ω t - α )} \\ {v}_{2} ( t - 2 T ) = v ( t - 2 T ) - v ( t - 3 T ) = V {e}^{j ( ω t - α )} - V {e}^{j ( ω t - 2 α )}\end{matrix} & ( 87 ) \\ \{ \begin{matrix}{i}_{2} ( t - T ) = i ( t - T ) - i ( t - 2 T ) = I {e}^{j ( ω t + φ )} - I {e}^{j ( ω t - α + φ )} \\ {i}_{2} ( t - 2 T ) = i ( t - 2 T ) - i ( t - 3 T ) = I {e}^{j ( ω t - α + φ )} - I {e}^{j ( ω t - 2 α + φ )}\end{matrix} & ( 88 )\end{matrix}$$

(Gauge Differential Power Group, Gauge Differential Active Power Group, and Gauge Differential Reactive Power Group)

The three differential voltage vectors v₂(t), v₂(t−T), and V₂(t−2T) and the two differential current vectors i₂(t−T) and i₂(t−2T) are defined as a “gauge differential power group”. Among the rotation vectors forming the gauge power group, the two differential voltage vectors v₂(t) and v₂(t−T) and the two differential current vectors i₂(t−T) and i₂(t−2T) are defined as a “gauge differential active power group” and the two differential voltage vectors v₂(t−T) and V₂(t−2T) and the two differential current vectors i₂(t−T) and i₂(t−2T) are defied as a “gauge differential reactive power group”.

(Gauge Differential Active Power)

Gauge differential active power is defined as indicated by the following formula using the gauge differential active power group.

P_{gd}=v₂₂i₂₂−v₂₁i₂₃ (89)

In the formula, differential voltage instantaneous values v₂₁ and v₂₂ are respectively real parts of the differential voltage vectors v₂(t) and v₂(t−T) and calculated as indicated by the following formula:

$$\{ \begin{matrix}{v}_{21} = Re [ {v}_{2} ( t ) ] = V cos ( ω t + α ) - V cos ( ω t ) \\ {v}_{22} = Re [ {v}_{2} ( t - T ) ] = V cos ( ω t ) - V cos ( ω t - α )\end{matrix} \qquad ( 90 )$$

Similarly, current instantaneous values i₂₂ and i₂₃ are respectively real parts of the differential current vectors i₂(t−T) and i₂(t−2T) and calculated as indicated by the following formula:

$$\{ \begin{matrix}{i}_{22} = Re [ {i}_{2} ( t - T ) ] = I cos ( ω t + φ ) - I cos ( ω t - α + φ ) \\ {i}_{23} = Re [ {i}_{2} ( t - 2 T ) ] = I cos ( ω t - α + φ ) - I cos ( ω t - 2 α + φ )\end{matrix} \qquad ( 91 )$$

If Formulas (90) and (91) are substituted in Formula (89), the calculation formula representing the gauge differential active power is converted as indicated by the following formula:

$$\begin{matrix}{P}_{gd} = {v}_{22} {i}_{22} - {v}_{21} {i}_{23} \\ = VI \{ \begin{matrix}[ cos ( ω t ) - cos ( ω t - α ) ] [ cos ( ω t + φ ) - \\ cos ( ω t - α + φ ) ] - [ cos ( ω t + α ) - cos ( ω t ) ] \\ [ cos ( ω t - α + φ ) - cos ( ω t - 2 α + φ ) ]\end{matrix} \} \\ = VI [ \begin{matrix}cos ( ω t ) cos ( ω t + φ ) - \\ cos ( ω t ) cos ( ω t - α + φ ) - \\ cos ( ω t - α ) cos ( ω t + φ ) + \\ cos ( ω t - α ) cos ( ω t - α + φ ) - \\ cos ( ω t + α ) cos ( ω t - α + φ ) + \\ cos ( ω t + α ) cos ( ω t - 2 α + φ ) + \\ cos ( ω t ) cos ( ω t - α + φ ) - \\ cos ( ω t ) cos ( ω t - 2 α + ϕ )\end{matrix} ] \\ = \frac{VI}{2} [ \begin{matrix}cos ( 2 ω t + φ ) + cos φ - cos ( 2 ω t - α + φ ) - \\ cos ( α - φ ) - cos ( 2 ω t - α + φ ) - cos ( α + φ ) + \\ cos ( 2 ω t - 2 α + φ ) + cos φ - cos ( 2 ω t + φ ) - \\ cos ( 2 α - φ ) + cos ( 2 ω t - α + φ ) + \\ cos ( 3 α - φ ) + cos ( 2 ω t - α + φ ) + \\ cos ( α - φ ) - cos ( 2 ω t - 2 α + φ ) - \\ cos ( 2 α - φ )\end{matrix} ] \\ = \frac{VI}{2} [ 2 cos φ - 2 cos ( 2 α - φ ) - cos ( α + φ ) + cos ( 3 α - φ ) ] \\ = 4 VI sin {αsin}^{2} \frac{α}{2} sin ( α - φ )\end{matrix} \qquad ( 92 )$$

That is, the calculation formula for the gauge differential active power can be represented as indicated by the following formula:

$${P}_{gd} = 4 VI sin {αsin}^{2} \frac{α}{2} sin ( α - φ ) \qquad ( 93 )$$

(Gauge Differential Reactive Power)

Gauge differential reactive power is defined as indicated by the following formula using the gauge differential reactive power group.

Q_{gd}=v₂₃i₂₂−v₂₂i₂₃ (94)

In the formula, differential voltage instantaneous values v₂₂ and v₂₃ are respectively real parts of the differential voltage vectors v₂(t−T) and v₂(t−2T) and calculated as indicated by the following formula:

$$\{ \begin{matrix}{v}_{22} = Re [ v ( t - T ) - v ( t - 2 T ) ] = V cos ( ω t ) - V cos ( ω t - α ) \\ {v}_{23} = Re [ v ( t - 2 T ) - v ( t - 3 T ) ] = V cos ( ω t - α ) - V cos ( ω t - 2 α )\end{matrix} \qquad ( 95 )$$

The current instantaneous values i₂ and i₃ are defined as indicated by Formula (91). If Formula (91) and Formula (95) are substituted in Formula (94), the calculation formula representing the gauge differential reactive power is converted as indicated by the following formula:

$$\begin{matrix}{Q}_{gd} = {v}_{23} {i}_{22} - {v}_{22} {i}_{23} \\ = VI \{ \begin{matrix}[ cos ( ω t - α ) - cos ( ω t - 2 α ) ] [ cos ( ω t + φ ) - \\ cos ( ω t - α + φ ) ] - [ cos ( ω t ) - cos ( ω t - α ) ] \\ [ cos ( ω t - α + φ ) - cos ( ω t - 2 α + φ ) ]\end{matrix} \} \\ = VI [ \begin{matrix}cos ( ω t - α ) cos ( ω t + φ ) - \\ cos ( ω t - α ) cos ( ω t - α + φ ) - \\ cos ( ω t - 2 α ) cos ( ω t + φ ) + \\ cos ( ω t - 2 α ) cos ( ω t - α + φ ) - \\ cos ( ω t ) cos ( ω t - α + φ ) + \\ cos ( ω t ) cos ( ω t - 2 α + φ ) + \\ cos ( ω t - α ) cos ( ω t - α + φ ) - \\ cos ( ω t - α ) cos ( ω t - 2 α + ϕ )\end{matrix} ] \\ = \frac{VI}{2} [ \begin{matrix}cos ( 2 ω t - α + φ ) + cos ( α + φ ) - \\ cos ( 2 ω t - 2 α + φ ) - cos φ - \\ cos ( 2 ω t - 2 α + φ ) - cos ( 2 α + φ ) + \\ cos ( 2 ω t - 3 α + φ ) + cos ( α + φ ) - \\ cos ( 2 ω t - α + φ ) - cos ( 2 α - φ ) + \\ cos ( 2 ω t - 2 α + φ ) + cos ( 2 α - φ ) + \\ cos ( 2 ω t - 2 α + φ ) + cos φ - \\ cos ( 2 ω t - 3 α + φ ) - cos ( α - φ )\end{matrix} ] \\ = \frac{VI}{2} [ 2 cos ( α + φ ) - 2 cos ( 2 α - φ ) + cos ( 2 α - φ ) + \\ cos ( 2 α + φ ) ] \\ = - 4 VI sin {αsin}^{2} \frac{α}{2} sin φ\end{matrix} \qquad ( 96 )$$

That is, the calculation formula for the gauge differential reactive power can be represented as indicated by the following formula:

$${Q}_{gd} = - 4 VI sin {αsin}^{2} \frac{α}{2} sin φ \qquad ( 97 )$$

From Formula (93) and Formula (97), a cosine value and a sine value of the voltage-current phase angle φ can be calculated using the following formula:

$$\{ \begin{matrix}cos φ = \frac{{P}_{gd} - {Q}_{gd} cos α}{4 VI {sin}^{2} {αsin}^{2} \frac{α}{2}} \\ sin φ = - \frac{{Q}_{gd}}{4 VI sin {αsin}^{2} \frac{α}{2}}\end{matrix} \qquad ( 98 )$$

Therefore, according to the general definition of electric power, active power and reactive power are calculated as indicated by the following formula:

$$\{ \begin{matrix}P = VI cos φ = \frac{{P}_{gd} - {Q}_{gd} cos α}{4 {sin}^{2} {αsin}^{2} \frac{α}{2}} = \frac{{P}_{gd} - {Q}_{gd} {f}_{C}}{2 ( 1 + {f}_{C} ) {( 1 - {f}_{C} )}^{2}} \\ Q = VI sin φ = - \frac{{Q}_{gd}}{4 sin {αsin}^{2} \frac{α}{2}} = - \frac{{Q}_{gd}}{2 ( 1 - {f}_{C} ) \sqrt{1 - {f}_{C}^{2}}}\end{matrix} \qquad ( 99 )$$

Similarly, according to the general definition of electric power, apparent power is calculated as indicated by the following formula:

$$\begin{matrix}S = \sqrt{{P}^{2} + {Q}^{2}} \\ = \sqrt{{( \frac{{P}_{gd} - {Q}_{gd} cos α}{4 {sin}^{2} {αsin}^{2} \frac{α}{2}} )}^{2} + {( \frac{{Q}_{gd}}{4 sin {αsin}^{2} \frac{α}{2}} )}^{2}} \\ = \frac{\sqrt{{P}_{gd}^{2} - 2 {P}_{gd} {Q}_{gd} cos α + {Q}_{gd}^{2}}}{4 {sin}^{2} α {sin}^{2} \frac{α}{2}} \\ = \frac{\sqrt{{P}_{gd}^{2} - 2 {P}_{gd} {Q}_{gd} {f}_{C} + {Q}_{gd}^{2}}}{2 ( 1 + {f}_{C} ) {( 1 - {f}_{C} )}^{2}}\end{matrix} \qquad ( 100 )$$

Similarly, a power factor is calculated as indicated by the following formula:]

$$\begin{matrix}PF = \frac{P}{S} \\ = \frac{{P}_{gd} - {Q}_{gd} cos α}{4 {sin}^{2} α {sin}^{2} \frac{α}{2}} \frac{4 {sin}^{2} {αsin}^{2} \frac{α}{2}}{\sqrt{{P}_{gd}^{2} - 2 {P}_{gd} {Q}_{gd} cos α + {Q}_{gd}^{2}}} \\ = \frac{{P}_{gd} - {Q}_{gd} cos α}{\sqrt{{P}_{gd}^{2} - 2 {P}_{gd} {Q}_{gd} cos α + {Q}_{gd}^{2}}} \\ = \frac{{P}_{gd} - {Q}_{gd} {f}_{C}}{\sqrt{{P}_{gd}^{2} - 2 {P}_{gd} {Q}_{gd} {f}_{C} + {Q}_{gd}^{2}}}\end{matrix} \qquad ( 101 )$$

(Gauge Differential Power Symmetry Index)

A method of using gauge differential power as an index for evaluating the symmetry of an input waveform is explained. A gauge differential power symmetry index is defined as indicated by the following formula:

S_{sym2}=|(cos φ)_{VI2}−(cos φ)_{PF2}| (102)

In the formula, (cos φ)_{VI2} and (cos φ)_{PF2} are cosine values of the voltage-current phase angle φ calculated as follows:

$$\{ \begin{matrix}{( cos φ )}_{VI 2} = \frac{{P}_{gd} - {Q}_{gd} cos α}{4 VI {sin}^{2} {αsin}^{2} \frac{α}{2}} = \frac{{P}_{gd} - {Q}_{gd} {f}_{C}}{{V}_{gd} {I}_{gd}} \\ {( cos φ )}_{PF 2} = PF = \frac{{P}_{gd} - {Q}_{gd} {f}_{C}}{{P}_{gd}^{2} - 2 {P}_{gd} {Q}_{gd} {f}_{C} + {Q}_{gd}^{2}}\end{matrix} \qquad ( 103 )$$

In Formula (102), if an input waveform is a pure sine wave, the gauge differential power symmetry index is zero.

On the other hand, when the gauge differential power symmetry index is larger than a predetermined threshold, that is, when the gauge differential power symmetry index is in a relation of the following formula with respect to a threshold S_{BRK2}, it is determined that the input waveform is not the pure sine wave because the symmetry of the input waveform is broken. In this case, a measured value (a calculated value) is latched according to necessity.

S_{sym2}=|(cos φ)_{VI2}−(cos φ)_{PF2}|≧S_{BRK2} (104)

(Distance Protection Calculation Formula)

A calculation formula for distance protection is presented. First, according to the definition of impedance, the following calculation formula is obtained:

$$\begin{matrix}Z = \frac{v ( t )}{i ( t )} \\ = \frac{V}{I} {e}^{jφ} \\ = \frac{V}{I} ( cos φ + jsin φ ) \\ = \frac{1}{4 {I}^{2} {sin}^{2} {αsin}^{2} \frac{α}{2}} ( {P}_{gd} - {Q}_{gd} cos α - j {Q}_{gd} sin α ) \\ = \frac{1}{{I}_{gd}^{2}} ( {P}_{gd} - {Q}_{gd} {f}_{C} - j {Q}_{gd} \sqrt{1 - {f}_{C}^{2}} )\end{matrix} \qquad ( 105 )$$

From a real part and an imaginary part of the above formula, resistance and inductance can be calculated as indicated by the following formula:

$$\{ \begin{matrix}R = \frac{{P}_{gd} - {Q}_{gd} {f}_{C}}{{I}_{gd}^{2}} \\ L = \frac{- {Q}_{gd} \sqrt{1 - {f}_{C}^{2}}}{2 π f {I}_{gd}^{2}}\end{matrix} \qquad ( 106 )$$

In the above formula, I_{gd} represents a gauge differential current and f represents a measured frequency. In distance protection in which a gauge differential power group is used, compared with distance protection in which a gauge power group is used, because the distance protection is not affected by a direct-current offset due to CT saturation, it is possible to perform more highly accurate measurement (calculation).

A coefficient distance k is calculated using the following formula:

$$k = \frac{L}{{L}_{0}} \times 100 \% \qquad ( 107 )$$

In the formula, L₀ represents the inductance of the entire length of a power transmission line and L represents inductance calculated by Formula (106). For example, if k=50%, this means that a failure occurs in the intermediate point of the power transmission line.

(Distance Protection Symmetry Index)

A method of using a result of a distance protection calculation as an index for evaluating the symmetry of an input waveform is explained. A distance protection symmetry index is defined as indicated by the following formula:

S_{DZ}=|L_{g}−L_{gd}| (108)

In the formula, L_{g} and L_{gd} are inductances calculated as follows:

$$\{ \begin{matrix}{L}_{g} = \frac{- {Q}_{g} \sqrt{1 - {f}_{C}}}{2 π f {I}_{g}^{2}} \\ {L}_{gd} = \frac{- {Q}_{gd} \sqrt{1 - {f}_{C}}}{2 π f {I}_{gd}^{2}}\end{matrix} \qquad ( 109 )$$

In Formula (109), if an input waveform is a pure sine wave, the distance protection symmetry index is zero.

On the other hand, when the distance protection symmetry index is larger than a predetermined threshold, that is, when the distance protection symmetry index is in a relation of the following formula with respect to a threshold S_{DZBRK}, it is determined that the input waveform is not the pure sine wave because the symmetry of the input waveform is broken. In this case, measured values (resistance and inductance) are latched according to necessity.

S_{DZ}=L_{g}−L_{gd}|≧S_{DZBRK} (110)

(Out-of-Step Protection Calculation Formula)

In Formula (82), the calculation formula for calculating an out-of-step center voltage using a gauge current and gauge power is shown. On the other hand, a calculation formula for calculating an out-of-step center voltage using a gauge differential current and gauge differential power is as indicated by the following formula:

$$\begin{matrix}{V}_{C} = V cos {φ}_{vi} \\ = V \frac{{P}_{gd} - {Q}_{gd} cos α}{4 V I {sin}^{2} {αsin}^{2} \frac{α}{2}} \\ = \frac{{P}_{gd} - {Q}_{gd} cos α}{2 {I}_{gd} sin αsin \frac{α}{2}} \\ = \frac{\sqrt{2} ( {P}_{gd} - {Q}_{gd} {f}_{C} )}{2 {I}_{gd} ( 1 - {f}_{C} ) \sqrt{1 + {f}_{C}}}\end{matrix} \qquad ( 111 )$$

In distance protection in which a gauge differential power group is used, compared with distance protection in which a gauge power group is used, because the distance protection is not affected by a direct-current offset due to CT saturation, it is possible to perform more highly accurate measurement (calculation).

(Out-of-Step Protection Symmetry Index)

A method of using a calculation result of an out-of-step center voltage as an index for evaluating the symmetry of an input waveform is explained. An out-of-step protection symmetry index is defined as indicated by the following formula:

S_{OUT}=|V_{Cg}−V_{Cgd}| (112)

In the formula, V_{Cg} and V_{Cgd} are out-of-step center voltages calculated as follows:

$$\{ \begin{matrix}{V}_{Cg} = \frac{{P}_{g} - {Q}_{g} {f}_{C}}{{I}_{g} \sqrt{1 - {f}_{C}^{2}}} \\ {V}_{Cgd} = \frac{\sqrt{2} ( {P}_{gd} - {Q}_{gd} {f}_{C} )}{2 {I}_{gd} ( 1 - {f}_{C} ) \sqrt{1 + {f}_{C}}}\end{matrix} \qquad ( 113 )$$

In Formula (113), if an input waveform is a pure sine wave, the out-of-step protection symmetry index is zero.

On the other hand, when the out-of-step protection symmetry index is larger than a predetermined threshold, that is, when the out-of-step protection symmetry index is in a relation of the following formula with respect to a threshold S_{VCBRK}, it is determined that the input waveform is not the pure sine wave because the symmetry of the input waveform is broken. In this case, a measured value (an out-of-step center voltage) is latched according to necessity.

S_{OUT}=|V_{Cg}−V_{Cgd}|≧S_{VCBRK} (114)

When it is desired to reduce the influence of noise, a plurality of sampling data only have to be used. A calculation formula for gauge differential active power in a plurality of gauge differential active power symmetry groups is as indicated by the following formula:

$${P}_{gd} = \frac{1}{n - 2} ( {\sum }_{k = 2}^{n - 1} ( {v}_{2 k} {i}_{2 k} - {v}_{2 ( k - 1 )} {i}_{2 ( k + 1 )} ) ) = 4 VI sin {αsin}^{2} \frac{α}{2} sin ( α - φ ) , \\ n \geq 3 \qquad ( 115 )$$

A calculation formula for gauge differential reactive power in a plurality of gauge differential reactive power symmetry groups is as indicated by the following formula:

$${Q}_{gd} = \frac{1}{n - 2} ( {\sum }_{k = 2}^{n - 1} ( {v}_{2 ( k + 1 )} {i}_{2 k} - {v}_{2 k} {i}_{2 ( k + 1 )} ) ) = - 4 VI sin {αsin}^{2} \frac{α}{2} sin φ , \\ n \geq 3 \qquad ( 116 )$$

Time series data of voltage instantaneous values and current instantaneous values is calculated using the following formula:

$$\{ \begin{matrix}{v}_{2 k} = Re \{ {v}_{2} [ t - ( k - 1 ) T ] \} , & k = 1 , 2 , … , n \\ {i}_{2 k} = Re \{ {i}_{2} [ t - ( k - 1 ) T ] \} , & k = 1 , 2 , … , n\end{matrix} \qquad ( 117 )$$

Time series data of a voltage vector and a current vector is calculated using the following formula:

$$\{ \begin{matrix}{v}_{2} [ t - ( k - 1 ) T ] = V {e}^{j [ ω t - ( k - 1 ) α ]} - V {e}^{j [ ω t - ( k - 2 ) α ]} , & k = 1 , 2 , … , n \\ {i}_{2} [ t - ( k - 1 ) T ] = I {e}^{j [ ω t - ( k - 1 ) α + φ ]} - I {e}^{j [ ω t - ( k - 2 ) α + φ ]} , & k = 1 , 2 , … , n\end{matrix} \qquad ( 118 )$$

(Inter-Bus Phase Difference)

A phase difference (an inter-bus phase difference) of rotation vectors between one terminal (hereinafter referred to as “terminal 1”) on a certain bus (or a power transmission line) and the other terminal (hereinafter referred to as “terminal 2”) on the same bus that occurs when the rotation vectors of both the terminals 1 and 2 have the same frequency is explained. In an example explained below, the rotation vectors are voltage vectors. However, it goes without saying that the phase difference can be applied to rotation vectors other than the voltage vectors. When the frequencies of the rotation vectors in the terminals 1 and 2 are different, a space synchronized phasor explained below only has to be used.

(Calculation of an Inter-Bus Voltage Phase Difference)

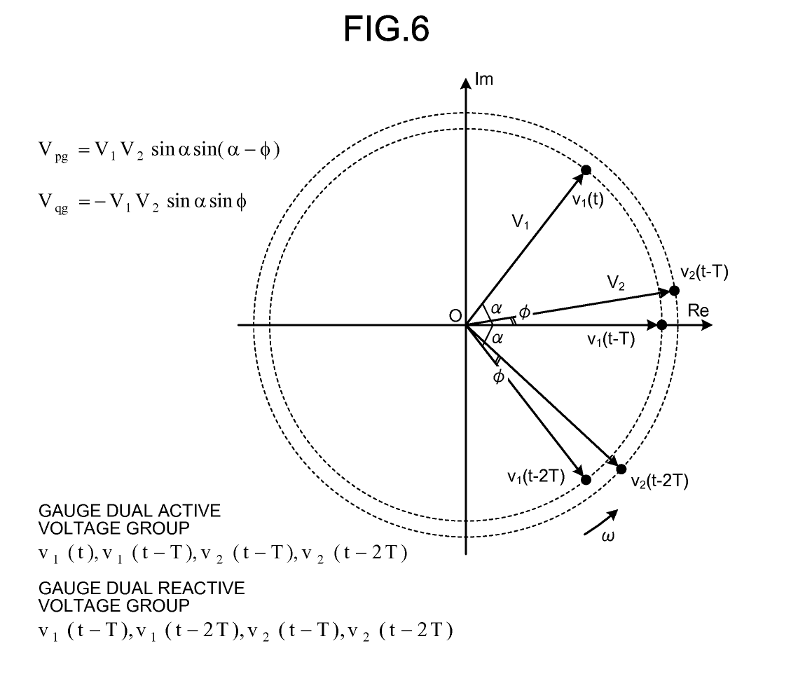

FIG. 6 is a diagram of a gauge dual voltage group on a complex plane. In FIG. 6, the three voltage vectors v₁(t), v₁(t−T), and v₁(t−2T) of a voltage instantaneous value V₁ rotating counterclockwise at a real frequency on the complex plane in the terminal 1 and two voltage vectors v₂(t−T) and v₂(t−2T) of a voltage instantaneous value V₂ rotating counterclockwise at the real frequency on the complex plane in the terminal 2 are shown. The three voltage vectors v₁(t), v₁(t−T), and v₁(t−2T) and the two voltage vectors v₂(t−T) and v₂(t−2T) can be respectively represented as indicated by the following formulas:

$$\begin{matrix}\{ \begin{matrix}{v}_{1} ( t ) = {V}_{1} {e}^{j ( ω t + α )} \\ {v}_{1} ( t - T ) = {V}_{1} {e}^{j ( ω t )} \\ {v}_{1} ( t - 2 T ) = {V}_{1} {e}^{j ( ω t - α )}\end{matrix} & ( 119 ) \\ \{ \begin{matrix}{v}_{2} ( t - T ) = {V}_{2} {e}^{j ( ω t + φ )} \\ {v}_{2} ( t - 2 T ) = {V}_{2} {e}^{j ( ω t - α + φ )}\end{matrix} & ( 120 )\end{matrix}$$

(Gauge Dual Voltage Group, Gauge Dual Active Voltage Group, and Gauge Dual Reactive Voltage Group)

The three voltage vectors v₁(t), v₁(t−T), and v₁(t−2T) in the terminal 1 and the two voltage vectors v₂(t−T) and v₂(t−2T) in the terminal 2 are defined as a “gauge dual voltage group”. Among the rotation vectors forming the gauge dual voltage group, the two voltage vectors v₁(t) and v₁(t−T) and the two voltage vectors v₂(t−T) and v₂(t−2T) are defined as a “gauge dual active voltage group”. The two voltage vectors v₁(t−T) and v₁(t−2T) and the two voltage vectors v₂(t−T) and v₂(t−2T) are defined as a “gauge dual reactive voltage group”. The terms “active” and “reactive” in the “gauge dual active voltage group” and the “gauge dual reactive voltage group” are used because the “gauge dual active voltage group” and the “gauge dual reactive voltage group” are similar to the “gauge active power group” and the “gauge reactive power group” in terms of structure.

(Gauge Dual Active Voltage)

A gauge dual active voltage is defined as indicated by the following formula using the gauge dual active voltage group:

V_{pg}=v₁₂v₂₂−v₁₁v₂₃ (121)

In the formula, voltage instantaneous values v₁₁ and v₁₂ of the terminal 1 are respectively real parts of the voltage vectors v₁(t) and v₁(t−T) and calculated as indicated by the following formula:

$$\{ \begin{matrix}{v}_{11} = Re [ {v}_{1} ( t ) ] = {V}_{1} cos ( ω t + α ) \\ {v}_{12} = Re [ {v}_{1} ( t - T ) ] = {V}_{1} cos ( ω t )\end{matrix} \qquad ( 122 )$$

Similarly, voltage instantaneous values v₂₂ and v₂₃ of the terminal 2 are respectively real parts of the voltage vectors v₂(t−T) and v₂(t−2T) and calculated as indicated by the following formula:

$$\{ \begin{matrix}{v}_{22} = Re [ {v}_{2} ( t - T ) ] = {V}_{2} cos ( ω t + φ ) \\ {v}_{23} = Re [ {v}_{2} ( t - 2 T ) ] = {V}_{2} cos ( ω t - α + φ )\end{matrix} \qquad ( 123 )$$

If Formulas (122) and (123) are substituted in Formula (121), the calculation formula representing the gauge dual active voltage is converted as indicated by the following formula:

$$\begin{matrix}{V}_{pg} = {v}_{12} {v}_{22} - {v}_{11} {v}_{23} \\ = {V}_{1} {V}_{2} [ cos ( ω t ) cos ( ω t + φ ) - cos ( ω t + α ) cos ( ω t - α + φ ) ] \\ = \frac{{V}_{1} {V}_{2}}{2} [ cos ( 2 ω t + φ ) + cos φ - cos ( 2 ω t + φ ) - cos ( 2 α - φ ) ] \\ = \frac{{V}_{1} {V}_{2}}{2} [ cos ϕ ( 1 - cos 2 α ) - sin ( 2 α ) sin φ ] \\ = {V}_{1} {V}_{2} sin αsin ( α - φ )\end{matrix} \qquad ( 124 )$$

That is, the calculation formula for the gauge dual active voltage can be represented as indicated by the following formula:

V_{pg}=V₁V₂ sin α sin(α−φ) (125)

(Gauge Dual Reactive Voltage)

A gauge dual reactive voltage is defined as indicated by the following formula using the gauge dual reactive voltage group.

V_{qg}=v₁₃v₁₂−v₁₂v₂₃ (126)

In the formula, voltage instantaneous values v₁₂ and v₁₃ of the terminal 1 are respectively real parts of the voltage vectors v₁(t−T) and v₁(t−2T) and calculated as indicated by the following formula:

$$\{ \begin{matrix}{v}_{12} = Re [ {v}_{1} ( t - T ) ] = {V}_{1} cos ( ω t ) \\ {v}_{13} = Re [ {v}_{1} ( t - 2 T ) ] = {V}_{1} cos ( ω t + α )\end{matrix} \qquad ( 127 )$$

Voltage instantaneous values v₂₂ and v₂₃ of the terminal 2 are defined as indicated by Formula (123). If Formula (123) and Formula (127) are substituted in Formula (126), the calculation formula representing the gauge dual reactive voltage is converted as indicated by the following formula:

$$\begin{matrix}{V}_{qg} = {v}_{13} {v}_{22} - {v}_{12} {v}_{23} \\ = {V}_{1} {V}_{2} [ cos ( ω t - α ) cos ( ω t + φ ) - cos ( ω t ) cos ( ω t - α + φ ) ] \\ = \frac{{V}_{1} {V}_{2}}{2} [ \begin{matrix}cos ( 2 ω t - α + φ ) + cos ( α + φ ) - \\ cos ( 2 ω t - α + φ ) - cos ( α - φ )\end{matrix} ] \\ = \frac{{V}_{1} {V}_{2}}{2} [ cos ( α + φ ) - cos ( α - φ ) ] \\ = - {V}_{1} {V}_{2} sin α sin φ\end{matrix} \qquad ( 128 )$$

That is, the calculation formula for the gauge dual reactive voltage can be represented as indicated by the following formula:

V_{qg}=−V₁V₂ sin α sin φ (129)

From Formula (125) an Formula (129), a cosine value and a sine value of a voltage phase angle difference φ between the terminals 1 and 2 (hereinafter simply referred to as “voltage phase angle difference φ”) can be calculated using the following formula:

$$\begin{matrix}\{ \begin{matrix}cos φ = \frac{{V}_{pg} - {V}_{qg} cos α}{{V}_{1} {V}_{2} {sin}^{2} α} \\ sin φ = - \frac{{V}_{qg}}{{V}_{1} {V}_{2} sin α}\end{matrix} & ( 130 )\end{matrix}$$

Therefore, the voltage phase angle difference φ is calculated as indicated by the following formula using the above formula:

$$φ = \{ \begin{matrix}{cos}^{- 1} ( \frac{{V}_{pg} - {V}_{qg} {f}_{C}}{{V}_{1 g} {V}_{2 g}} ) , & {V}_{qg} \leq 0 \\ - {cos}^{- 1} ( \frac{{V}_{pg} - {V}_{qg} {f}_{C}}{{V}_{1 g} {V}_{2 g}} ) , & {V}_{qg} > 0\end{matrix} \qquad ( 131 )$$

There is a relation of the following formula between gauge voltages and voltage amplitudes in the terminals 1 and 2:

$$\{ \begin{matrix}{V}_{1 g} = {V}_{1} sin α \\ {V}_{2 g} = {V}_{2} sin α\end{matrix} \qquad ( 132 )$$

As indicated by the following formula, it is also possible to directly calculate a cosine of the voltage phase angle difference φ using V_{pg}, V_{qg}, and f_{C}:

$$\begin{matrix}{( cos φ )}_{V 12} = \frac{cos φ}{\sqrt{{sin}^{2} φ + {cos}^{2} φ}} \\ = \frac{{V}_{pg} - {V}_{qg} cos α}{{V}_{1} {V}_{2} {sin}^{2} α} \frac{1}{\sqrt{{( \frac{{V}_{qg}}{{V}_{1} {V}_{2} sin α} )}^{2} + {( \frac{{V}_{pg} - {V}_{qg} cos α}{{V}_{1} {V}_{2} {sin}^{2} α} )}^{2}}} \\ = \frac{{V}_{pg} - {V}_{qg} cos α}{\sqrt{{V}_{pg}^{2} - 2 {V}_{pg} {V}_{qg} cos α + {V}_{qg}^{2}}} \\ = \frac{{V}_{pg} - {V}_{qg} {f}_{C}}{\sqrt{{V}_{pg}^{2} - 2 {V}_{pg} {V}_{qg} {f}_{C} + {V}_{qg}^{2}}}\end{matrix} \qquad ( 133 )$$

(Gauge Dual Voltage Symmetry Index)

A method of using a gauge dual voltage as an index for evaluating the symmetry of an input waveform is explained. A gauge dual voltage symmetry index is defined as indicated by the following formula:

V_{2sym1}=|(cos φ)_{V11}−(cos φ)_{V12}| (134)

In the formula, (cos φ)_{V11} and (cos φ)_{V12} are cosine values of the voltage phase angle difference φ calculated as follows:

$$\{ \begin{matrix}{( cos φ )}_{V 11} = \frac{{V}_{pg} - {V}_{qg} cos α}{{V}_{1} {V}_{2} {sin}^{2} α} = \frac{{V}_{pg} - {V}_{qg} {f}_{C}}{{V}_{1 g} {V}_{2 g}} \\ {( cos φ )}_{V 12} = \frac{{V}_{pg} - {V}_{qg} {f}_{C}}{\sqrt{{V}_{pg}^{2} - 2 {V}_{pg} {V}_{qg} {f}_{C} + {V}_{qg}^{2}}}\end{matrix} \qquad ( 135 )$$

In Formula (134), if an input waveform is a pure sine wave, the gauge dual voltage symmetry index is zero.

On the other hand, when the gauge dual voltage symmetry index is larger than a predetermined threshold, that is, when the gauge dual voltage symmetry index is in a relation of the following formula with respect to a threshold V_{2BRK1}, it is determined that the input waveform is not the pure sine wave because the symmetry of the input waveform is broken. In this case, a measured value (a voltage phase angle difference) is latched according to necessity.

V_{2sym1}=|(cos φ)_{V11}−(cos φ)_{V12}|≧V_{2BRK1} (136)

When it is desired to reduce the influence of noise, a plurality of sampling data only have to be used. A calculation formula for a gauge dual active voltage in a plurality of gauge dual active voltage groups is as indicated by the following formula:

$${V}_{pg} = \frac{1}{n - 2} ( {\sum }_{k = 2}^{n - 1} ( {v}_{1 k} {v}_{2 k} - {v}_{1 ( k - 1 )} {v}_{2 ( k + 1 )} ) ) = {V}_{1} {V}_{2} sin α sin ( α - φ ) , \\ n \geq 3 \qquad ( 137 )$$

A calculation formula for a gauge dual reactive voltage in a plurality of gauge dual reactive voltage group is as indicated by the following formula:

$${V}_{qg} = \frac{1}{n - 2} ( {\sum }_{k = 2}^{n - 1} ( {v}_{1 ( k + 1 )} {v}_{2 k} - {v}_{1 k} {v}_{2 ( k + 1 )} ) ) = - {V}_{1} {V}_{2} sin α sin φ , n \geq 3 \qquad ( 138 )$$

Time series data of voltage instantaneous values in the terminals is calculated using the following formula:

$$\begin{matrix}{v}_{1 k} = Re \{ {v}_{1} [ t - ( k - 1 ) T ] \} , & k = 1 , 2 , … , n \\ {v}_{2 k} = Re \{ {v}_{2} [ t - ( k - 1 ) T ] \} , & k = 1 , 2 , … , n\end{matrix} \} \qquad ( 139 )$$

Time series data of voltage vectors in the terminals is calculated using the following formula:

$$\begin{matrix}{v}_{1} [ t - ( k - 1 ) T ] = {V}_{1} {e}^{j [ ω t - ( k - 1 ) α ]} , & k = 1 , 2 , … , n \\ {v}_{2} [ t - ( k - 1 ) T ] = {V}_{2} {e}^{j [ ω t - ( k - 1 ) α + φ ]} , & k = 1 , 2 , … , n\end{matrix} \} \qquad ( 140 )$$

(Gauge Dual Differential Voltage Group, Gauge Dual Differential Active Voltage Group, and Gauge Dual Differential Reactive Voltage Group)

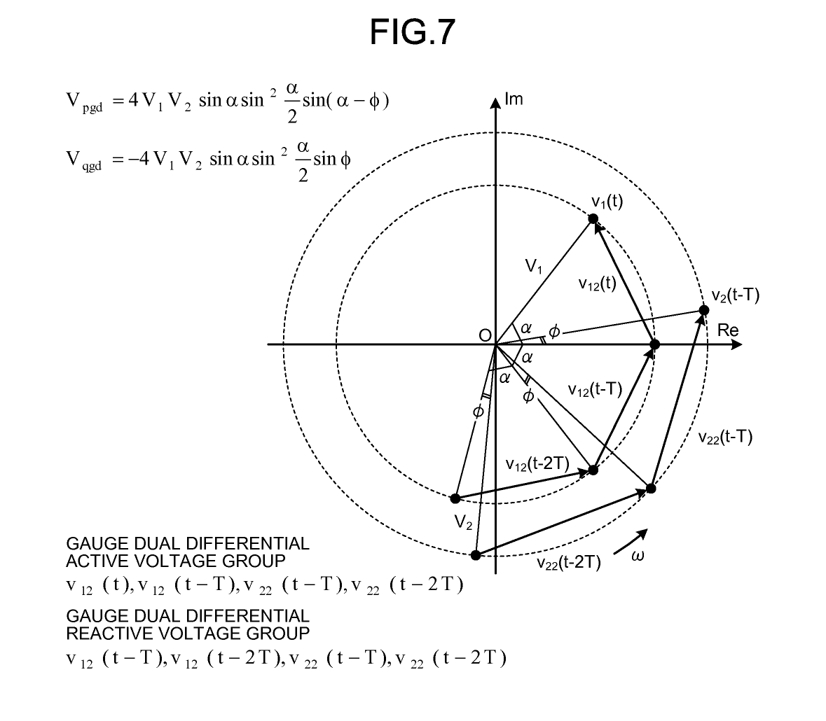

FIG. 7 is a diagram of a gauge dual differential voltage group on a complex plane. In FIG. 7, three differential voltage vectors v₁₂(t), v₁₂(t−T), and v₁₂(t−2T) of the voltage instantaneous value V₁ rotating counterclockwise at a real frequency on the complex plane in the terminal 1 and two differential voltage vectors v₂₂(t−T) an v₂₂(t−2T) of the voltage instantaneous value V₂ rotating counterclockwise at the real frequency on the complex plane in the terminal 2 are shown. The three differential voltage vectors v₁₂(t), v₁₂(t−T), and v₁₂(t−2T) and the two differential voltage vectors v₂₂(t−T) an v₂₂(t−2T) can be respectively represented as indicated by the following formulas:

$$\begin{matrix}\{ \begin{matrix}{v}_{12} ( t ) = {v}_{1} ( t ) - {v}_{1} ( t - T ) = {V}_{1} {e}^{j ( ω t + α )} - {V}_{1} {e}^{j ω t} \\ {v}_{12} ( t - T ) = {v}_{1} ( t - T ) - {v}_{1} ( t - 2 T ) = {V}_{1} {e}^{j ω t} - {V}_{1} {e}^{j ( ω t - α )} \\ {v}_{12} ( t - 2 T ) = {v}_{1} ( t - 2 T ) - {v}_{1} ( t - 3 T ) = {V}_{1} {e}^{j ( ω t - α )} - {V}_{1} {e}^{j ( ω t - 2 α )}\end{matrix} & ( 141 ) \\ \{ \begin{matrix}{v}_{22} ( t - T ) = {v}_{2} ( t - T ) - {v}_{2} ( t - 2 T ) = {V}_{2} {e}^{j ( ω t + φ )} - {V}_{2} {e}^{j ( ω t - α + φ )} \\ {v}_{22} ( t - 2 T ) = {v}_{2} ( t - 2 T ) - {v}_{2} ( t - 3 T ) = {V}_{2} {e}^{j ( ω t - α + φ )} - {V}_{2} {e}^{j ( ω t - 2 α + φ )}\end{matrix} & ( 142 )\end{matrix}$$

The three differential voltage vectors v₁₂(t), v₁₂(t−T), and v₁₂(t−2T) in the terminal 1 and the two differential voltage vectors v₂₂(t−T) an v₂₂(t−2T) in the terminal 2 are defined as a “gauge dual differential voltage group”. Among the rotation vectors forming the gauge dual voltage group, the two differential voltage vectors v₁₂(t) and v₁₂(t−T) and the two differential voltage vectors v₂₂(t−T) an v₂₂(t−2T) are defined as a “gauge dual differential active voltage group”. The two differential voltage vectors v₁₂(t−T) and v₁₂(t−2T) and the two differential voltage vectors v₂₂(t-T) an v₂₂(t−2T) are defined as a “gauge dual differential reactive voltage group”.

(Gauge Dual Differential Active Voltage)

A gauge dual differential active voltage is defined as indicated by the following formula using the gauge dual differential active voltage group.

V_{pgd}=v₁₂₂v₂₂₂−v₁₂₁v₂₂₃ (143)

In the formula, voltage instantaneous values V₁₂₁ and V₁₂₂ of the terminal 1 are respectively real parts of the differential voltage vectors v₁₂(t) and v₁₂(t−T) and calculated as indicated by the following formula:

$$\{ \begin{matrix}{v}_{121} = Re [ {v}_{12} ( t ) ] = {V}_{1} cos ( ω t + α ) - {V}_{1} cos ( ω t ) \\ {v}_{122} = Re [ {v}_{12} ( t - T ) ] = {V}_{1} cos ( ω t ) - {V}_{1} cos ( ω t - α )\end{matrix} \qquad ( 144 )$$

Similarly, voltage instantaneous values V₂₂₂ and V₂₂₃ of the terminal 2 are respectively real parts of the differential voltage vectors v₂₂(t−T) and v₂₂(t−2T) and calculated as indicated by the following formula:

$$\{ \begin{matrix}{v}_{222} = Re [ {v}_{2} ( t - T ) ] = {V}_{2} cos ( ω t + φ ) - {V}_{2} cos ( ω t - α + φ ) \\ {v}_{223} = Re [ {v}_{2} ( t - 2 T ) ] = {V}_{2} cos ( ω t - α + φ ) - {V}_{2} cos ( ω t - 2 α + φ )\end{matrix} \qquad ( 145 )$$

If Formulas (144) and (145) are substituted in Formula (143), the calculation formula representing the gauge dual differential active voltage is converted as indicated by the following formula:

$$\begin{matrix}{V}_{pgd} = {v}_{122} {v}_{222} - {v}_{121} {v}_{223} \\ = {V}_{1} {V}_{2} \{ \begin{matrix}\begin{matrix}[ cos ( ω t ) - cos ( ω t - α ) ] \\ [ cos ( ω t + φ ) - cos ( ω t - α + φ ) ] - \\ [ cos ( ω t + α ) - cos ( ω t ) ]\end{matrix} \\ [ cos ( ω t - α + φ ) - cos ( ω t - 2 α + φ ) ]\end{matrix} \} \\ = VI [ \begin{matrix} cos ( ω t ) cos ( ω t + φ ) - \\ cos ( ω t ) cos ( ω t - α + φ ) - \\ cos ( ω t - α ) cos ( ω t + φ ) + \\ cos ( ω t - α ) cos ( ω t - α + φ ) - \\ cos ( ω t + α ) cos ( ω t - α + φ ) + \\ cos ( ω t + α ) cos ( ω t - 2 α + φ ) + \\ cos ( ω t ) cos ( ω t - α + φ ) - \\ cos ( ω t ) cos ( ω t - 2 α + ϕ )\end{matrix} ] \\ = \frac{{V}_{1} {V}_{2}}{2} [ \begin{matrix} cos ( 2 ω t + φ ) + cos φ - \\ cos ( 2 ω t - α + φ ) - cos ( α - φ ) - \\ cos ( 2 ω t - α + φ ) - cos ( α + φ ) + \\ cos ( 2 ω t - 2 α + φ ) + \\ cos ( φ ) - cos ( 2 ω t + φ ) - \\ cos ( 2 α - φ ) + cos ( 2 ω t - α + φ ) + \\ cos ( 3 α - φ ) + cos ( 2 ω t - α + φ ) + \\ cos ( α - φ ) - cos ( 2 ω t - 2 α + φ ) - \\ cos ( 2 α - φ )\end{matrix} ] \\ = \frac{{V}_{1} {V}_{2}}{2} [ 2 cos φ - 2 cos ( 2 α - φ ) - cos ( α + φ ) + \\ cos ( 3 α - φ ) ] \\ = 4 {V}_{1} {V}_{2} sin {αsin}^{2} \frac{α}{2} sin ( α - φ )\end{matrix} \qquad ( 146 )$$

That is, the calculation formula for the gauge dual differential active voltage can be represented as indicated by the following formula:

$${V}_{pgd} = 4 {V}_{1} {V}_{2} sin {αsin}^{2} \frac{α}{2} sin ( α - φ ) \qquad ( 147 )$$

(Gauge Dual Differential Reactive Voltage)

A gauge dual differential reactive voltage is defined as indicated by the following formula using the gauge dual differential reactive voltage group:

V_{qgd}=v₁₂₃v₂₂₂−v₁₂₂−v₂₂₃ (148)

In the formula, differential voltage instantaneous values v₁₂₂ and v₁₂₃ of the terminal 1 are respectively real parts of the differential voltage vectors v₁₂(t−T) and v₁₂(t−2T) and calculated as indicated by the following formula:

$$\begin{matrix}\{ \begin{matrix}{v}_{122} = Re [ {v}_{1} ( t - T ) - {v}_{1} ( t - 2 T ) ] = {V}_{1} cos ( ω t ) - {V}_{1} cos ( ω t - α ) \\ {v}_{123} = Re [ {v}_{1} ( t - 2 T ) - {v}_{1} ( t - 3 T ) ] = {V}_{1} cos ( ω t - α ) - {V}_{1} cos ( ω t - 2 α )\end{matrix} & ( 149 )\end{matrix}$$

Differential voltage instantaneous values v₂₂₂ and v₂₂₃ of the terminal 2 are defined as indicated by Formula (145). If Formula (145) and Formula (149) are substituted in Formula (148), the calculation formula representing the gauge dual differential reactive voltage is converted as indicated by the following formula:

$${V}_{qgd} = {v}_{123} {v}_{222} - {v}_{122} {v}_{223} = {V}_{1} {V}_{2} \{ \begin{matrix}\begin{matrix}\begin{matrix}[ cos ( ω t - α ) - cos ( ω t - 2 α ) ] \\ [ cos ( ω t + φ ) - cos ( ω t - α + φ ) ] -\end{matrix} \\ [ cos ( ω t ) - cos ( ω t - α ) ]\end{matrix} \\ [ cos ( ω t - α + φ ) - cos ( ω t - 2 α + φ ) ]\end{matrix} \} = VI [ \begin{matrix}\begin{matrix}\begin{matrix}\begin{matrix}\begin{matrix}cos ( ω t - α ) cos ( ω t + φ ) - \\ cos ( ω t - α ) cos ( ω t - α + φ ) -\end{matrix} \\ cos ( ω t - 2 α ) cos ( ω t + φ ) +\end{matrix} \\ cos ( ω t - 2 α ) cos ( ω t - α + φ ) -\end{matrix} \\ cos ( ω t ) cos ( ω t - α + φ ) +\end{matrix} \\ cos ( ω t ) cos ( ω t - 2 α + φ ) + \\ cos ( ω t - α ) cos ( ω t - α + φ ) - \\ cos ( ω t - α ) cos ( ω t - 2 α + φ )\end{matrix} ] = \frac{{V}_{1} {V}_{2}}{2} [ \begin{matrix}\begin{matrix}\begin{matrix}\begin{matrix}\begin{matrix}cos ( 2 ω t - α + φ ) + cos ( α + φ ) - \\ cos ( 2 ω t - 2 α + φ ) - cos φ -\end{matrix} \\ cos ( 2 ω t - 2 α + φ ) - cos ( 2 α + φ ) +\end{matrix} \\ cos ( 2 ω t - 3 α + φ ) + cos ( α + φ ) -\end{matrix} \\ cos ( 2 ω t - α + φ ) - cos ( α - φ ) +\end{matrix} \\ cos ( 2 ω t - 2 α + φ ) + cos ( 2 α - φ ) + \\ cos ( 2 ω t - 2 α + φ ) + cos φ - \\ cos ( 2 ω t - 3 α + φ ) - cos ( α - φ )\end{matrix} ] = \frac{{V}_{1} {V}_{2}}{2} [ \begin{matrix}2 cos ( α + φ ) - 2 cos ( α - φ ) + \\ cos ( 2 α - φ ) - cos ( 2 α + φ )\end{matrix} ] = - 4 {V}_{1} {V}_{2} sin {αsin}^{2} \frac{α}{2} sin φ \qquad ( 150 )$$

That is, the calculation formula for the gauge dual differential reactive voltage can be represented as indicated by the following formula:

$${V}_{qgd} = - 4 {V}_{1} {V}_{2} sin α {sin}^{2} \frac{α}{2} sin φ \qquad ( 151 )$$

From Formula (147) and Formula (151), a cosine value and a sine value of the voltage phase angle difference φ between the terminals 1 and 2 can be calculated using the following formula: According to the above explanation, a cosine value and a sine value of the voltage phase angle difference can be calculated using the following formula:

$$\{ \begin{matrix}cos φ = \frac{{V}_{pgd} - {V}_{qgd} cos α}{4 {V}_{1} {V}_{2} {sin}^{2} α {sin}^{2} \frac{α}{2}} \\ sin φ = - \frac{{V}_{qgd}}{4 {V}_{1} {V}_{2} sin α {sin}^{2} \frac{α}{2} }\end{matrix} \qquad ( 152 )$$

Therefore, the voltage phase angle difference φ is calculated as indicated by the following formula using the above formula:

$$φ = \{ \begin{matrix}{cos}^{- 1} ( \frac{{V}_{pqd} - {V}_{qgd} {f}_{C}}{{V}_{1 gd} {V}_{2 gd}} ) , & {V}_{qgd} \leq 0 \\ - {cos}^{- 1} ( \frac{{V}_{pgd} - {V}_{qgd} cos α}{{V}_{1 gd} {V}_{2 gd}} ) , & {V}_{qgd} > 0\end{matrix} \qquad ( 153 )$$

There is a relation of the following formula between gauge differential voltages and differential voltage amplitudes in the terminals 1 and 2:

$$\{ \begin{matrix}{V}_{1 gd} = 2 {V}_{1} sin αsin \frac{α}{2} \\ {V}_{2 gd} = 2 {V}_{2} sin αs in \frac{α}{2}\end{matrix} \qquad ( 154 )$$

As indicated by the following formula, it is also possible to directly calculate the voltage phase angle difference φ using V_{pgd}, V_{qgd}, and f_{C}.

$$\begin{matrix}{( cos φ )}_{V 22} = \frac{cos φ}{\sqrt{{sin}^{2} φ + {cos}^{2} φ}} \\ = \frac{{V}_{pgd} - {V}_{qgd} cos α}{4 {V}_{1} {V}_{2} {sin}^{2} α {sin}^{2} \frac{α}{2}} \\ \frac{1}{\sqrt{{( \frac{{V}_{qgd}}{4 {V}_{1} {V}_{2} sin {αsin}^{2} \frac{α}{2}} )}^{2} + {( \frac{{V}_{pgd} - {V}_{qgd} cos α}{4 {V}_{1} {V}_{2} {sin}^{2} α {sin}^{2} \frac{α}{2}} )}^{2}}} \\ = \frac{{V}_{pgd} - {V}_{qgd} cos α}{\sqrt{{V}_{pgd}^{2} - 2 {V}_{pgd} {V}_{qgd} cos α + {V}_{qgd}^{2}}} \\ = \frac{{V}_{pgd} - {V}_{qgd} {f}_{C}}{\sqrt{{V}_{pgd}^{2} - 2 {V}_{pgd} {V}_{qgd} {f}_{C} + {V}_{qgd}^{2}}}\end{matrix} \qquad ( 155 )$$

(Gauge Dual Differential Voltage Symmetry Index)

A method of using a gauge dual differential voltage as an index for evaluating the symmetry of an input waveform is explained. A gauge dual differential voltage symmetry index is defined as indicated by the following formula:

V_{2sym2}=|(cos φ)_{V21}−(cos φ)_{V22}| (156)

In the formula, (cos φ)_{V21} and (cos φ)_{V22} are cosine values of the voltage phase angle difference φ calculated as follows:

$$\{ \begin{matrix}{( cos φ )}_{V 21} = \frac{{V}_{pgd} - {V}_{qgd} cos α}{4 {V}_{1} {V}_{2} {sin}^{2} {αsin}^{2} \frac{α}{2}} = \frac{{V}_{pgd} - {V}_{qgd} {f}_{C}}{{V}_{1 gd} {V}_{2 gd}} \\ {( cos φ )}_{V 22} = \frac{{V}_{pgd} - {V}_{qgd} {f}_{C}}{{V}_{pgd}^{2} - 2 {V}_{pgd} {V}_{qgd} {f}_{C} + {V}_{qgd}^{2}} \end{matrix} \qquad ( 157 )$$

In Formula (156), if an input waveform is a pure sine wave, the gauge dual differential voltage symmetry index is zero.

On the other hand, when the gauge dual differential voltage symmetry index is larger than a predetermined threshold, that is, when the gauge dual differential voltage symmetry index is in a relation of the following formula with respect to a threshold S_{2BRK2}, it is determined that the input waveform is not the pure sine wave because the symmetry of the input waveform is broken. In this case, a measured value (a voltage phase angle difference) is latched according to necessity.

V_{2sym2}=|(cos φ)_{V21}−(cos φ)_{V22}|≧V_{2BRK2} (158)

When it is desired to reduce the influence of noise, a plurality of sampling data only have to be used. A calculation formula for a gauge dual differential active voltage in a plurality of gauge dual differential active voltage groups is as indicated by the following formula:

$${V}_{pgd} = \frac{1}{n - 2} ( {\sum }_{k = 2}^{n - 1} ( {v}_{21 k} - {v}_{22 k} - {v}_{21 ( k - 1 )} {v}_{22 ( k + 1 )} ) ) = 4 {V}_{1} {V}_{2} sin {αsin}^{2} \frac{α}{2} sin ( α - φ ) , n \geq 3 \qquad ( 159 )$$

A calculation formula for a gauge dual differential reactive voltage in a plurality of gauge dual differential reactive voltage groups is as indicated by the following formula:

$${V}_{qgd} = \frac{1}{n - 2} ( {\sum }_{k = 2}^{n - 1} ( {v}_{21 ( k + 1 )} {v}_{22 k} - {v}_{21 k} {v}_{22 ( k + 1 )} ) ) = - 4 {V}_{1} {V}_{2} sin {αsin}^{2} \frac{α}{2} sin φ , n \geq 3 \qquad ( 160 )$$

Time series data of voltage instantaneous values in the terminals is calculated using the following formula:

$$\begin{matrix}{v}_{21 k} = Re \{ {v}_{21} [ t - ( k - 1 ) T ] \} , & k = 1 , 2 , … , n \\ {v}_{22 k} = Re \{ {v}_{22} [ t - ( k - 1 ) T ] \} , & k = 1 , 2 , … , n\end{matrix} \} \qquad ( 161 )$$

Time series data of voltage vectors in the terminals is calculated using the following formula:

$$\begin{matrix}{v}_{21} [ t - ( k - 1 ) T ] = {V}_{21} {e}^{j [ ω t - ( k - 1 ) α ]} - {V}_{21} {e}^{j [ ω t - ( k - 2 ) α ]} , k = 1 , 2 , … , n \\ {v}_{22} [ t - ( k - 1 ) T ] = {V}_{22} {e}^{j [ ω t - ( k - 1 ) α + φ ]} - {V}_{22} {e}^{j [ ω t - ( k - 2 ) α + φ ]} , k = 1 , 2 , … , n\end{matrix} \} \qquad ( 162 )$$

The above explanation can be applied to a gauge dual current group and a gauge dual differential current group. Expansion of a formula is omitted.

When a voltage phase angle difference is calculated as explained above, it is assumed that real frequencies in the terminals 1 and 2 are the same. However, when the frequencies of the terminals 1 and 2 are different, it is desirable to use a space synchronized phasor explained later.

(Synchronized Phasor)

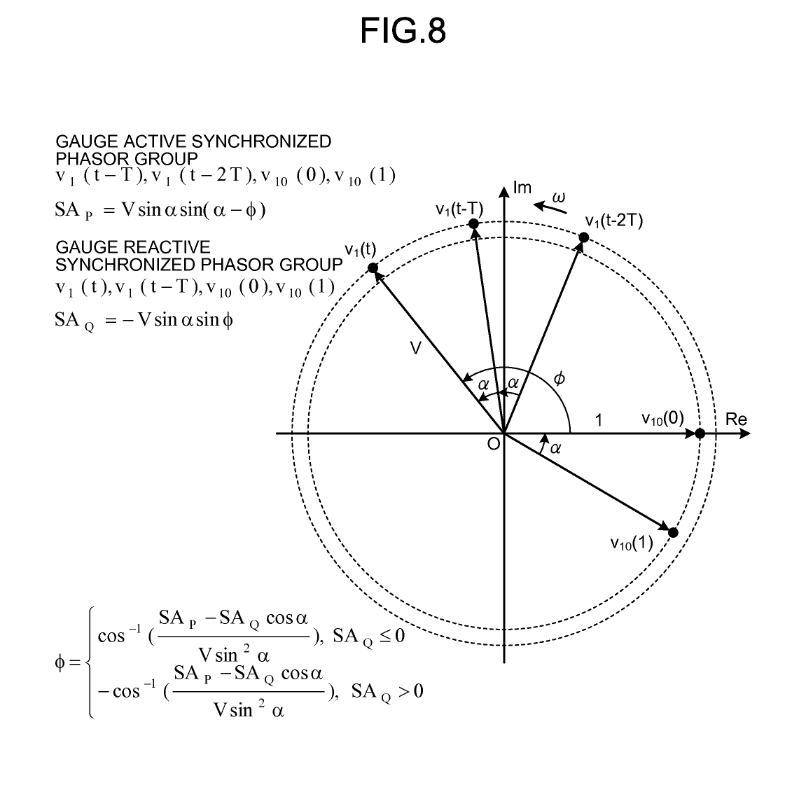

FIG. 8 is a diagram of a synchronized phasor group on a complex plane. On the complex plane shown in FIG. 8, the three voltage vectors v₁(t), v₁(t−T), and v₁(t−2T) rotating counterclockwise at a real frequency and two fixed unit vectors v₁₀(0) and v₁₀(1) are shown. The three voltage vectors v₁(t), v₁(t−T), and v₁(t−2T) can be represented by the following formula:

$$\{ \begin{matrix}{v}_{1} ( t ) = V {e}^{j φ} \\ {v}_{1} ( t - T ) = V {e}^{j ( φ - α )} \\ {v}_{1} ( t - 2 T ) = V {e}^{j ( φ - 2 α )}\end{matrix} \qquad ( 163 )$$

As explained in the “meanings of terms” above, the synchronized phasor is an absolute phase angle of a voltage vector or a current vector rotating counterclockwise on a complex plane. Because the synchronized phasor is the absolute phase angle, the synchronized phasor is a time dependent value that changes at every moment. Therefore, if the synchronized phasor is represented as it is, a component that changes depending on the rotation phase angle and a component that changes depending on time are included in the synchronized phasor. Therefore, in the above Formula (163), an absolute phase angle component at a certain point when time is stopped is shown. When a direct-current offset is included in a voltage vector, after a direct-current offset component is calculated using the calculation method explained above and the calculated direct-current offset component is subtracted from the voltage vector and cancelled, processing explained below only has to be applied.

The two fixed unit vectors v₁₀(0) and v₁₀(1) can be represented by the following formula:

$$\{ \begin{matrix}{v}_{10} ( 0 ) = {e}^{- j α \times 0} = 1 \\ {v}_{10} ( 1 ) = {e}^{- j α \times 1} = {e}^{- j α}\end{matrix} \qquad ( 164 )$$

In the formula, α represents a rotation phase angle determined on-line.

(Gauge Synchronized Phasor Group, Gauge Active Synchronized Phasor Group, and Gauge Reactive Synchronized Phasor Group)

The three voltage vectors v₁(t), v₁(t−T), and v₁(t−2T) and the two fixed unit vectors v₁₀(0) and v₁₀(1) shown in FIG. 8 are defined as a “gauge synchronized phasor group”. Among the vectors forming the gauge synchronized phasor group, the two voltage vectors v₁(t−T) and v₁(t−2T) and the two fixed unit vectors v₁₀(0) and v₁₀(1) are defined as a “gauge active synchronized phasor group” and the two voltage vectors v₁(t) and v₁(t−T) and the two fixed unit vectors v₁₀(0) and v₁₀(1) are defined as a “gauge reactive synchronized phasor group”.

The terms “active” and “reactive” in the “gauge active synchronized phasor group” and the “gauge reactive synchronized phasor group” are affixed because the “gauge active synchronized phasor group” and the “gauge reactive synchronized phasor group” are similar to the “gauge active power” and the “gauge reactive power”, which are calculation results of rotation invariables of the symmetry groups, i.e., “gauge active power group” and “gauge reactive power group”. The same applies to a gauge differential synchronized phasor group, a gauge differential active synchronized phasor group, and a gauge differential reactive synchronized phasor group. However, there is a structural difference in that, whereas the gauge synchronized phasor group includes the rotating vectors (V₁(t), v₁(t−T), and v₁(t−2T)) and the stationary vectors (V₁₀(0) and V₁₀(1)), all the vectors included in the gauge power group are the rotating vectors (V(t), v(t−T), v(t−2T), i(t−T), and i(t−2T)).

(Gauge Active Synchronized Phasor and Gauge Reactive Synchronized Phasor Group)

A gauge active synchronized phasor is defined as indicated by the following formula using the gauge active synchronized phasor group:

SA_{P}=v₁₂v₁₀₁−v₁₃v₁₀₀ (165)

A gauge reactive synchronized phasor is defined as indicated by the following formula using the gauge reactive synchronized phasor group:

SA_{Q}=v₁₁v₁₀₁−v₁₂v₁₀₀ (166)

The voltage instantaneous values v₁₁, v₁₂, and v₁₃ in Formulas (165) and (166) are respectively real parts of the voltage vectors v₁(t), v₁(t−T), and v₁(t−2T) and calculated as indicated by the following formula:

$$\{ \begin{matrix}{v}_{11} = Re [ {v}_{1} ( t ) ] = V cos φ \\ {v}_{12} = Re [ {v}_{1} ( t - T ) ] = V cos ( φ - α ) \\ {v}_{13} = Re [ {v}_{1} ( t - 2 T ) ] = V cos ( φ - 2 α )\end{matrix} \qquad ( 167 )$$

Similarly, instantaneous values v₁₀₀ and v₁₀₁ of the two fixed unit vectors are respectively real parts of the fixed unit vectors v₁₀(0) and v₁₀(1) and calculated as indicated by the following formula:

$$\{ \begin{matrix}{v}_{100} = Re [ {v}_{10} ( 0 ) ] = 1 \\ {v}_{101} = Re [ {v}_{10} ( 1 ) ] = cos α = {f}_{C}\end{matrix} \qquad ( 168 )$$

If v₁₁ and v₁₂ of Formula (167) and v₁₀₀ and v₁₀₁ of Formula (168) are substituted in Formula (165), the calculation formula representing the gauge active synchronized phasor is converted as indicated by the following formula:

$$\begin{matrix}{SA}_{P} = {v}_{12} {v}_{101} - {v}_{13} {v}_{100} \\ = V [ cos ( φ - α ) cos α - cos ( φ - 2 α ) ] \\ = \frac{V}{2} [ cos φ - cos ( φ - 2 α ) ] \\ = \frac{V}{2} [ cos φ ( 1 - cos 2 α ) - sin 2 α sin φ ] \\ = V sin α sin ( α - φ )\end{matrix} \qquad ( 169 )$$

That is, the calculation formula for the gauge active synchronized phasor can be represented as indicated by the following formula:

SA_{P}=V sin α sin(α−φ) (170)

If v₁₂ and v₁₃ of Formula (167) and v₁₀₀ and v₁₀₁ of Formula (168) are substituted in Formula (166), the calculation formula representing the gauge reactive synchronized phasor is converted as indicated by the following formula:

$$\begin{matrix}{SA}_{Q} = {v}_{11} {v}_{101} - {v}_{12} {v}_{100} \\ = V [ cos φcos α - cos ( φ - α ) ] \\ = \frac{V}{2} [ cos ( φ - α ) + cos ( φ + α ) - 2 cos ( φ - α ) ] \\ = \frac{V}{2} [ cos ( φ + α ) - cos ( φ - α ) ] \\ = - V sin αsin φ\end{matrix} \qquad ( 171 )$$

That is, the calculation formula for the gauge reactive synchronized phasor can be represented as indicated by the following formula:

SA_{Q}=−V sin α sin φ (172)

In Formulas (170) and (172), the frequency dependent amounts V and α and the time dependent amount φ are represented as one calculation formula.

(Calculation by Imaginary Parts of the Voltage Vectors)

In the above explanation, the real parts of the voltage vectors are used in calculation. However, imaginary parts of the voltage vectors can be used. Calculation formulas in which the imaginary parts of the voltage vectors are used are presented below.

First, when the voltage instantaneous values v₁₁, v₁₂, and v₁₃ are set as imaginary part instantaneous values of the voltage vectors v₁(t), v₁(t−T), and v₁(t−2T), the voltage instantaneous values v₁₁, v₁₂, and v₁₃ are calculated as indicated by the following formula:

$$\{ \begin{matrix}{v}_{11} = Im [ {v}_{1} ( t ) ] = V sin φ \\ {v}_{12} = Im [ {v}_{1} ( t - T ) ] = V sin ( φ - α ) \\ {v}_{13} = Im [ {v}_{1} ( t - 2 T ) = V sin ( φ - 2 α )\end{matrix} \qquad ( 173 )$$

Similarly, when the instantaneous values v₁₀₀ and v₁₀₁ of the fixed unit vectors are set as imaginary part instantaneous values of the fixed unit vectors v₁₀(0) and v₁₀(1), the instantaneous values V₁₀₀ and V₁₀₁ are calculated as indicated by the following formula:

$$\{ \begin{matrix}{v}_{100} = Im [ {v}_{10} ( 0 ) ] = 0 \\ {v}_{101} = Im [ {v}_{10} ( 1 ) ] = - sin α\end{matrix} \qquad ( 174 )$$

If v₁₁ and v₁₂ of Formula (173) and v₁₀₀ and v₁₀₁ of Formula (174) are substituted in Formula (165), the calculation formula representing the gauge active synchronized phasor is converted as indicated by the following formula:

$$\begin{matrix}{SA}_{P} = {v}_{12} {v}_{101} - {v}_{13} {v}_{100} \\ = V [ sin ( φ - α ) \times ( - sin α ) - sin ( φ - 2 α ) \times 0 ] \\ = V sin αsin ( α - φ )\end{matrix} \qquad ( 175 )$$

If v₁₂ and v₁₃ of Formula (173) and v₁₀₀ and v₁₀₁ of Formula (174) are substituted in Formula (166), the calculation formula representing the gauge reactive synchronized phasor is converted as indicated by the following formula:

$$\begin{matrix}{SA}_{Q} = {v}_{11} {v}_{101} - {v}_{12} {v}_{100} \\ = V [ sin φ \times ( - sin α ) - sin ( φ - α ) \times 0 ] \\ = - V sin αsin φ\end{matrix} \qquad ( 176 )$$

Formula (169) and Formula (175) coincide with each other. Formula (171) and Formula (176) coincide with each other. In this way, the results are the same irrespective of whether the real parts of the voltage vectors are used or the imaginary parts of the voltage vectors are used. This means that a synchronized phasor of an alternating-current sine wave has symmetry.

(Synchronized Phasor Cosine Method)

A relation of the following formula is obtained according to Formula (170) and Formula (172):

$$\{ \begin{matrix}{SA}_{P} = V {sin}^{2} α cos φ - V sin αcos α sin φ \\ - {SA}_{Q} \times cos α = V sin αcos α sin φ\end{matrix} \qquad ( 177 )$$

According to the above formula, a cosine of the synchronized phasor is represented by the following formula:

$$cos φ = \frac{{SA}_{P} - {SA}_{Q} cos α}{V {sin}^{2} α} \qquad ( 178 )$$

Therefore, the synchronized phasor is calculated using the following formula:

$$φ = \{ \begin{matrix}{cos}^{- 1} ( \frac{{SA}_{P} - {SA}_{Q} cos α}{V {sin}^{2} α} ) , & {SA}_{Q} \leq 0 \\ - {cos}^{- 1} ( \frac{{SA}_{P} - {SA}_{Q} cos α}{V {sin}^{2} α} ) , & {SA}_{Q} > 0\end{matrix} \qquad ( 179 )$$

In this way, it is seen that the synchronized phasor changes between −180 degrees to +180 degrees and is a time depending amount.

(Synchronized Phasor Tangent Method)

When Formula (177) is used, a relation of the following formula is obtained:

$$\frac{{SA}_{P}}{{SA}_{Q}} = \frac{V {sin}^{2} α cos πh - V sin α cos α sin φ}{- V sin α sin πh} = - \frac{sin αcos φ}{sin φ} + cos α \qquad ( 180 )$$

According to the above formula, a tangent of the synchronized phasor is represented by the following formula:

$$tan φ = \frac{sin α}{cos α - \frac{{SA}_{P}}{{SA}_{Q}}} \qquad ( 181 )$$

Therefore, the synchronized phasor is calculated using the following formula:

$$φ = \{ \begin{matrix}{tan}^{- 1} ( \frac{sin α}{cos α - \frac{{SA}_{P}}{{SA}_{Q}}} ) , & {SA}_{Q} \leq 0 \\ {tan}^{- 1} ( \frac{sin α}{cos α - \frac{{SA}_{P}}{{SA}_{Q}}} ) - π , & {SA}_{Q} > 0\end{matrix} \qquad ( 182 )$$

In Formula (182), a voltage amplitude variable V is absent. Therefore, if an input waveform is symmetry, results of Formula (179) and Formula (182) should be equal because of a request for symmetry. Therefore, when calculation results of Formula (179) and Formula (182) are different, the symmetry of the input waveform is broken. It is made possible to determine that the input waveform is not a pure sine wave. A synchronized phasor symmetry index that makes use of the characteristics of these formulas is explained later.

(Calculation Formula for a Gauge Active Synchronized Phasor by a Plurality of Sampling Data)

A calculation formula for calculating a gauge active synchronized phasor when the alternating-current electrical quantity measuring apparatus has a plurality of sampling data (the number of sampling points is n) is given by the following formula:

$${SA}_{P} = \frac{1}{n - 2} ( {\sum }_{k = 2}^{n - 1} ( {v}_{1 k} {v}_{10 ( k - 1 )} - {v}_{1 ( k + 1 )} {v}_{10 ( k - 2 )} ) ) = V sin α sin ( α - φ ) , \\ n \geq 3 \qquad ( 183 )$$

In the above formula, v₁ₖ represents time series data of a voltage instantaneous value and v₁₀ₖ represents a member of a fixed unit vector group represented by the following formulas:

$$\begin{matrix}\{ \begin{matrix}{v}_{10} ( 0 ) = 1 \\ {v}_{10} ( 1 ) = {e}^{- j α} \\ ⋮ \\ {v}_{10} ( n - 2 ) = {e}^{- j ( n - 2 ) α}\end{matrix} & ( 184 ) \\ {v}_{10 k} = cos ( k α ) , k = 0 , 1 , … , n - 2 & ( 185 )\end{matrix}$$

(Calculation Formula for a Gauge Reactive Synchronized Phasor by a Plurality of Sampling Data)

A calculation formula for calculating a gauge reactive synchronized phasor when the alternating-current electrical quantity measuring apparatus has a plurality of sampling data (the number of sampling points is n) is given by the following formula:

$${SA}_{Q} = \frac{1}{n - 2} ( {\sum }_{k = 2}^{n - 1} ( {v}_{1 ( k - 1 )} {v}_{10 ( k - 1 )} - {v}_{1 k} {v}_{10 ( k - 2 )} ) ) = - V sin αsin φ , \\ n \geq 3 \qquad ( 186 )$$

(Complex Number Representation of a Voltage Vector)

First, a real part and an imaginary part of a voltage vector are represented as indicated by the following formula:

v(t)=vᵣₑ+jvᵢₘ (187)

In the formula, vᵣₑ and vᵢₘ respectively represent the real part and the imaginary part of the voltage vector and are calculated as indicated by the following formula using Formulas (172), (173), and the like:

$$\{ \begin{matrix}{v}_{re} = V cos φ = \frac{{SA}_{P} - {SA}_{Q} cos α}{{sin}^{2} α} \\ {v}_{im} = V sin φ = - \frac{{SA}_{Q}}{sin α}\end{matrix} \qquad ( 188 )$$

Formula (188) is an extremely important formula and means that the real part of the voltage vector is a voltage fundamental wave instantaneous value. If Formula (188) is used, it is possible to directly calculate the real part and the imaginary part of the voltage vector from time series data.

When Formula (188) is converted into a formula in which the frequency coefficient f_{C} is used, the real part and the imaginary part of the voltage vector are represented by the following formula:

$$\{ \begin{matrix}{v}_{re} = \frac{{SA}_{P} - {SA}_{Q} {f}_{c}}{1 - {f}_{c}^{2}} \\ {v}_{im} = - \frac{{SA}_{Q}}{\sqrt{1 - {f}_{c}^{2}}}\end{matrix} \qquad ( 189 )$$

According to Formula (189), the voltage amplitude V can be calculated as indicated by the following formula:

$$\begin{matrix}V = \sqrt{{v}_{re}^{2} + {v}_{im}^{2}} \\ = \sqrt{( \frac{{SA}_{P} - {SA}_{Q} cos α}{{sin}^{2} α} ) + {( \frac{{SA}_{Q}}{sin α} )}^{2}} \\ = \frac{\sqrt{{SA}_{P}^{2} - 2 {SA}_{P} {SA}_{Q} cos α + {SA}_{Q}^{2}}}{{sin}^{2} α} \\ = \frac{\sqrt{{SA}_{P}^{2} - 2 {SA}_{P} {SA}_{Q} {f}_{c} + {SA}_{Q}^{2}}}{1 - {f}_{c}^{2}}\end{matrix} \qquad ( 190 )$$

As indicated by the following formula, it is also possible to directly calculate a cosine of the synchronized phasor φ using SA_{P}, SA_{Q}, and f_{C}:

$$\begin{matrix}{( cos φ )}_{SP 12} = \frac{{v}_{re}}{V} \\ = \frac{{SA}_{P} - {SA}_{Q} cos α}{{sin}^{2} α} \frac{{sin}^{2} α}{\sqrt{{SA}_{P}^{2} - 2 {SA}_{P} {SA}_{Q} cos α + {SA}_{Q}^{2}}} \\ = \frac{{SA}_{P} - {SA}_{Q} cos α}{\sqrt{{SA}_{P}^{2} - 2 {SA}_{P} {SA}_{Q} cos α + {SA}_{Q}^{2}}} \\ = \frac{{SA}_{P} - {SA}_{Q} {f}_{c}}{\sqrt{{SA}_{P}^{2} - 2 {SA}_{P} {SA}_{Q} {f}_{c} + {SA}_{Q}^{2}}}\end{matrix} \qquad ( 191 )$$

(Synchronized Phasor Cosine Symmetry Index)

A method of using a cosine of a synchronized phasor as an index for evaluating the symmetry of an input waveform is explained. A synchronized phasor cosine symmetry index is defined as indicated by the following formula:

SPS_{sym1}=|(cos φ)_{SP11}−(cos φ)_{SP12}| (192)

In the formula, (cos φ)_{SP11} and (cos φ)_{SP12} are cosine values of the synchronized phasor φ calculated as follows:

$$\{ \begin{matrix}{( cos φ )}_{SP 11} = \frac{{SA}_{P} - {SA}_{Q} cos α}{V {sin}^{2} α} = \frac{{SA}_{P} - {SA}_{Q} {f}_{c}}{{V}_{g} \sqrt{1 - {f}_{c}^{2}}} \\ {( cos φ )}_{Sp 12} = \frac{{SA}_{P} - {SA}_{Q} {f}_{c}}{\sqrt{{SA}_{P}^{2} - 2 {SA}_{P} {SA}_{Q} {f}_{c} + {SA}_{Q}^{2}}}\end{matrix} \qquad ( 193 )$$

In Formula (193), if an input waveform is a pure sine wave, the synchronized phasor cosine symmetry index is zero.

On the other hand, when the synchronized phasor cosine symmetry index is larger than a predetermined threshold, that is, when the synchronized phasor cosine symmetry index is in a relation of the following formula with respect to a threshold SPS_{sym1}, it is determined that the input waveform is not the pure sine wave because the symmetry of the input waveform is broken. In this case, a measured value is latched according to necessity.

SPS_{sym1}=|(cos φ)_{SP11}−(cos φ)_{SP12}|≧SPS_{BRK1} (194)

The above explanation can be applied to a current vector and a current amplitude of the current vector as well. Expansion of a formula is omitted.

The above explanation concerning the synchronized phasor is on the premise that a real frequency is unknown, that is, the real frequency is not always a rated frequency. On the other hand, in the following explanation concerning the synchronized phasor, it is assumed that the real frequency is known, that is, the real frequency is the rated frequency or in a state in which the real frequency can be regarded as the rated frequency although fluctuating in the vicinity of the rated frequency (50 Hz or 60 Hz). According to this assumption, it is possible to perform high-speed measurement in various monitoring control apparatuses, for example, it is possible to apply the explanation to a smart meter.

(α=90°)

For example, a rotation phase angle α=90° means a sampling frequency of 200 Hz in a 50 Hz system and means a sampling frequency of 240 Hz in a 60 Hz system. In this case, real number values of respective members forming a fixed unit vector group are as indicated by the following formula:

$$\{ \begin{matrix}{v}_{100} = 1 \\ {v}_{101} = 0 \\ {v}_{102} = - 1 \\ {v}_{103} = 0 \\ ⋮ \\ {v}_{10 k} = cos [ k \times 90 ° ]\end{matrix} \qquad ( 195 )$$

In the formula, k=n−2, where n represents the number of sampling points.

A gauge active synchronized phasor can be calculated using the following formula:

$${SA}_{P} = \frac{1}{n - 2} {\sum }_{k = 2}^{n - 1} {v}_{1 k} , n \geq 3 \qquad ( 196 )$$

In the formula, v_{1K} represents time series data of a voltage instantaneous value.

A gauge reactive synchronized phasor can be calculated using the following formula:

$${SA}_{Q} = \frac{1}{n - 2} {\sum }_{k = 2}^{n - 1} {v}_{1 ( k - 1 )} , n \geq 3 \qquad ( 197 )$$

In the formula, V_{1(K-1)} represents time series data of a voltage instantaneous value.

(Complex Number Representation of the Voltage Vector in the Case of α=90°)

In the case of α=90°, from Formula (188), vᵣₑ and vᵢₘ, which are the real part and the imaginary part of the voltage vector, can be respectively simplified as indicated by the following formula:

$$\{ \begin{matrix}{v}_{re} = {SA}_{P} \\ {v}_{im} = - {SA}_{Q}\end{matrix} \qquad ( 198 )$$

Therefore, the voltage amplitude V can be calculated as follows:

V=\sqrt{vᵣₑ²+vᵢₘ²}=\sqrt{SA_{P}²+SA_{Q}²} (199)

If Formula (179), which is the calculation formula by the synchronized phasor cosine method explained above, is used, the synchronized phasor can be calculated using the following formula:

$$φ = \{ \begin{matrix}{cos}^{- 1} ( \frac{{SA}_{P}}{\sqrt{{SA}_{P}^{2} + {SA}_{Q}^{2}}} ) , & {SA}_{Q} \leq 0 \\ - {cos}^{- 1} ( \frac{{SA}_{P}}{\sqrt{{SA}_{P}^{2} + {SA}_{Q}^{2}}} ) , & {SA}_{Q} > 0\end{matrix} \qquad ( 200 )$$

In a general protection control apparatus in Japan, 30° sampling (α=30°) is widely used. In the case of α=30°, as in the above explanation, calculation formulas for a voltage amplitude, a synchronized phasor, a gauge active synchronized phasor, a gauge reactive synchronized phasor, and the like can be derived. Because specific formula expansion is the same as the above explanation, explanation of the specific formula expansion is omitted here.

(Voltage Amplitude Symmetry Index 2)

A second index (a voltage amplitude symmetry index 2) of the method of using a voltage amplitude as an index for evaluating the symmetry of an input waveform is explained. The voltage amplitude symmetry index 2 is defined as indicated by the following formula:

V_{sym2}=|V_{SA}−V_{gdA}| (201)

In the formula, V_{SA} and V_{gdA} respectively represent voltage amplitudes calculated according to a gauge synchronized phasor group and a gauge differential voltage group as follows:

$$\{ \begin{matrix}{V}_{SA} = \frac{\sqrt{{SA}_{P}^{2} - 2 {SA}_{P} {SA}_{Q} {f}_{c} + {SA}_{Q}^{2}}}{1 - {f}_{c}^{2}} \\ {V}_{gdA} = \frac{\sqrt{2} {V}_{gd}}{2 ( 1 - {f}_{c} ) \sqrt{1 + {f}_{c}}}\end{matrix} \qquad ( 202 )$$

If an input waveform is a pure sine wave, the voltage amplitude symmetry index 2 indicated by Formula (201) is zero.

On the other hand, when the voltage amplitude symmetry index 2 is larger than a predetermined threshold, that is, when the voltage amplitude symmetry index 2 is in a relation of the next formula with respect to the threshold V_{BRK}, it is determined that the input waveform is not the pure sine wave because the symmetry of the input waveform is broken. In this case, a rotation phase angle, a frequency, a voltage amplitude, and the like, which are measured values, are latched according to necessity.

V_{sym2}=|V_{SA}−V_{gdA}|>V_{BRK} (203)

The idea of the voltage amplitude symmetry index 2 can be applied to a current amplitude as well. Expansion of a formula is omitted.

(Synchronized Phasor Symmetry Index)

A method of using a synchronized phasor as an index for evaluating the symmetry of an input waveform is explained. A synchronized phasor symmetry index is defined as indicated by the following formula:

φ_{symA}=|φ_{cos A}−φ_{tan A}| (204)

In the formula, φ_{cos A} and φ_{tan A} respectively represent synchronized phasors calculated by the synchronized phasor cosine method and the synchronized phasor tangent method as follows:

φ_{symA}=|φ_{cos A}−φ_{tan A}|>φ_{BRK} (205)

If an input waveform is a pure sine wave, the synchronized phasor symmetry index indicated by Formula (204) is zero.

On the other hand, when the synchronized phasor symmetry index is larger than a predetermined threshold, that is, when the synchronized phasor symmetry index is in a relation of the following formula with respect to a threshold φ_{BRK}, it is determined that the input waveform is not the pure sine wave because the symmetry of the input waveform is broken. In this case, the synchronized phasor is estimated as follows:

$${φ}_{t} = \{ \begin{matrix}{φ}_{t - T} + 2 π fT , & {φ}_{t - T} + 2 π fT \leq π \\ {φ}_{t - T} + 2 π fT - 2 π , & {φ}_{t - T} + 2 π fT > π\end{matrix} \qquad ( 206 )$$

In the formula, φₜ and φ_{t-T} respectively represent a synchronized phasor at the present point and a synchronized phasor at the immediately preceding step, f represents a real frequency, and T represents one cycle of a sampling frequency. There are various uses of an estimated value of the synchronized phasor presented here. In a thirteenth embodiment explained below, an instantaneous value estimating method is introduced.

(Differential Synchronized Phasor)

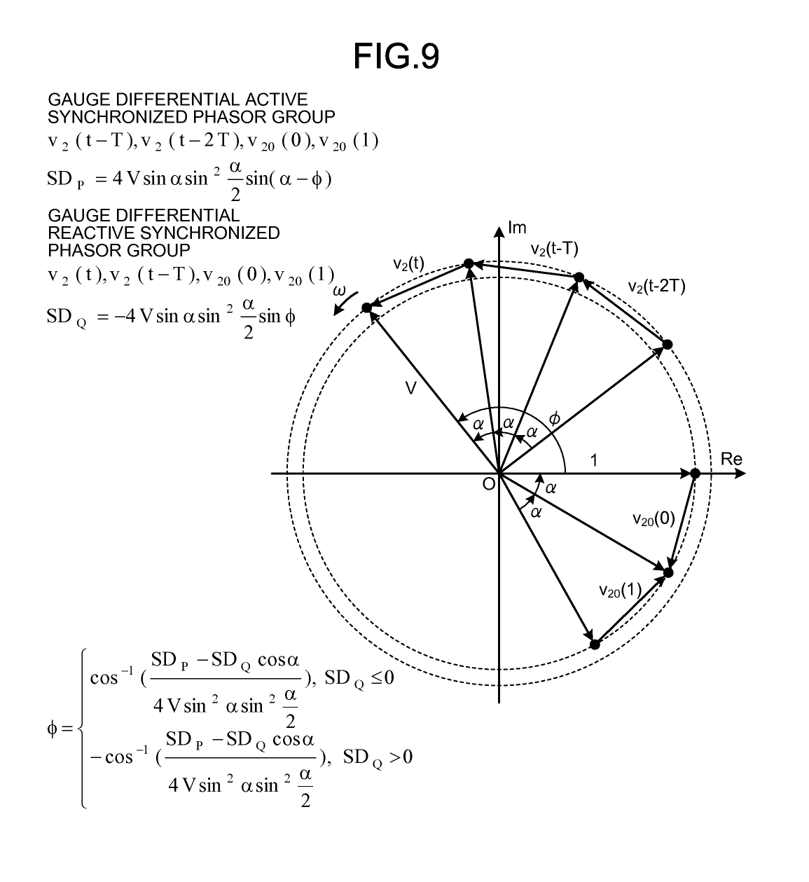

FIG. 9 is a diagram of a differential synchronized phasor group on a complex plane. On the complex plane shown in FIG. 9, the three differential voltage vectors v₂(t), v₂(t−T), and v₂(t−2T) rotating counterclockwise at a real frequency and two fixed difference unit vectors v₂₀(0) and v₂₀(1) are shown. The three differential voltage vectors v₂(t), v₂(t−T), and v₂(t−2T) and the two fixed difference unit vectors v₂₀(0) and v₂₀(1) can be represented by the following formulas:

$$\begin{matrix}\{ \begin{matrix}{v}_{2} ( t ) = V {e}^{jφ} - V {e}^{j ( φ - α )} \\ {v}_{2} ( t - T ) = V {e}^{j ( φ - α )} - V {e}^{j ( φ - 2 α )} \\ {v}_{2} ( t - 2 T ) = V {e}^{j ( φ - 2 α )} - V {e}^{j ( φ - 3 α )}\end{matrix} & ( 207 ) \\ \{ \begin{matrix}{v}_{20} ( 0 ) = 1 - {e}^{- jα} \\ {v}_{20} ( 1 ) = {e}^{- jα} - {e}^{- j2α}\end{matrix} & ( 208 )\end{matrix}$$

(Gauge Differential Synchronized Phasor Group, Gauge Differential Active Synchronized Phasor Group, and Gauge Differential Reactive Synchronized Phasor Group)

The three differential voltage vectors v₂(t), v₂(t−T), and v₂(t−2T) and the two fixed difference unit vectors v₂₀(0) and v₂₀(1) shown in FIG. 9 are defined as a “gauge differential synchronized phasor group”. Among the vectors forming the gauge differential synchronized phasor group, the two differential voltage vectors v₂(t−T) and v₂(t−2T) and the two fixed difference unit vectors v₂₀(0) and v₂₀(1) are defined as a “gauge differential active synchronized phasor group”. The two differential voltage vectors v₂(t) and v₂(t−T) and the two fixed difference unit vectors v₂₀(0) and v₂₀(1) are defined as a “gauge differential reactive synchronized phasor group”.

(Gauge Differential Active Synchronized Phasor and Gauge Differential Reactive Synchronized Phasor)

A gauge differential active synchronized phasor is defined as indicated by the following formula using the gauge differential active synchronized phasor group:

SD_{P}=v₂₂v₂₀₁−v₂₃v₂₀₀ (209)

A gauge differential reactive synchronized phasor is defined as indicated by the following formula using the gauge differential reactive synchronized phasor group:

SD_{Q}=v₂₁v₂₀₁−v₂₂−v₂₀₀ (210)

The voltage instantaneous values v₁₁, v₁₂, and v₁₃ in Formulas (209) and (210) are respectively real parts of the differential voltage vectors v₂(t), v₂(t−T), and v₂(t−2T) and calculated as indicated by the following formula:

$$\{ \begin{matrix}{v}_{21} = Re [ {v}_{2} ( t ) ] = V cos φ - V cos ( φ - α ) \\ {v}_{22} = Re [ {v}_{2} ( t - T ) ] = V cos ( φ - α ) - V cos ( φ - 2 α ) \\ {v}_{23} = Re [ {v}_{2} ( t - 2 T ) ] = V cos ( φ - 2 α ) - V cos ( φ - 3 α )\end{matrix} \qquad ( 211 )$$

Similarly, instantaneous values v₂₀₀ and v₂₀₁ of two fixed unit vectors are respectively real parts of the fixed difference unit vectors v₂₀(0) and v₂₀(1) and calculated as indicated by the following formula:

$$\{ \begin{matrix}{v}_{200} = Re [ {v}_{20} ( 0 ) ] = 1 - cos α = 1 - {f}_{c} \\ {v}_{201} = Re [ {v}_{20} ( 1 ) ] = cos α - cos 2 α = 1 + {f}_{c} - 2 {f}_{c}^{2}\end{matrix} \qquad ( 212 )$$

If v₂₁ and v₂₂ of Formula (211) and v₂₀₀ and v₂₀₁ of Formula (212) are substituted in Formula (209), the calculation formula representing the gauge differential active synchronized phasor is converted as indicated by the following formula:

$$\begin{matrix}{SD}_{P} = {v}_{22} {v}_{201} - {v}_{23} {v}_{200} \\ = V \{ \begin{matrix}[ cos ( φ - α ) - cos ( φ - 2 α ) ] [ cos α - cos 2 α ] - \\ [ cos ( φ - 2 α ) - cos ( φ - 3 α ) ] [ 1 - cos α ]\end{matrix} \} \\ = V [ \begin{matrix}\begin{matrix}cos ( φ - α ) cos α - cos ( φ - 2 α ) cos α - \\ cos ( φ - α ) cos 2 α + cos ( φ - 2 α ) cos 2 α -\end{matrix} \\ \begin{matrix}cos ( φ - 2 α ) + cos ( φ - 3 α ) + \\ cos ( φ - 2 α ) cos α - cos ( φ - 3 α ) cos α\end{matrix}\end{matrix} ] \\ = \frac{V}{2} [ \begin{matrix}cos φ + cos ( φ - 2 α ) - cos ( φ - α ) - cos ( φ - 3 α ) - \\ cos ( φ + α ) - cos ( φ - 3 α ) + cos φ + cos ( φ - 4 α ) - \\ 2 cos ( φ - 2 α ) + 2 cos ( φ - 3 α ) + \\ cos ( φ - α ) + cos ( φ - 3 α ) - cos ( φ - 2 α ) - cos ( φ - 4 α )\end{matrix} ] \\ = \frac{V}{2} [ 2 cos φ - cos ( φ + α ) - 2 cos ( φ - 2 α ) + cos ( φ - 3 α ) ] \\ = \frac{V}{2} [ \begin{matrix}( 2 - cos α - 2 cos 2 α + cos 3 α ) cos φ + \\ ( sin α - 2 sin 2 α + sin 3 α ) sin φ\end{matrix} ] \\ = \frac{V}{2} [ \begin{matrix}4 {sin}^{2} α ( 1 - cos α ) cos φ - \\ 4 sin αcosα ( 1 - cos α ) sin φ\end{matrix} ] \\ = 4 V sin α {sin}^{2} \frac{α}{2} sin ( α - φ )\end{matrix} \qquad ( 213 )$$

That is, the calculation formula for the gauge differential active synchronized phasor can be represented as indicated by the following formula:

$${SD}_{P} = 4 V sin α {sin}^{2} \frac{α}{2} sin ( α - φ ) \qquad ( 214 )$$

If v₂₁ and v₂₂ of Formula (211) and v₂₀₀ and v₂₀₁ of Formula (212) are substituted in Formula (210), the calculation formula representing the gauge differential reactive synchronized phasor is converted as indicated by the following formula:

$$\begin{matrix}{SD}_{Q} = {v}_{21} {v}_{201} - {v}_{22} {v}_{200} \\ = V \{ \begin{matrix}[ cos φ - cos ( φ - α ) ] [ cos α - cos 2 α ] - \\ [ cos ( φ - α ) - cos ( φ - 2 α ) ] [ 1 - cos α ]\end{matrix} \} \\ = V [ \begin{matrix}cos φcosα - cos ( φ - α ) cos α - \\ cos φcos 2 α + cos ( φ - α ) cos 2 α - \\ cos ( φ - α ) + cos ( φ - 2 α ) + \\ cos ( φ - α ) cos α - cos ( φ - 2 α ) cos α\end{matrix} ] \\ = \frac{V}{2} [ \begin{matrix}cos ( φ + α ) + cos ( φ - α ) - cos φ - cos ( φ - 2 α ) - \\ cos ( φ + 2 α ) - cos ( φ - 2 α ) + cos ( φ + α ) + cos ( φ - 3 α ) - \\ 2 cos ( φ - α ) + 2 cos ( φ - 2 α ) + \\ cos φ + cos ( φ - 2 α ) - cos ( φ - α ) - cos ( φ - 3 α )\end{matrix} ] \\ = \frac{V}{2} [ 2 cos ( φ + α ) - 2 cos ( φ - α ) + cos ( φ - 2 α ) - cos ( φ + 2 α ) ] \\ = \frac{V}{2} [ ( - cos 2 α + cos 2 α ) cos φ - ( 4 sin α - 2 sin 2 α ) sin φ ] \\ = - 2 V sin α ( 1 - cos α ) sin φ \\ = - 4 V sin α {sin}^{2} \frac{α}{2} sin φ\end{matrix} \qquad ( 215 )$$

That is, the calculation formula for the gauge differential reactive synchronized phasor can be represented as indicated by the following formula:

$${SD}_{Q} = - 4 V sin α {sin}^{2} \frac{α}{2} sin φ \qquad ( 216 )$$

(Calculation with an Imaginary Part of the Differential Voltage Vector)

In the above explanation, the real part of the differential voltage vector is used for the calculation. However, an imaginary part of the differential voltage vector can be used. A calculation formula in which the imaginary part of the differential voltage vector is used is presented below.

First, when the voltage instantaneous values v₂₁, v₂₂, and v₂₃ are set as imaginary part instantaneous values of the voltage vectors v₂(t), v₂(t−T), and v₂(t−2T), the voltage instantaneous values v₂₁, v₂₂, and v₂₃ are calculated as indicated by the following formula:

$$\{ \begin{matrix}{v}_{21} = Im [ {v}_{2} ( t ) ] = V sin φ - V sin ( φ - α ) \\ {v}_{22} = Im [ {v}_{2} ( t - T ) ] = V sin ( φ - α ) - V sin ( φ - 2 α ) \\ {v}_{23} = Im [ {v}_{2} ( t - 2 T ) ] = V sin ( φ - 2 α ) - V sin ( φ - 3 α )\end{matrix} \qquad ( 217 )$$

Similarly, when the instantaneous values v₂₀₀ and v₂₀₁ of the fixed unit vectors are set as imaginary part instantaneous values of the fixed unit vectors v₂₀(0) and v₂₀(1), the instantaneous values v₂₀₀ and v₂₀₁ are calculated as indicated by the following formula:

$$\{ \begin{matrix}{v}_{200} = Im [ {v}_{20} ( 0 ) ] = sin α \\ {v}_{201} = Im [ {v}_{20} ( 1 ) ] = - sin α + sin 2 α\end{matrix} \qquad ( 218 )$$

If v₂₁ and v₂₂ of Formula (217) and v₂₀₀ and v₂₀₁ of Formula (218) are substituted in Formula (209), the calculation formula representing the gauge differential active synchronized phasor is converted as indicated by the following formula:

$$\begin{matrix}{SD}_{P} = {v}_{22} {v}_{201} - {v}_{23} {v}_{200} \\ = V \{ \begin{matrix}[ sin ( φ - α ) - sin ( φ - 2 α ) ] [ - sin α + sin 2 α ] - \\ [ sin ( φ - 2 α ) - sin ( φ - 3 α ) ] sin α\end{matrix} \} \\ = V [ \begin{matrix}- sin ( φ - α ) sin α + sin ( φ - 2 α ) sin α + \\ sin ( φ - α ) sin 2 α - sin ( φ - 2 α ) sin 2 α - \\ sin ( φ - 2 α ) sin α + sin ( φ - 3 α ) sin α\end{matrix} ] \\ = \frac{V}{2} [ \begin{matrix}- cos ( φ - 2 α ) + cos φ + cos ( φ - 3 α ) - cos ( φ - α ) + \\ cos ( φ - 3 α ) - cos ( φ + α ) - cos ( φ - 4 α ) + cos φ - \\ cos ( φ - 3 α ) + cos ( φ - α ) + cos ( φ - 4 α ) - cos ( φ - 2 α )\end{matrix} ] \\ = \frac{V}{2} [ 2 cos φ - cos ( φ + α ) - 2 cos ( φ - 2 α ) + cos ( φ - 3 α ) ] \\ = \frac{V}{2} [ \begin{matrix}( 2 - cos α - 2 cos 2 α + cos 3 α ) cos φ + \\ ( sin α - 2 sin 2 α + sin 3 α ) sin φ\end{matrix} ] \\ = \frac{V}{2} [ 4 {sin}^{2} α ( 1 - cos α ) cos φ - 4 sin αcos α ( 1 - cos α ) sin φ ] \\ = 4 V sin α {sin}^{2} \frac{α}{2} sin ( α - φ )\end{matrix} \qquad ( 219 )$$

If v₂₁ and v₂₂ of Formula (217) and v₂₀₀ and v₂₀₁ of Formula (218) are substituted in Formula (209), the calculation formula representing the gauge differential reactive synchronized phasor is converted as indicated by the following formula:

$$\begin{matrix}{SD}_{Q} = {v}_{21} {v}_{201} - {v}_{22} {v}_{200} \\ = V \{ \begin{matrix}[ sin φ - sin ( φ - α ) ] [ - sin α + sin 2 α ] - \\ [ sin ( φ - α ) - sin ( φ - 2 α ) ] sin α\end{matrix} \} \\ = V [ \begin{matrix}- sin φsin α + sin ( φ - α ) sin α + \\ sin φsin 2 α - sin ( φ - α ) sin 2 α - \\ sin ( φ - α ) sin α + sin ( φ - 2 α ) sin α\end{matrix} ] \\ = \frac{V}{2} [ \begin{matrix}- cos ( φ - α ) + cos ( φ + α ) + cos ( φ - 2 α ) - cos φ + \\ cos ( φ - 2 α ) - cos ( φ + 2 α ) - cos ( φ - 3 α ) + cos ( φ + α ) - \\ cos ( φ - 2 α ) + cos φ + cos ( φ - 3 α ) - cos ( φ - α )\end{matrix} ] \\ = \frac{V}{2} [ 2 cos ( φ + α ) - 2 cos ( φ - α ) + cos ( φ - 2 α ) - cos ( φ + 2 α ) ] \\ = \frac{V}{2} [ ( - cos 2 α + cos 2 α ) cos φ - ( 4 sin α - 2 sin 2 α ) sin φ ] \\ = - 2 V sin α ( 1 - cos α ) sin φ \\ = - 4 V sin α {sin}^{2} \frac{α}{2} sin φ\end{matrix} \qquad ( 220 )$$

Formula (214) and Formula (219) coincide with each other. Formula (216) and Formula (220) coincide with each other. In this way, the results are the same irrespective of whether the real parts of the differential voltage vectors are used or the imaginary parts of the differential voltage vectors are used. This means that a differential synchronized phasor of an alternating-current sine wave has symmetry.

(Differential Synchronized Phasor Cosine Method)

According to Formula (214) and Formula (216), a relation of the following formula is obtained:

$$\{ \begin{matrix}{SD}_{P} = 4 V {sin}^{2} α {sin}^{2} \frac{α}{2} cos φ - 4 V sin α {sin}^{2} \frac{α}{2} cos αsin φ \\ - {SD}_{Q} \times cos α = 4 V sin {α}^{2} \frac{α}{2} cos α sin φ\end{matrix} \qquad ( 221 )$$

According to the above formula, a cosine of a differential synchronized phasor is represented by the following formula:

$$cos φ = \frac{{SD}_{P} - {SD}_{Q} cos α}{4 V {sin}^{2} α {sin}^{2} \frac{α}{2}} \qquad ( 222 )$$

Therefore, the differential synchronized phasor is calculated using the following formula:

$$φ = \{ \begin{matrix}{cos}^{- 1} ( \frac{{SD}_{P} - {SD}_{Q} cos α}{4 V {sin}^{2} α {sin}^{2} \frac{α}{2}} ) , & {SD}_{Q} \leq 0 \\ - {cos}^{- 1} ( \frac{{SD}_{P} - {SD}_{Q} cos α}{4 V {sin}^{2} α {sin}^{2} \frac{α}{2}} ) , & {SD}_{Q} > 0\end{matrix} \qquad ( 223 )$$

The differential synchronized phasor calculated by the above formula is calculated using the differential voltage vectors. Therefore, there is an advantage that the influence of a direct-current offset in a voltage waveform is small.

(Differential Synchronized Phasor Tangent Method)

When Formula (221) is used, a relation of the following formula is obtained:

$$\frac{{SD}_{P}}{{SD}_{Q}} = \frac{4 V {sin}^{2} {αsin}^{2} \frac{α}{2} cos φ - 4 V sin {αsin}^{2} \frac{α}{2} cos αsin φ}{- 4 V sin {αsin}^{2} \frac{α}{2} sin φ} = \frac{sin α}{tan φ} + cos α \qquad ( 224 )$$

According to the above formula, a tangent of the differential synchronized phasor is represented by the following formula:

$$tan φ = \frac{sin α}{cos α - \frac{{SD}_{P}}{{SD}_{Q}}} \qquad ( 225 )$$

Therefore, the differential synchronized phasor is calculated using the following formula:

$$φ = \{ \begin{matrix}{tan}^{- 1} ( \frac{sin α}{cos α - \frac{{SD}_{P}}{{SD}_{Q}}} ) , & {SD}_{Q} \leq 0 \\ {tan}^{- 1} ( \frac{sin α}{cos α - \frac{{SD}_{P}}{{SD}_{Q}}} ) - π , & {SD}_{Q} > 0\end{matrix} \qquad ( 226 )$$

The differential synchronized phasor calculated by the above formula is calculated using the differential voltage vectors. Therefore, there is an effect that the influence of the direct-current offset in a voltage waveform is small.

(Calculation Formula for a Gauge Differential Active Synchronized Phasor by a Plurality of Sampling Data)

A calculation formula for calculating a gauge differential active synchronized phasor when the alternating-current electrical quantity measuring apparatus has a plurality of sampling data (the number of sampling points is n) is given by the following formula:

$$\begin{matrix}{SD}_{P} = \frac{1}{n - 2} ( {\sum }_{k = 2}^{n - 1} ( {v}_{2 k} {v}_{20 ( k - 2 )} - {v}_{2 ( k + 1 )} {v}_{20 ( k - 1 )} ) ) \\ = 4 V sin α {sin}^{2} \frac{α}{2} sin ( α - φ ) , n \geq 3\end{matrix} \qquad ( 227 )$$

In the above formula, v₂ₖ represents time series data of a differential voltage instantaneous value and v₂₀ₖ represents a member of a fixed difference unit vector group represented by the following formulas:

$$\begin{matrix}\{ \begin{matrix}{v}_{20} ( 0 ) = 1 - {e}^{- j α} \\ {v}_{20} ( 1 ) = {e}^{- j α} - {e}^{- j 2 α} \\ ⋮ \\ {v}_{20} ( n - 2 ) = {e}^{- j ( n - 2 ) α} - {e}^{- j ( n - 3 ) α}\end{matrix} & ( 228 ) \\ {v}_{20 k} = cos ( k α ) - cos [ ( k - 1 ) α ] , k = 0 , 1 , … , n - 2 & ( 229 )\end{matrix}$$

(Calculation Formula for a Gauge Differential Reactive Synchronized Phasor by a Plurality of Sampling Data)

A calculation formula for calculating a gauge differential reactive synchronized phasor when the alternating-current electrical quantity measuring apparatus has a plurality of sampling data (the number of sampling points is n) is given by the following formula:

$$\begin{matrix}{SD}_{Q} = \frac{1}{n - 2} ( {\sum }_{k = 2}^{n - 1} ( {v}_{2 ( k - 1 )} {v}_{20 ( k - 2 )} - {v}_{2 k} {v}_{20 ( k - 1 )} ) ) \\ = - 4 V sin α {sin}^{2} \frac{α}{2} sin φ , n \geq 3\end{matrix} \qquad ( 230 )$$

(Complex Number Representation of a Voltage Vector)

First, the real part vᵣₑ and the imaginary part vᵢₘ of the voltage vector are represented as indicated by the following formula using Formulas (216), (222), and the like:

$$\{ \begin{matrix}{v}_{re} = V cos φ = \frac{{SD}_{P} - {SD}_{Q} cos α}{4 {sin}^{2} α {sin}^{2} \frac{α}{2}} \\ {v}_{im} = V sin φ = - \frac{{SD}_{Q}}{4 sin α {sin}^{2} \frac{α}{2}}\end{matrix} \qquad ( 231 )$$

Formula (231) is an extremely important formula. A real part and an imaginary part of a voltage vector can be directly calculated from time series data.

When Formula (231) is converted into a formula in which the frequency coefficient f_{C} is used, the real part and the imaginary part of the voltage vector are represented by the following formula:

$$\{ \begin{matrix}{v}_{re} = \frac{{SD}_{P} - {SD}_{Q} {f}_{C}}{2 ( 1 + {f}_{C} ) {( 1 - {f}_{C} )}^{2}} \\ {v}_{im} = - \frac{{SD}_{Q}}{2 ( 1 - {f}_{C} ) \sqrt{1 - {f}_{C}^{2}}}\end{matrix} \qquad ( 232 )$$

According to Formula (232), the voltage amplitude V can be calculated as indicated by the following formula:

$$\begin{matrix}V = \sqrt{{v}_{re}^{2} + {v}_{im}^{2}} \\ = \sqrt{{( \frac{{SD}_{P} - {SD}_{Q} cos α}{4 {sin}^{2} α {sin}^{2} \frac{α}{2}} )}^{2} + {( \frac{{SD}_{Q}}{4 sin α {sin}^{2} \frac{α}{2}} )}^{2}} \\ = \frac{\sqrt{{SD}_{P}^{2} - 2 {SD}_{P} {SD}_{Q} cos α + {SD}_{Q}^{2}}}{4 {sin}^{2} α {sin}^{2} \frac{α}{2}} \\ = \frac{\sqrt{{SD}_{P}^{2} - 2 {SD}_{P} {SD}_{Q} {f}_{C} + {SD}_{Q}^{2}}}{2 ( 1 + {f}_{C} ) {( 1 - {f}_{C} )}^{2}}\end{matrix} \qquad ( 233 )$$

As indicated by the following formula, it is also possible to directly calculate a cosine of the synchronized phasor φ using SD_{P}, SD_{Q}, and f_{C}:

$$\begin{matrix}{( cos φ )}_{SP 22} = \frac{{v}_{re}}{V} \\ = \frac{{SD}_{P} - {SD}_{Q} cos α}{4 {sin}^{2} α {sin}^{2} \frac{α}{2}} \\ \frac{4 {sin}^{2} α {sin}^{2} \frac{α}{2}}{\sqrt{{SD}_{P}^{2} - 2 {SD}_{P} {SD}_{Q} cos α + {SD}_{Q}^{2}}} \\ = \frac{{SD}_{P} - {SD}_{Q} cos α}{\sqrt{{SD}_{P}^{2} - 2 {SD}_{P} {SD}_{Q} cos α + {SD}_{Q}^{2}}} \\ = \frac{{SD}_{P} - {SD}_{Q} {f}_{C}}{\sqrt{{SD}_{P}^{2} - 2 {SD}_{P} {SD}_{Q} {f}_{C} + {SD}_{Q}^{2}}}\end{matrix} \qquad ( 234 )$$

(Differential Synchronized Phasor Cosine Symmetry Index)

A method of using a cosine of a differential synchronized phasor as an index for evaluating the symmetry of an input waveform is explained. A differential synchronized phasor cosine symmetry index is defined as indicated by the following formula:

SPS_{sym2}=|(cos φ)_{SP21}−(cos φ)_{SP}| (235)

In the formula, (cos φ)_{SP21} and (cos φ)_{SP22} are cosine values of the synchronized phasor φ calculated as follows:

$$\{ \begin{matrix}{( cos φ )}_{SP 21} = \frac{{SD}_{P} - {SD}_{Q} cos α}{4 V {sin}^{2} α {sin}^{2} \frac{α}{2}} = \frac{\sqrt{2} ( {SD}_{P} - {SD}_{Q} {f}_{C} )}{2 {V}_{g} ( 1 - {f}_{C} ) \sqrt{1 + {f}_{C}}} \\ {( cos φ )}_{SP 22} = \frac{{SD}_{P} - {SD}_{Q} {f}_{C}}{\sqrt{{SD}_{P}^{2} - 2 {SD}_{P} {SD}_{Q} {f}_{C} + {SD}_{Q}^{2}}}\end{matrix} \qquad ( 236 )$$

In Formula (236), if an input waveform is a pure sine wave, the synchronized phasor cosine symmetry index is zero.

On the other hand, when the differential synchronized phasor cosine symmetry index is larger than a predetermined threshold, that is, when the differential synchronized phasor cosine symmetry index is in a relation of the following formula with respect to a threshold SPS_{sym2}, it is determined that the input waveform is not the pure sine wave because the symmetry of the input waveform is broken. In this case, a measured value is latched according to necessity.

SPS_{sym2}=|(cos φ)_{SP21}−(cos φ)_{SP22}|≧SPS_{BRK2} (237)

The above explanation can be applied to a current vector and a current amplitude of the current vector as well. Expansion of a formula is omitted.

The above explanation concerning the differential synchronized phasor is on the premise that a real frequency is unknown, that is, the real frequency is not always a rated frequency. On the other hand, in the following explanation concerning the differential synchronized phasor, it is assumed that the real frequency is known, that is, the real frequency is the rated frequency or in a state in which the real frequency can be regarded as the rated frequency although fluctuating in the vicinity of the rated frequency (50 Hz or 60 Hz). According to this assumption, it is possible to perform high-speed measurement in various monitoring control apparatuses, for example, it is possible to apply the explanation to a smart meter.

(α=90°)

For example, a rotation phase angle α=90° means a sampling frequency of 200 Hz in a 50 Hz system and means a sampling frequency of 240 Hz in a 60 Hz system. In this case, real number values of respective members forming a fixed unit vector group are as indicated by the following formula:

$$\{ \begin{matrix}{v}_{100} = 1 - 0 = 1 \\ {v}_{101} = 0 - ( - 1 ) = 1 \\ ⋮ \\ {v}_{10 k} = cos [ k \times 90 ° ] - cos [ ( k - 1 ) \times 90 ° ]\end{matrix} \qquad ( 238 )$$

In the formula, k=n−2, where n represents the number of sampling points.

The following formula holds from Expressions (170), (172), (214), and (216)]

$$\frac{{SD}_{P}}{{SA}_{P}} = \frac{{SD}_{Q}}{{SA}_{Q}} = 4 {sin}^{2} \frac{θ}{2} = 2 \qquad ( 239 )$$

Therefore, a discriminant shown below is proposed as a discriminant for determining symmetry breaking of an input alternating voltage.

$$\{ \begin{matrix}\vert \frac{{SD}_{P}}{{SA}_{P}} - 2 \vert > ɛ \\ \vert \frac{{SD}_{Q}}{{SA}_{Q}} - 2 \vert > ɛ\end{matrix} \qquad ( 240 )$$

In the formula, ε represents a setting value. When the above formula is satisfied, it is determined that the symmetry of an input alternating-current waveform is broken. In this case, it is desirable to perform processing for latching a value of the preceding step without adopting, for example, a calculation result of a synchronized phasor explained below.

(Complex Number Representation of the Voltage Vector in the Case of α=90°)

In the case of α=90°, from Formula (231), vᵣₑ and vᵢₘ, which are the real part and the imaginary part of the voltage vector, can be respectively simplified as indicated by the following formula:

$$\{ \begin{matrix}{v}_{re} = \frac{{SD}_{P}}{2} \\ {v}_{im} = - \frac{{SD}_{Q}}{2}\end{matrix} \qquad ( 241 )$$

Therefore, the voltage amplitude V can be calculated as follows:

$$V = \sqrt{{v}_{re}^{2} + {v}_{im}^{2}} = \frac{1}{2} \sqrt{{SD}_{P}^{2} + {SD}_{Q}^{2}} \qquad ( 242 )$$

If Formula (223), which is the calculation formula by the synchronized phasor cosine method, is used, a synchronized phasor can be calculated using the following formula:

$$φ = \{ \begin{matrix}{cos}^{- 1} ( \frac{{SD}_{P}}{\sqrt{{SD}_{P}^{2} + {SD}_{Q}^{2}}} ) , & {SD}_{Q} \leq 0 \\ - {cos}^{- 1} ( \frac{{SD}_{P}}{\sqrt{{SD}_{P}^{2} + {SD}_{Q}^{2}}} ) , & {SD}_{Q} > 0\end{matrix} \qquad ( 243 )$$

In a general protection control apparatus in Japan, 30° sampling (α=30°) is widely used. In the case of α=30°, as in the above explanation, calculation formulas for a voltage amplitude, a synchronized phasor, a gauge differential active synchronized phasor, a gauge differential reactive synchronized phasor, and the like can be derived. Because specific formula expansion is the same as the above explanation, explanation of the specific formula expansion is omitted here.

As explained above, the voltage amplitude and the synchronized phasor can be calculated using the gauge synchronized phasor group or the gauge differential synchronized phasor group. However, when both the methods can be used, it is desirable to apply the calculation method in which the differential synchronized phasor group not affected by a direct-current offset of an input waveform is used.

The above explanation can be applied to calculation processing for a synchronized phasor by a current vector. Expansion of a formula is omitted.

(Voltage Amplitude Symmetry Index 3)

A third index (a voltage amplitude symmetry index 3) of the method of using a voltage amplitude as an index for evaluating the symmetry of an input waveform is explained. The voltage amplitude symmetry index 3 is defined as indicated by the following formula:

V_{sym3}=V_{SD}−V_{gdA}| (244)

In the formula, V_{SD} and V_{gdA} are voltage amplitudes respectively calculated according to the gauge differential synchronized phasor group and the gauge differential voltage group as follows:

$$\{ \begin{matrix}{V}_{SD} = \frac{\sqrt{{SD}_{P}^{2} - 2 {SD}_{P} {SD}_{Q} {f}_{C} + {SD}_{Q}^{2}}}{2 ( 1 + {f}_{C} ) {( 1 - {f}_{C} )}^{2}} \\ {V}_{gdA} = \frac{\sqrt{2} {V}_{gd}}{2 ( 1 - {f}_{C} ) \sqrt{1 + {f}_{C}}}\end{matrix} \qquad ( 245 )$$

If an input waveform is a pure sine wave, the voltage amplitude symmetry index 3 indicated by Formula (244) is zero.

On the other hand, when the voltage amplitude symmetry index 3 is larger than a predetermined threshold, that is, when the voltage amplitude symmetry index 3 is in a relation of the following formula with respect to the threshold V_{BRK}, it is determined that the input waveform is not the pure sine wave because the symmetry of the input waveform is broken. In this case, a rotation phase angle, a frequency, a voltage amplitude, and the like, which are measured values, are latched according to necessity.

V_{sym3}=|V_{SD}−V_{gdA}|>V_{BRK} (246)

The idea of the voltage amplitude symmetry index 3 can be applied to a current amplitude as well. Expansion of the formula is omitted.

(Voltage Amplitude Symmetry Index 4)

A fourth index (a voltage amplitude symmetry index 4) of the method of using a voltage amplitude as an index for evaluating the symmetry of an input waveform is explained. The voltage amplitude symmetry index 4 is defined as indicated by the following formula:

V_{sym4}=|V_{SA}−V_{SD}| (247)

In the formula, V_{SA} and V_{SD} are voltage amplitudes respectively calculated according to the gauge synchronized phasor group and the gauge differential synchronized phasor group as follows:

$$\{ \begin{matrix}{V}_{SA} = \frac{\sqrt{{SA}_{P}^{2} - 2 {SA}_{P} {SA}_{Q} {f}_{C} + {SA}_{Q}^{2}}}{1 - {f}_{C}^{2}} \\ {V}_{SD} = \frac{\sqrt{{SD}_{P}^{2} - 2 {SD}_{P} {SD}_{Q} {f}_{C} + {SD}_{Q}^{2}}}{2 ( 1 + {f}_{C} ) {( 1 - {f}_{C} )}^{2}}\end{matrix} \qquad ( 248 )$$

If an input waveform is a pure sine wave, the voltage amplitude symmetry index 4 indicated by Formula (247) is zero.

On the other hand, when the voltage amplitude symmetry index 4 is larger than a predetermined threshold, that is, when the voltage amplitude symmetry index 4 is in a relation of the following formula with respect to the threshold V_{BRK}, it is determined that the input waveform is not the pure sine wave because the symmetry of the input waveform is broken. In this case, a rotation phase angle, a frequency, a voltage amplitude, and the like, which are measured values, are latched according to necessity.

V_{sym4}=|V_{SA}−V_{SD}|>V_{BRK} (249)

The idea of the voltage amplitude symmetry index 4 can be applied to a current amplitude as well. Expansion of the formula is omitted.

(Synchronized Phasor Symmetry Index)

A method of using a differential synchronized phasor as an index for evaluating the symmetry of an input waveform is explained. A differential synchronized phasor symmetry index is defined as indicated by the following formula:

φ_{symD}=|φ_{cos D}−φ_{tan D}| (250)

In the formula, φ_{cos D} and φ_{tan D} respectively represent synchronized phasors calculated by the differential synchronized phasor cosine method and the differential synchronized phasor tangent method.

If an input waveform is a pure sine wave, the differential synchronized phasor symmetry index indicated by Formula (250) is zero.

On the other hand, when the differential synchronized phasor symmetry index is larger than a predetermined threshold, that is, when the differential synchronized phasor symmetry index is in a relation of the following formula with respect to the threshold φ_{BRK}, it is determined that the input waveform is not the pure sine wave because the symmetry of the input waveform is broken. In this case, a synchronized phasor is estimated using Formula (206).

φ_{symD}=|φ_{cos D}−φ_{tan D}|>φ_{BRK} (251)

(Gauge Active Reactive Synchronized Phasor Symmetry Index)

A method of using a gauge active reactive synchronized phasor as an index for evaluating the symmetry of an input waveform is explained.

First, as indicated by Formula (239) as well, the following formula holds according to Formulas (170), (172), (214), and (216).

$$\frac{{SD}_{P}}{{SA}_{P}} = \frac{{SD}_{Q}}{{SA}_{Q}} = 4 {sin}^{2} \frac{α}{2} \qquad ( 252 )$$

In the formula, SA_{P} and SD_{P} respectively represent a gauge active synchronized phasor and a gauge differential active synchronized phasor and SA_{Q} and SD_{Q} respectively represent a gauge reactive synchronized phasor and a gauge differential reactive synchronized phasor.

When an absolute value of a difference between a first term and a second term of Formula (252) is defined as a gauge active reactive synchronized phasor symmetry index, it is determined that an input waveform is a sine wave when a differential synchronized phasor symmetry index SAD_{sym} is smaller than the predetermined threshold φ_{BRK} as indicated by the following formula:

$${SAD}_{sym} = \vert \frac{{SD}_{P}}{{SA}_{P}} - \frac{{SD}_{Q}}{{SA}_{Q}} \vert < {SAD}_{BRK} \qquad ( 253 )$$

On the other hand, when the differential synchronized phasor symmetry index SAD_{sym} is larger than the predetermined threshold φ_{BRK}, it is determined that the input waveform is not the pure sine wave because the symmetry of the input waveform is broken.

(Estimation of a Voltage Fundamental Wave Instantaneous Value)

A voltage fundamental wave instantaneous value is a real part of a voltage vector. As indicated by Formula (189), the voltage fundamental wave instantaneous value is represented by the following formula:

$${v}_{re} = V cos {φ}_{V} = \frac{{SA}_{P} - {SA}_{Q} {f}_{C}}{1 - {f}_{C}^{2}} \qquad ( 254 )$$

In the formula, V represents a voltage amplitude, φ_{V} represents a synchronized phasor of a voltage, SA_{P} represents a gauge active synchronized phasor, SA_{Q} represents a gauge reactive synchronized phasor, and f_{C} represents a frequency coefficient.

If the calculation methods explained above are suitably combined, because the calculated voltage amplitude and the calculated phasor themselves eliminate the influence of a direct-current offset, a non-sine waveform, correlative Gaussian noise, and the like, a highly-accurate voltage fundamental wave instantaneous value is obtained.

Similarly, a current fundamental instantaneous value is a real part of the voltage vector and represented by the following formula same as Formula (189):

$${i}_{re} = I cos {φ}_{I} = \frac{{SA}_{P} - {SA}_{Q} {f}_{C}}{1 - {f}_{C}^{2}} \qquad ( 255 )$$

In the formula, I represents a voltage amplitude, φ_{I} represents a synchronized phasor of an electric current, SA_{P} represents a gauge active synchronized phasor, SA_{Q} represents a gauge reactive synchronous phasor, and f_{C} represents a frequency coefficient.

SA_{P} and SA_{Q} in Formula (254) and SA_{P} and SA_{Q} in Formula (255) have the same sign but have different contents (values) of the sign. SA_{P} and SA_{Q} in Formula (254) have values calculated according to voltage data and f_{C} is also calculated using the voltage data. On the other hand, SA_{P} and SA_{Q} in Formula (255) have values calculated according to current data and f_{C} is also calculated using the current data. In a fourteenth embodiment explained below, an application example to an active filter is explained.

(THD Indexes)

For monitoring of power quality, two THD indexes explained below are proposed. A smaller value of the THD indexes means higher power quality. Conversely, when a value of the THD indexes is large, this means that the power quality is deteriorated. Specifically, this represents that harmonic noise, voltage flicker, and the like are present in a voltage waveform/a current waveform.

(Voltage THD Index)

A voltage THD index, which is one of indexes for evaluating the power quality, is defined as indicated by the following formula:

$${THD}_{V} = \sqrt{\frac{1}{N} {\sum }_{k = 1}^{N} {( {v}_{Lk} - {v}_{rek} - {d}_{V} )}^{2}} \qquad ( 256 )$$

In the formula, v_{LK} represents a real voltage instantaneous value, vᵣₑₖ represents a voltage fundamental wave instantaneous value, and d_{V} represents a voltage direct-current offset. N represents the number of samplings in one cycle of a rated frequency in a power system and is calculated using the following formula:

$$N = int ( \frac{{f}_{S}}{{f}_{0}} ) \qquad ( 257 )$$

In the formula, f_{S} represents a sampling frequency, f₀ represents a rated frequency, and “int” represents a function for extracting an integer portion.

Similarly, a current THD index, which is another index for evaluating power quality, is defined as indicated by the following formula:

$${THD}_{I} = \sqrt{\frac{1}{N} {\sum }_{k = 1}^{N} {( {i}_{Lk} - {i}_{rek} - {d}_{I} )}^{2}} \qquad ( 258 )$$

In the formula, i_{LK} represents a real current instantaneous value, iᵣₑₖ represents the current fundamental wave instantaneous value calculated by Formula (255), and d₁ represents a current direct-current offset. N, f_{S}, and f₀ are as explained above.

The various calculation formulas presented above can be applied to various alternating-current electrical quantity measuring apparatuses. Fourteen embodiments are presented below as application examples of the alternating-current electrical quantity measuring apparatuses. It goes without saying that the present invention is not limited to these embodiments.

### First Embodiment

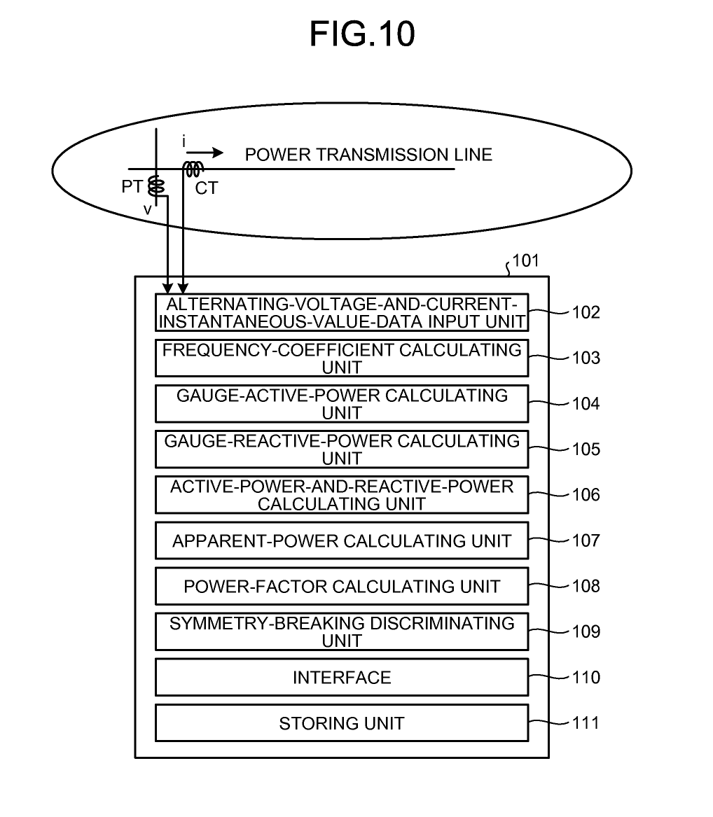

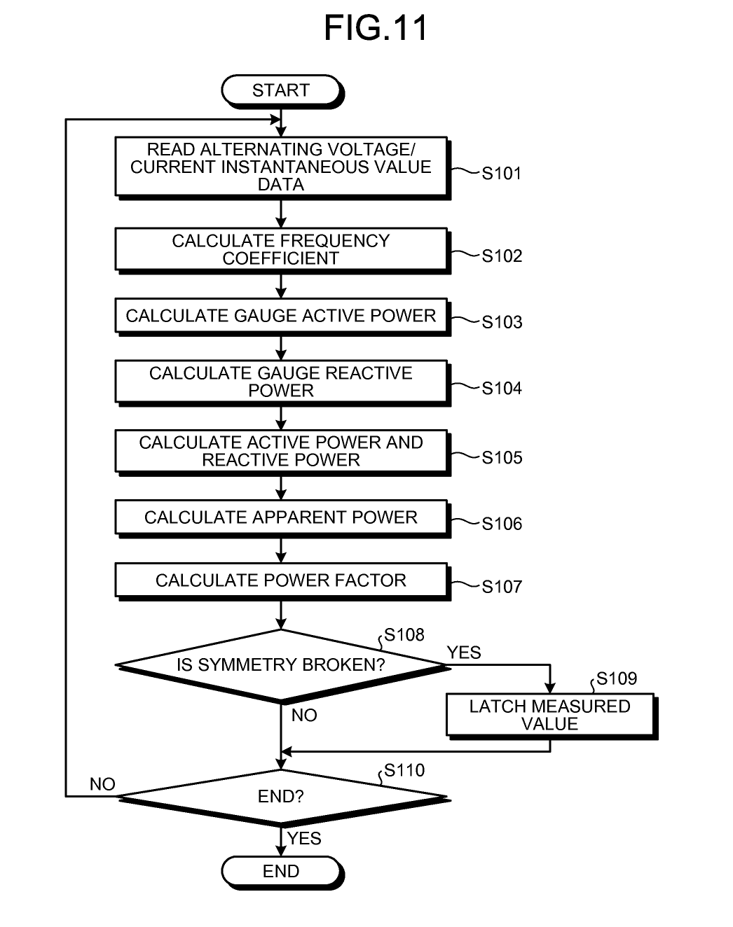

FIG. 10 is a diagram of a functional configuration of a power measuring apparatus according to a first embodiment. FIG. 11 is a flowchart for explaining a flow of processing in the power measuring apparatus.

As shown in FIG. 10, a power measuring apparatus 101 according to the first embodiment includes an alternating-voltage-and-current-instantaneous-value-data input unit 102, a frequency-coefficient calculating unit 103, a gauge-active-power calculating unit 104, a gauge-reactive-power calculating unit 105, an active-power-and-reactive-power calculating unit 106, an apparent-power calculating unit 107, a power-factor calculating unit 108, a symmetry-breaking discriminating unit 109, an interface 110, and a storing unit 111. The interface 110 performs processing for outputting a calculation result and the like to a display apparatus and an external apparatus. The storing unit 111 performs processing for storing measurement data, a calculation result, and the like.

In the above configuration, the alternating-voltage-and-current-instantaneous-value-data input unit 102 performs processing for reading out a voltage instantaneous value and a current instantaneous value from a meter transformer (PT) and a current transformer (CT) provided in a power system (step S101). Data of the read-out voltage instantaneous value and the read-out current instantaneous value are stored in the storing unit 111.

The frequency-coefficient calculating unit 103 calculates a frequency coefficient based on the calculation processing explained above (step S102). Calculation processing for the frequency coefficient can be explained as follows if the calculation processing including the concept of the calculation processing explained above is generally explained. That is, to satisfy the sampling theorem, the frequency-coefficient calculating unit 103 performs processing for calculating, as a frequency coefficient, a value obtained by normalizing, with a differential voltage instantaneous value at intermediate time, a mean value of a sum of differential voltage instantaneous values at times other than the intermediate time among differential voltage instantaneous value data at three points each representing an inter-point distance between voltage instantaneous value data at adjacent two points in voltage instantaneous value data at continuous at least four points sampled at a sampling frequency twice or more as high as the frequency of an alternating voltage set as a measurement target.

The gauge-active-power calculating unit 104 calculates gauge active power based on the calculation processing explained above (step S103). Processing by the gauge-active-power calculating unit 104 can also be generally explained as follows. That is, the gauge-active-power calculating unit 104 performs processing for calculating, as gauge active power, a value calculated by a predetermined multiply-subtract operation using voltage instantaneous value data at two points measured at early times among voltage instantaneous value data at predetermined continuous three points sampled at the sampling frequency and differential current instantaneous value data at two points measured at late times among current instantaneous value data at three points sampled at the sampling frequency and sampled at time same as time of the sampling of voltage instantaneous values at the predetermined three-points.

The gauge-reactive-power calculating unit 105 calculates gauge reactive power based on the calculation processing explained above (step S104). To explain more in detail and generally, the gauge-reactive-power calculating unit 105 performs processing for calculating, as gauge reactive power, a value calculated by a predetermined multiply-subtract operation using voltage instantaneous value data at two points measured at late times among voltage instantaneous value data at predetermined continuous three points sampled at the sampling frequency and differential current instantaneous value data at two points measured at late times among current instantaneous value data at three points sampled at the sampling frequency and sampled at time same as time of the sampling of voltage instantaneous values at the predetermined three-points.

The active-power-and-reactive-power calculating unit 106 calculates active power using the frequency coefficient calculated by the frequency-coefficient calculating unit 103, the gauge active power calculated by the gauge-active-power calculating unit 104, and the gauge reactive power calculated by the gauge-reactive-power calculating unit 105 (step S105). The active-power-and-reactive-power calculating unit 106 calculates reactive power using the frequency coefficient calculated by the frequency-coefficient calculating unit 103 and the gauge reactive power calculated by the gauge-reactive-power calculating unit 105 (step S105).

The apparent-power calculating unit 107 calculates apparent power using the frequency coefficient calculated by the frequency-coefficient calculating unit 103, the gauge active power calculated by the gauge-active-power calculating unit 104, and the gauge reactive power calculated by the gauge-reactive-power calculating unit 105 (step S106).

The power-factor calculating unit 108 calculates a power factor using the frequency coefficient calculated by the frequency-coefficient calculating unit 103, the gauge active power calculated by the gauge-active-power calculating unit 104, and the gauge reactive power calculated by the gauge-reactive-power calculating unit 105 (step S107).

The symmetry-breaking discriminating unit 109 determines breaking of symmetry using, for example, the gauge power symmetry index (step S108). When not determining the breaking of symmetry (No at step S108), the symmetry-breaking discriminating unit 109 shifts to step S110. On the other hand, when determining the breaking of symmetry (Yes at step S108), the symmetry-breaking discriminating unit 109 latches a measured value (a calculated value) (step S109) and thereafter shifts to step S110. An index other than the gauge power symmetry index can be used as a determination index for determining breaking of symmetry.

At the last step S110, the power measuring apparatus 101 performs determination processing for determining whether to end the entire flow explained above. If not to end the flow (No at step S110), the power measuring apparatus 101 repeats the processing at steps S101 to S109.

In the above explanation, the frequency coefficient, the active power, the reactive power, the apparent power, and the power factor are calculated based on the differential voltage instantaneous value data and the differential current instantaneous value data. However, the frequency coefficient, the active power, the reactive power, the apparent power, and the power factor can be calculated based on voltage instantaneous value data and current instantaneous value data as explained above in the calculation processing.

Contents of general processing concerning the frequency-coefficient calculating unit 103, the gauge-active-power calculating unit 104, and the gauge-reactive-power calculating unit 105 in calculating the frequency coefficient, the active power, the reactive power, the apparent power, and the power factor based on the voltage instantaneous value data and the current instantaneous value data are as explained below.

The gauge-active-power calculating unit 104 performs processing for calculating, as gauge active power, a value calculated by a predetermined multiply-subtract operation using voltage instantaneous value data at two points measured at early times among voltage instantaneous value data at continuous predetermined three points sampled at the sampling frequency and differential current instantaneous value data at two points measured at late times among current instantaneous value data at three points sampled at the sampling frequency and sampled at time same as time of sampling of voltage instantaneous values at the predetermined three points.

The gauge-reactive-power calculating unit 105 performs processing for calculating, as gauge differential reactive power, a value calculated by a predetermined multiply-subtract operation using voltage instantaneous value data at two points measured at late times among voltage instantaneous value data at continuous predetermined three points sampled at the sampling frequency and differential current instantaneous value data at two points measured at late times among current instantaneous value data at three points sampled at the sampling frequency and sampled at time same as time of sampling of voltage instantaneous values at the predetermined three points.

A flow of power calculation performed using a measurement result of a synchronized phasor is as explained below. First, a voltage-current phase angle is calculated using the following formula:

$${φ}_{vi} = \{ \begin{matrix}{φ}_{v} - {φ}_{i} - 2 π , & {φ}_{v} - {φ}_{i} > π \\ {φ}_{v} - {φ}_{i} + 2 π , & {φ}_{v} - {φ}_{i} < - π \\ {φ}_{v} - {φ}_{i} , & others\end{matrix} \qquad ( 259 )$$

In the formula, φ_{V} and φᵢ respectively represent a voltage synchronized phasor and a current synchronized phasor. Complex power W is represented as indicated by the following formula using active power P and reactive power Q:

W=P+jQ (260)

The active power P and the reactive power Q are represented as indicated by the following formula using the voltage amplitude V, the current amplitude I, and a synchronized phasor φᵥᵢ:

$$\{ \begin{matrix}P = VI cos {φ}_{vi} \\ Q = VI sin {φ}_{vi}\end{matrix} \qquad ( 261 )$$

Therefore, the active power P can be calculated from a first formula of (261) and the reactive power Q can be calculated from a second formula. A power factor can be calculated using the following formula:

$$PF = \frac{P}{\sqrt{{P}^{2} + {Q}^{2}}} = cos {φ}_{vi} \qquad ( 262 )$$

### Second Embodiment

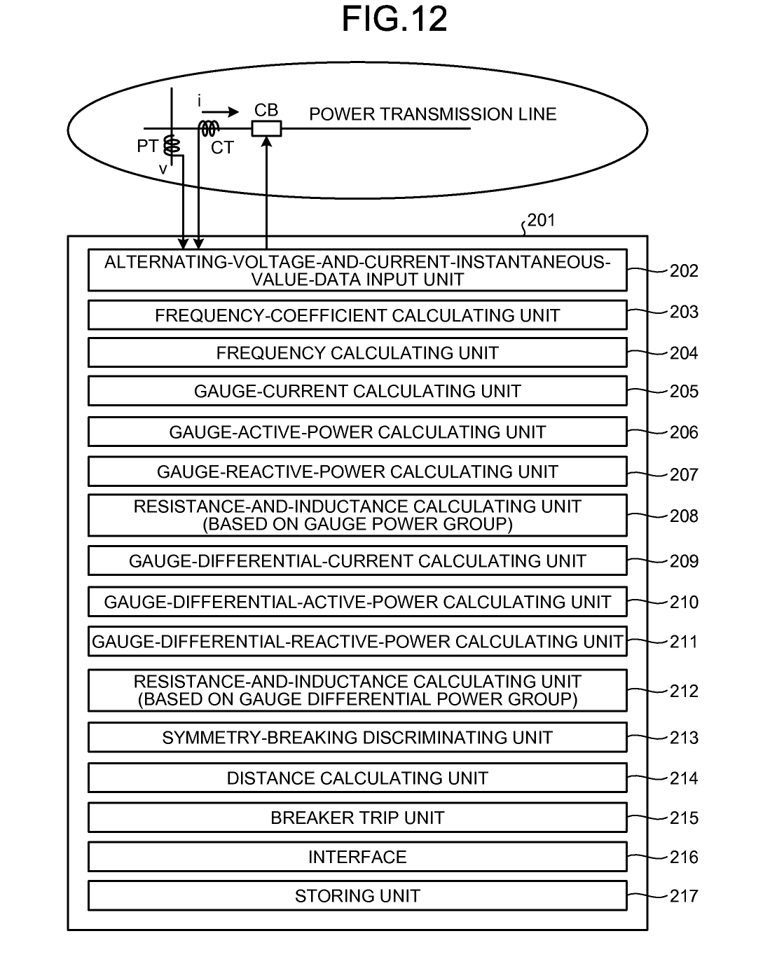

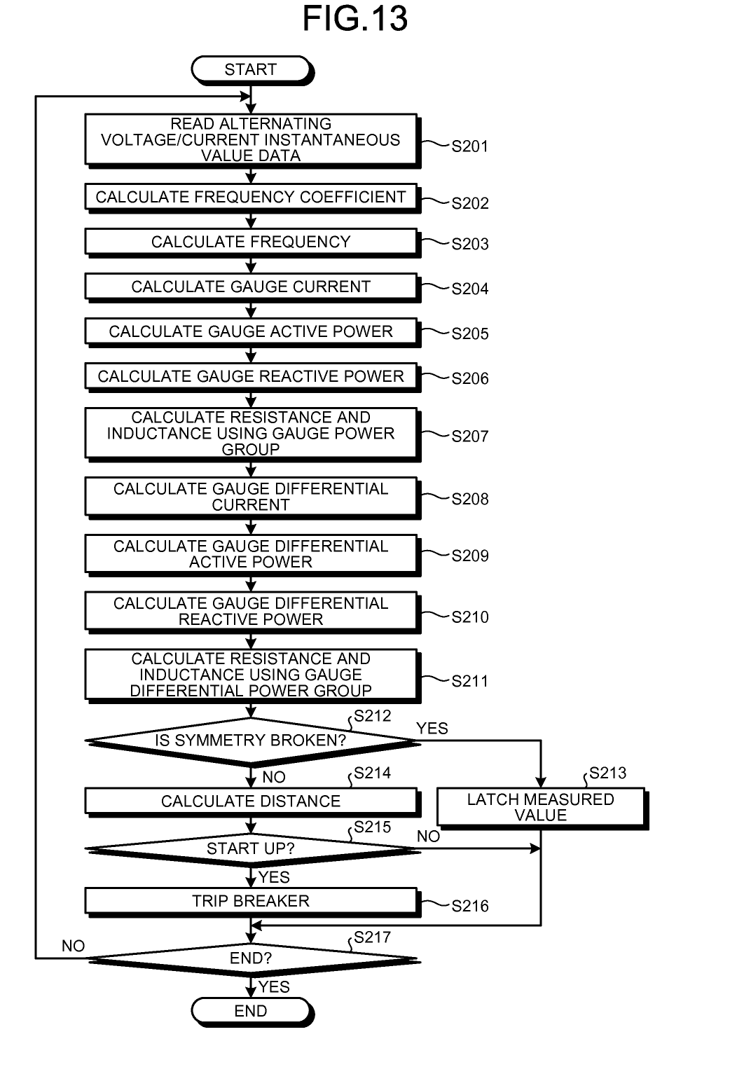

FIG. 12 is a diagram of a functional configuration of a distance protection relay according to a second embodiment. FIG. 13 is a flowchart for explaining a flow of processing in the distance protection relay.

As shown in FIG. 12, a distance protection relay 201 according to the second embodiment includes an alternating-voltage-and-current-instantaneous-value-data input unit 202, a frequency-coefficient calculating unit 203, a frequency calculating unit 204, a gauge-current calculating unit 205, a gauge-active-power calculating unit 206, a gauge-reactive-power calculating unit 207, a resistance-and-inductance calculating unit 208, a gauge-differential-current calculating unit 209, a gauge-differential-active-power calculating unit 210, a gauge-differential-reactive-power calculating unit 211, a resistance-and-inductance calculating unit 212, a symmetry-breaking discriminating unit 213, a distance calculating unit 214, a breaker trip unit 215, an interface 216, and a storing unit 217. The resistance-and-inductance calculating unit 208 is a calculating unit based on a gauge power group. The resistance-and-inductance calculating unit 212 is a calculating unit based on a gauge differential power group. The interface 216 performs processing for outputting a calculation result and the like to a display apparatus and an external apparatus. The storing unit 217 performs processing for storing measurement data, a calculation result, and the like. The distance protection relay 201 can include a gauge-voltage calculating unit instead of the gauge-current calculating unit 205. The distance protection relay 201 can include a gauge-differential-voltage calculating unit instead of the gauge-differential-current calculating unit 209.

In the above configuration, the alternating-voltage-and-current-instantaneous-value-data input unit 202 performs processing for reading out a voltage instantaneous value and a current instantaneous value from a meter transformer (PT) and a current transformer (CT) provided in a power system (step S201). Data of the read-out voltage instantaneous value and the read-out current instantaneous value are stored in the storing unit 217.

The frequency-coefficient calculating unit 203 calculates a frequency coefficient based on the calculation processing explained above (step S202). This calculation processing for a frequency coefficient is the same as or equivalent to the calculation processing in the first embodiment. The frequency calculating unit 204 calculates a frequency (a real frequency) based on the frequency coefficient and the sampling frequency (step S203).

The gauge-current calculating unit 205 calculates a gauge current based on the calculation processing explained above (step S204). Calculation processing for the gauge current can be explained as follows when the calculation processing including the concept of the calculation processing explained above is generally explained. That is, to satisfy the sampling theorem, the gauge-current calculating unit 205 performs processing for calculating, as a gauge current, a value obtained by normalizing, with an amplitude value of an alternating current, a current amplitude calculated by, for example, a square integral operation of current instantaneous value data at continuous at least three points sampled at a sampling frequency twice or more as high as the frequency of an alternating voltage set as a measurement target. In the calculation formula explained above, as the square integral operation, a formula for averaging a difference between a square value of a voltage instantaneous value at intermediate time and a product of voltage instantaneous values at times other than the intermediate time among voltage instantaneous value data at three points is illustrated.

The gauge-active-power calculating unit 206 calculates gauge active power based on the calculation processing explained above (step S205). The gauge-reactive-power calculating unit 207 calculates gauge reactive power based on the calculation processing explained above (step S206). These kinds of calculation processing for the gauge active power and the gauge reactive power are the same as or equivalent to the calculation method in the first embodiment.

The resistance-and-inductance calculating unit 208 calculates resistance using the frequency coefficient calculated by the frequency-coefficient calculating unit 203, the gauge current calculated by the gauge-current calculating unit 205, the gauge active power calculated by the gauge-active-power calculating unit 206, and the gauge reactive power calculated by the gauge-reactive-power calculating unit 207 (step S207). The resistance-and-inductance calculating unit 208 calculates inductance using the frequency coefficient calculated by the frequency-coefficient calculating unit 203, the gauge current calculated by the gauge-current calculating unit 205, and the gauge reactive power calculated by the gauge-reactive-power calculating unit 207 (step S207).

The gauge-differential-current calculating unit 209 calculates a gauge differential current based on the calculation processing explained above (step S208). The gauge-differential-current calculating unit 209 can also be generally explained as follows. That is, the gauge-differential-current calculating unit 209 performs processing for calculating, as a gauge differential current, a value obtained by normalizing, with an amplitude value of an alternating current, a value calculated by, for example, a square integral operation of differential current instantaneous value data at three points each representing an inter-point distance between current instantaneous value data at adjacent two points in current instantaneous value data at continuous at least four points sampled at the sampling frequency and including current instantaneous value data at three points used in calculating the gauge current. In the calculation formula explained above, as the square integral operation, a formula for averaging a difference between a square value of a differential current instantaneous value at intermediate time and a product of differential current instantaneous values at times other than the intermediate time among differential current instantaneous value data at three points is illustrated.

The gauge-differential-active-power calculating unit 210 calculates gauge differential active power based on the calculation processing explained above (step S209). Processing by the gauge-differential-active-power calculating unit 210 can be generally explained as follows. That is, the gauge-differential-active-power calculating unit 210 performs processing for calculating, as a gauge differential active power, a value calculated by a predetermined multiply-subtract operation using differential voltage instantaneous value data at two points measured at early times among differential voltage instantaneous value data at three points each representing an inter-point distance between voltage instantaneous value data at adjacent two points in voltage instantaneous value data at continuous predetermined four points sampled at the sampling frequency and differential current instantaneous value data at two points measured at late times among differential current instantaneous value data at three points each representing an inter-point distance between current instantaneous value data adjacent two points in current instantaneous value data at four points sampled at the sampling frequency and sampled at time same as time of the sampling of voltage instantaneous values at the predetermined four-points.

The gauge-differential-reactive-power calculating unit 211 calculates gauge differential reactive power based on the calculation processing explained above (step S210). Processing by the gauge-differential-reactive power calculating unit 211 can also be generally explained as follows. The gauge-differential-reactive-power calculating unit 211 performs processing for calculating, as a gauge differential reactive power, a value calculated by a predetermined multiply-subtract operation using differential voltage instantaneous value data at two points measured at late times among differential voltage instantaneous value data at three points each representing an inter-point distance between voltage instantaneous value data at adjacent two points in voltage instantaneous value data at continuous predetermined four points sampled at the sampling frequency and differential current instantaneous value data at two points measured at late times among differential current instantaneous value data at three points each representing an inter-point distance between current instantaneous value data at adjacent two points in current instantaneous value data at four points sampled at the sampling frequency and sampled at time same as time of the sampling of voltage instantaneous values at the predetermined four-points.

The resistance-and-inductance calculating unit 212 calculates resistance using the frequency coefficient calculated by the frequency-coefficient calculating unit 203, the gauge differential current calculated by the gauge-differential-current calculating unit 209, the gauge differential active power calculated by the gauge-differential-active-power calculating unit 210, and the gauge differential reactive power calculated by the gauge-differential-reactive-power calculating unit 211 (step S211). The resistance-and-inductance calculating unit 212 calculates inductance using the frequency coefficient calculated by the frequency-coefficient calculating unit 203, the gauge differential current calculated by the gauge-differential-current calculating unit 209, and the gauge differential reactive power calculated by the gauge-differential-reactive-power calculating unit 211 (step S211).

The symmetry-breaking discriminating unit 213 determines breaking of symmetry using, for example, the gauge power symmetry index (step S212). When not determining the breaking of symmetry (No at step S212), the symmetry-breaking discriminating unit 213 calculates a distance to a failure point (a distance coefficient) (step S214) and further determines whether to start up the protection apparatus (step S215). When determining to start up the protection apparatus (e.g., when the distance is within the setting range) (Yes at step S215), the symmetry-breaking discriminating unit 213 trips a breaker (step S216) and shifts to step S217. When determining not to start up the protection apparatus (No at step S215), the symmetry-breaking discriminating unit 213 shifts to step S217 without tripping the breaker. When determining the breaking of symmetry (Yes at step S212), the symmetry-breaking discriminating unit 213 latches a measured value (a calculated value) (step S213) and thereafter shifts to step S217. An index other than the gauge power symmetry index can be used as a determination index for determining breaking of symmetry.

At the last step S217, the distance protection relay 201 performs determination processing for determining whether to end the entire flow explained above. If not to end the flow (No at step S217), the distance protection relay 201 repeats the processing at steps S201 to S216.

The frequency calculated at step S203 is a real frequency. Therefore, unlike the distance protection relay in the past, the distance protection relay in the second embodiment can perform automatic correction of a system real frequency. Therefore, even when a system frequency fluctuates because of an accident, it is possible to perform highly accurate distance measurement. Because the distance protection relay in this embodiment provides a specific distance measured value, the distance protection relay can be applied to an accident point standardizing apparatus as well.

A flow of a distance protection calculation performed using a measurement result of a synchronized phasor is as explained below.

First, when a voltage-current phase angle is represented as φᵥᵢ and a voltage amplitude and a current amplitude are respectively represented as V and I, impedance Z is represented as indicated by the following formula:

$$Z = R + j X = \frac{V}{I} {e}^{j {φ}_{vi}} \qquad ( 263 )$$

Resistance forming a real part of the impedance and inductance forming an imaginary part of the impedance are represented as indicated by the following formula:

$$\{ \begin{matrix}R = \frac{V}{I} cos {φ}_{vi} \\ L = \frac{V}{2 π fI} sin {φ}_{vi}\end{matrix} \qquad ( 264 )$$

When this apparatus is applied to a distance protection relay for a power transmission line, resistance of the power transmission line from a place where the distance protection relay is arranged to an earth point or a short-circuit point can be calculated from a first formula of (264). The inductance of the power transmission line to the earth point or the short-circuit point can be calculated from a second formula of (264).

### Third Embodiment

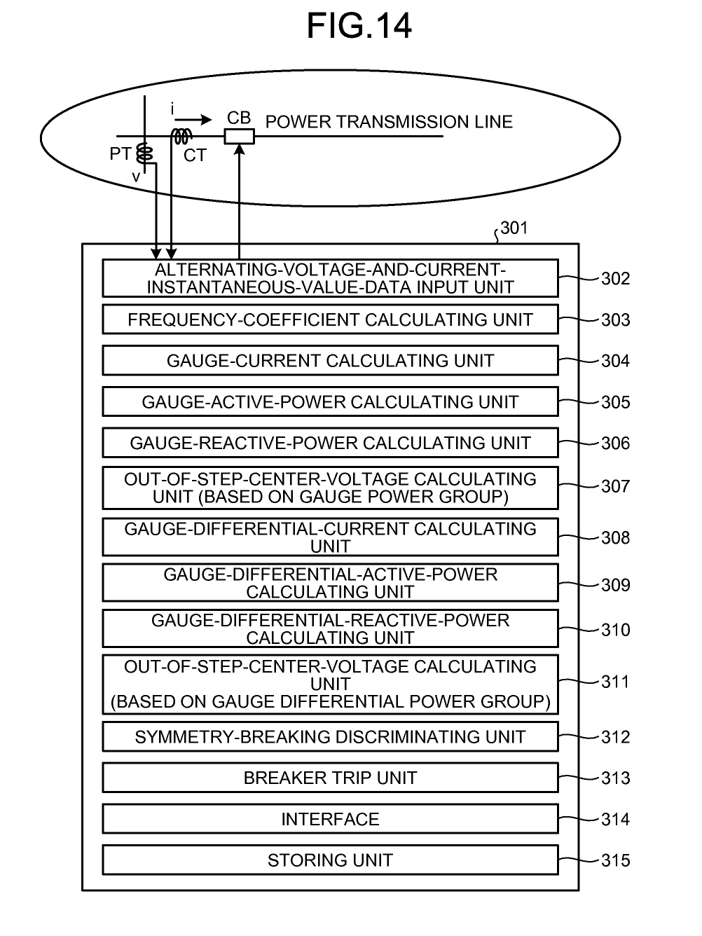

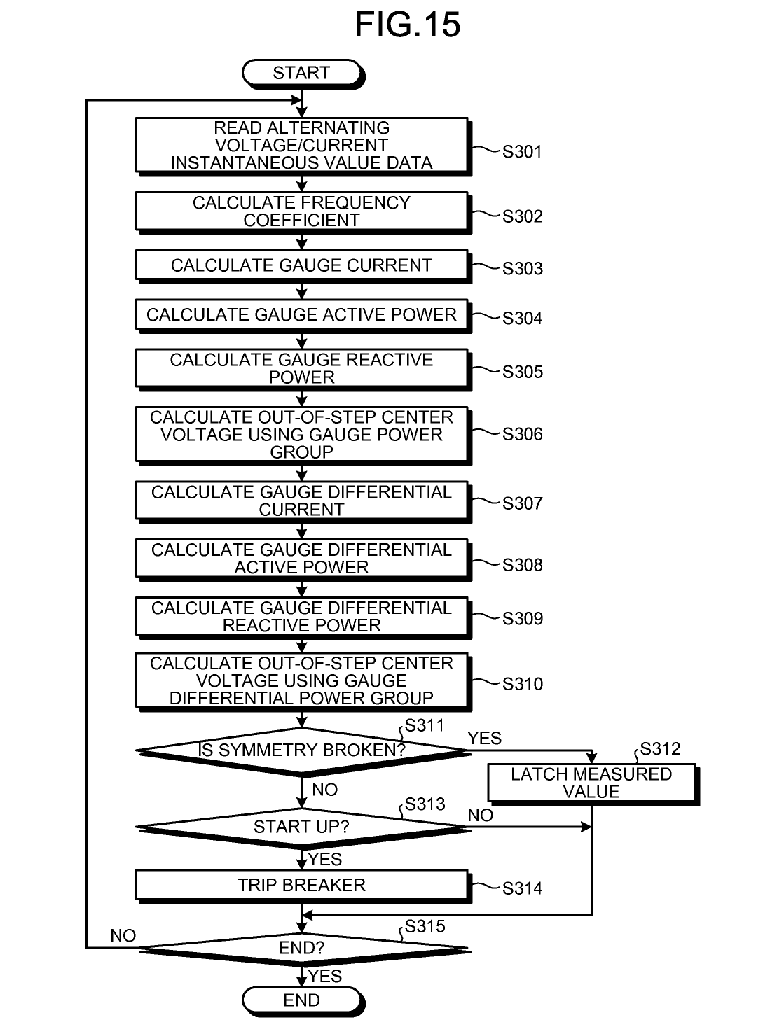

FIG. 14 is a diagram of a functional configuration of an out-of-step protection relay according to a third embodiment. FIG. 15 is a flowchart for explaining a flow of processing in the out-of-step protection relay.

As shown in FIG. 14, an out-of-step protection apparatus according to the third embodiment includes an alternating-voltage-and-current-instantaneous-value-data input unit 302, a frequency-coefficient calculating unit 303, a gauge-current calculating unit 304, a gauge-active-power calculating unit 305, a gauge-reactive-power calculating unit 306, an out-of-step-center-voltage calculating unit 307, a gauge-differential-current calculating unit 308, a gauge-differential-active-power calculating unit 309, a gauge-differential-reactive-power calculating unit 310, an out-of-step-center-voltage calculating unit 311, a symmetry-breaking discriminating unit 312, a breaker trip unit 313, an interface 314, and a storing unit 315. The out-of-step-center-voltage calculating unit 307 is a calculating unit based on a gauge power group. The out-of-step-center-voltage calculating unit 311 is a calculating unit based on a gauge differential power group. The interface 314 performs processing for outputting a calculation result and the like to a display apparatus and an external apparatus. The storing unit 315 performs processing for storing measurement data, a calculation result, and the like.

In the configuration explained above, the alternating-voltage-and-current-instantaneous-value-data input unit 302 performs processing for reading out a voltage instantaneous value and a current instantaneous value from a meter transformer (PT) and a current transformer (CT) provided in a power system (step S301). Data of the read-out voltage instantaneous value and the read-out current instantaneous value are stored in the storing unit 315.

The frequency-coefficient calculating unit 303 calculates a frequency coefficient based on the calculation processing explained above (step S302). This calculation processing for a frequency coefficient is the same as or equivalent to the calculation processing in the first and second embodiments. The gauge-current calculating unit 304 calculates a gauge current based on the calculation processing explained above (step S303). The gauge-active-power calculating unit 305 calculates gauge active power based on the calculation processing explained above (step S304). The gauge-reactive-power calculating unit 306 calculates gauge reactive power based on the calculation processing explained above (step S305). These kinds of calculation processing for a gauge current, gauge active power, and gauge reactive power are the same as or equivalent to the calculation processing in the second embodiment.

The out-of-step-center-voltage calculating unit 307 calculates an out-of-step center voltage using the frequency coefficient calculated by the frequency-coefficient calculating unit 303, the gauge current calculated by the gauge-current calculating unit 304, the gauge active power calculated by the gauge-active-power calculating unit 305, and the gauge reactive power calculated by the gauge-reactive-power calculating unit 306 (step S306).

The gauge-differential-current calculating unit 308 calculates a gauge differential current based on the calculation processing explained above (step S307). The gauge-differential-active-power calculating unit 309 calculates gauge differential active power based on the calculation processing explained above (step S308). The gauge-differential-reactive-power calculating unit 310 calculates gauge differential reactive power based on the calculation processing explained above (step S309). These kinds of calculation processing for a gauge differential current, gauge differential active power, and gauge differential reactive power are the same as or equivalent to the calculation processing in the second embodiment.

The out-of-step-center-voltage calculating unit 311 calculates an out-of-step center voltage using the frequency coefficient calculated by the frequency-coefficient calculating unit 303, the gauge current calculated by the gauge-current calculating unit 304, the gauge active power calculated by the gauge-active-power calculating unit 305, and the gauge reactive power calculated by the gauge-reactive-power calculating unit 306 (step S310).

The symmetry-breaking discriminating unit 312 determines breaking of symmetry using, for example, the gauge power symmetry index or the gauge differential power symmetry index (step S311). When not determining the breaking of symmetry (No at step S311), the symmetry-breaking discriminating unit 312 further determines whether to start up the out-of-step protection relay (step S313). When determining to start up the out-of-step protection relay (e.g., when the out-of-step center voltage is smaller than a setting value (e.g., 0.3 PU)) (Yes at step S313), the symmetry-breaking discriminating unit 312 trips a breaker (step S314) and shifts to step S315. When determining not to start up the out-of-step protection relay (No at step S313), the symmetry-breaking discriminating unit 312 shifts to step S315 without tripping the breaker. When determining the breaking of symmetry (Yes at step S311), the symmetry-breaking discriminating unit 312 latches a measured value (a calculated value) (step S312) and thereafter shifts to step S315. An index other than the gauge differential power symmetry index can be used as a determination index for determining breaking of symmetry.

At the last step S315, the out-of-step protection relay 301 performs determination processing for determining whether to end the entire flow explained above. If not to end the flow (No at step S315), the out-of-step protection relay 301 repeats the processing at steps S301 to S314.

In the second embodiment, an embodiment in which a measurement result of a phasor is applied to the distance protection relay is explained. In the third embodiment, likewise, a measurement result of a phasor can be applied to the out-of-step protection relay.

### Fourth Embodiment

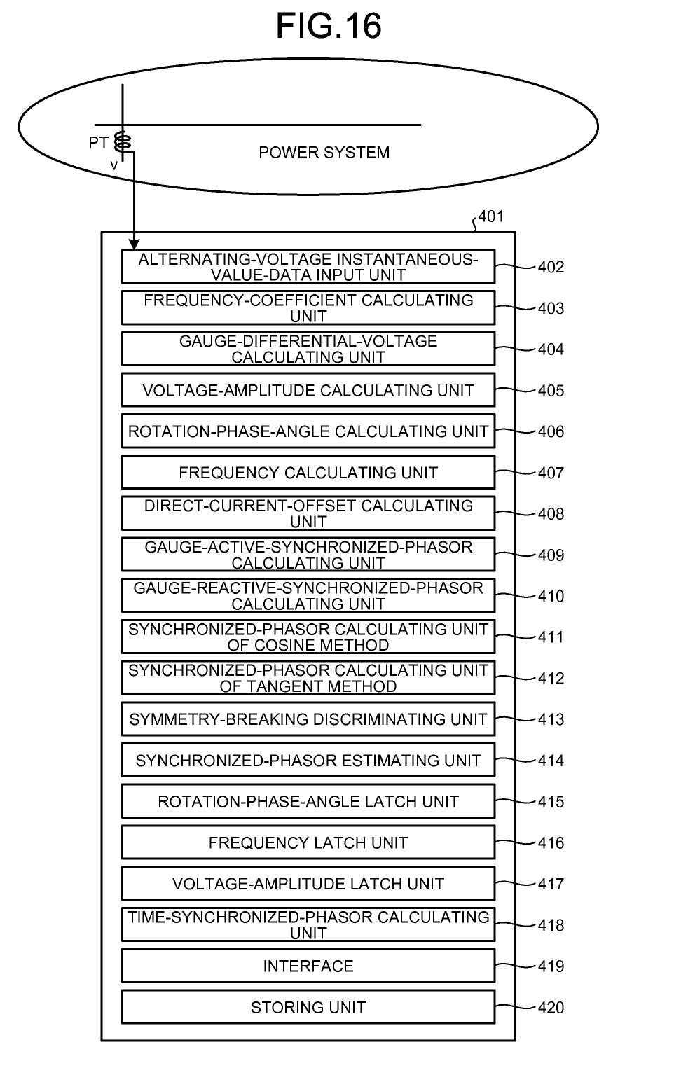

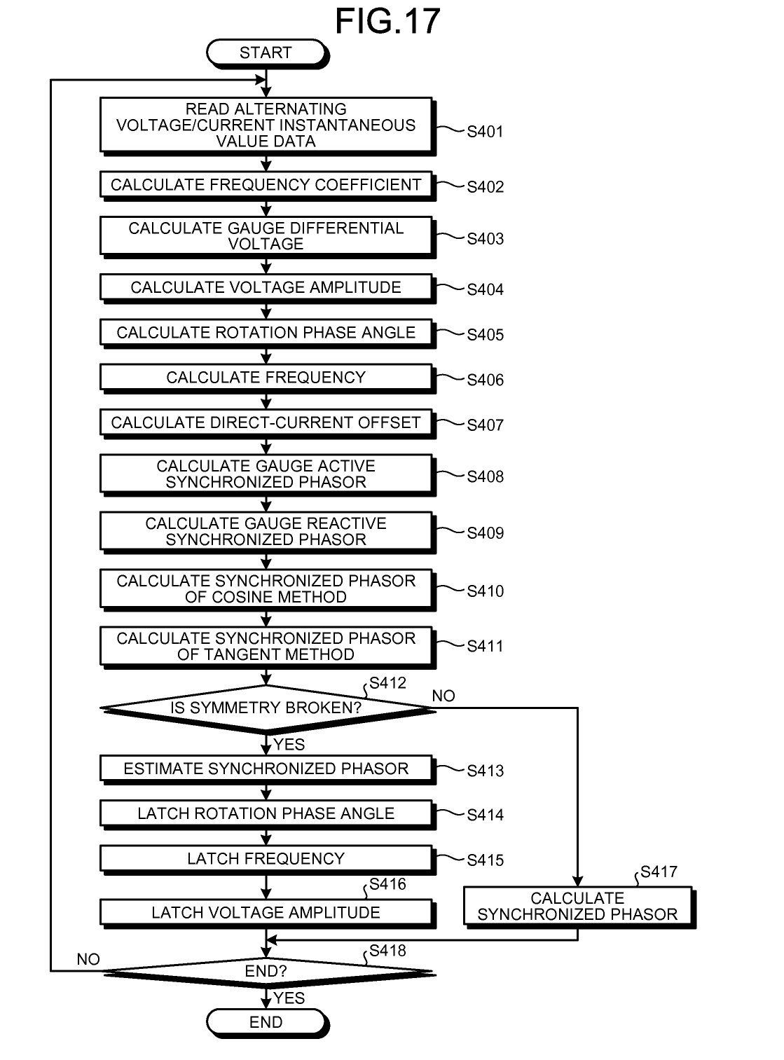

FIG. 16 is a diagram of a functional configuration of a time-synchronized-phasor measuring apparatus according to a fourth embodiment. FIG. 17 is a flowchart for explaining a flow of processing in the time-synchronized-phasor measuring apparatus.

As shown in FIG. 16, a time-synchronized-phasor measuring apparatus 401 according to the fourth embodiment includes an alternating-voltage-instantaneous-value-data input unit 402, a frequency-coefficient calculating unit 403, a gauge-differential-voltage calculating unit 404, a voltage-amplitude calculating unit 405, a rotation-phase-angle calculating unit 406, a frequency calculating unit 407, a direct-current-offset calculating unit 408, a gauge-active-synchronized-phasor calculating unit 409, a gauge-reactive-synchronized-phasor calculating unit 410, a synchronized-phasor calculating unit (a cosine method) 411, a synchronized-phasor calculating unit (a tangent method) 412, a symmetry-breaking discriminating unit 413, a synchronized-phasor estimating unit 414, a rotation-phase-angle latch unit 415, a frequency latch unit 416, a voltage-amplitude latch unit 417, a time-synchronized-phasor calculating unit 418, an interface 419, and a storing unit 420. The interface 419 performs processing for outputting a calculation result and the like to a display apparatus and an external apparatus. The storing unit 420 performs processing for storing measurement data, a calculation result, and the like. The time-synchronized-phasor measuring apparatus 401 can include a gauge-differential-active-synchronized-phasor calculating unit instead of the gauge-active-synchronized-phasor calculating unit 409. The time-synchronized-phasor measuring apparatus 401 can include a gauge-differential-reactive-synchronized-phasor calculating unit instead of the gauge-reactive-synchronized-phasor calculating unit 410.

In the configuration explained above, the alternating-voltage-instantaneous-value-data input unit 402 performs processing for reading out a voltage instantaneous value from a meter transformer (PT) provided in a power system (step S401). Read-out voltage instantaneous value data is stored in the storing unit 420.

The frequency-coefficient calculating unit 403 calculates a frequency coefficient based on the calculation processing explained above (step S402). This calculation processing for a frequency coefficient is the same as or equivalent to the calculation processing in the first to third embodiments.

The gauge-differential-voltage calculating unit 404 calculates a gauge differential voltage based on the calculation processing explained above (step S403). To explain more in detail and generally, the gauge-differential-voltage calculating unit 404 performs processing for calculating, as a gauge differential voltage, a value obtained by normalizing, with an amplitude value of an alternating voltage, a value calculated by, for example, a square integral operation of differential voltage instantaneous value data at three points each representing an inter-point distance between voltage instantaneous value data at adjacent two points in voltage instantaneous value data at continuous at least four points sampled at the sampling frequency and sampled at a sampling frequency twice or more as high as the frequency of an alternating voltage set as a measurement target. In the calculation formula explained above, as the square integral operation, a formula for averaging a difference between a square value of a differential voltage instantaneous value at intermediate time and a product of differential voltage instantaneous values at times other than the intermediate time among differential voltage instantaneous value data at three points is illustrated.

The voltage-amplitude calculating unit 405 calculates a voltage amplitude using the frequency coefficient calculated by the frequency-coefficient calculating unit 403 and the gauge differential voltage calculated by the gauge-differential-voltage calculating unit 404 (step S404). The rotation-phase-angle calculating unit 406 calculates a rotation phase angle using the frequency coefficient calculated by the frequency-coefficient calculating unit 403 (step S405). The frequency calculating unit 407 calculates a frequency using the frequency coefficient calculated by the frequency-coefficient calculating unit 403 (step S406).

The direct-current-offset calculating unit 408 calculates a direct-current offset using differential voltage instantaneous value data at three points used in calculating the gauge differential voltage or voltage instantaneous value data at three points among voltage instantaneous value data at four points, which are sources of the differential voltage instantaneous value data at the three points, and the frequency coefficient calculated by the frequency-coefficient calculating unit 403 (step S407).

The gauge-active-synchronized-phasor calculating unit 409 calculates a gauge active synchronized phasor based on the calculation processing explained above (step S408). To explain more in detail and generally, the gauge-active-synchronized-phasor calculating unit 409 performs processing for calculating, as a gauge active synchronized phasor, a value calculated by a predetermined multiply-subtract operation using voltage instantaneous value data at two points measured at late times among voltage instantaneous value data at continuous three points sampled at the sampling frequency, a first fixed unit vector present on a complex plane same as a complex plane of an alternating voltage (an alternating current) set as a measurement target, and a second fixed unit vector delayed by the rotation phase angle calculated by the rotation-phase-angle calculating unit 406 with respect to the first fixed unit vector.

The gauge-reactive-synchronized-phasor calculating unit 410 calculates a gauge reactive synchronized phasor based on the calculation processing explained above (step S409). To explain more in detail and generally, the gauge-reactive-synchronized-phasor calculating unit 410 performs processing for calculating, as a gauge reactive synchronized phasor, a value calculated by a predetermined multiply-subtract operation using voltage instantaneous value data at two points measured at early times among voltage instantaneous voltage instantaneous value data at three points used in calculating the gauge active synchronized phasor and first and second fixed unit vectors used in calculating the gauge active synchronized phasor.

The synchronized-phasor calculating unit (the cosine method) 411 applies calculation processing by the cosine method explained above and calculates a synchronized phasor using the gauge active synchronized phasor calculated by the gauge-active-synchronized-phasor calculating unit 409, the gauge reactive synchronized phasor calculated by the gauge-reactive-synchronized-phasor calculating unit 410, the rotation phase angle calculated by the rotation-phase-angle calculating unit 406, and the voltage amplitude calculated by the voltage-amplitude calculating unit 405 (step S410).

The synchronized-phasor calculating unit (the tangent method) 412 applies calculation processing by the tangent method explained above and calculates a synchronized phasor using the gauge active synchronized phasor calculated by the gauge-active-synchronized-phasor calculating unit 409, the gauge reactive synchronized phasor calculated by the gauge-reactive-synchronized-phasor calculating unit 410, and the rotation phase angle calculated by the rotation-phase-angle calculating unit 406 (step S411).

The symmetry-breaking discriminating unit 413 determines breaking of symmetry using, for example, the synchronized phasor symmetry index (step S412). When determining the breaking of symmetry (Yes at step S412), a synchronized phasor is estimated by the synchronized-phasor estimating unit 414 (step S413), a rotation phase angle is latched by the rotation-phase-angle latch unit 415 (step S414), a frequency is latched by the frequency latch unit 416 (step S415), a voltage amplitude is latched by the voltage-amplitude latch unit 417 (step S416), and, thereafter, the symmetry-breaking discriminating unit 413 shifts to step S418. On the other hand, when not determining the breaking of symmetry (No at step S412), a time synchronized phasor is calculated by the time-synchronized-phasor calculating unit 418 (step S417) and, thereafter, the symmetry-breaking discriminating unit 413 shifts to step S418. The time synchronized phasor is a difference value between a synchronized phasor at the present point and a synchronized phasor one or several cycles before the present point and is calculated as indicated by the following formula:

$${φ}_{TP} = \{ \begin{matrix}{φ}_{t} - {φ}_{t - {T}_{0}} - 2 π , & {φ}_{t} - {φ}_{t - {T}_{0}} > π \\ {φ}_{t} - {φ}_{t - {T}_{0}} + 2 π , & {φ}_{t} - {φ}_{t - {T}_{0}} < - π \\ {φ}_{t} - {φ}_{t - {T}_{0}} , & others\end{matrix} \qquad ( 265 )$$

In the formula, φₜ represents a synchronized phasor at the present point and φ_{t-T0} represents a synchronized phasor at designated time (time t₀ before the present point).

At the last step S418, the time-synchronized-phasor measuring apparatus 401 performs determination processing for determining whether to end the entire flow explained above. If not to tend the flow (No at step S418), the time-synchronized-phasor measuring apparatus 401 repeats the processing at steps S401 to S417.

### Fifth Embodiment

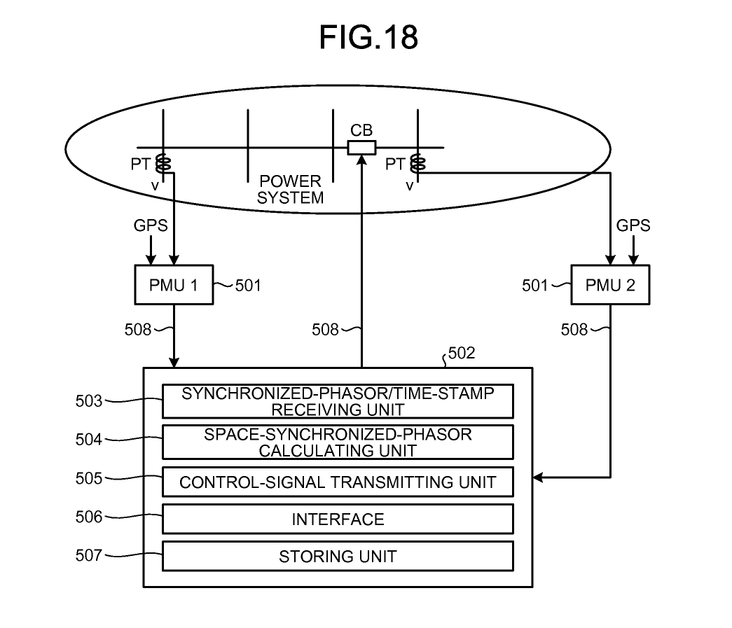

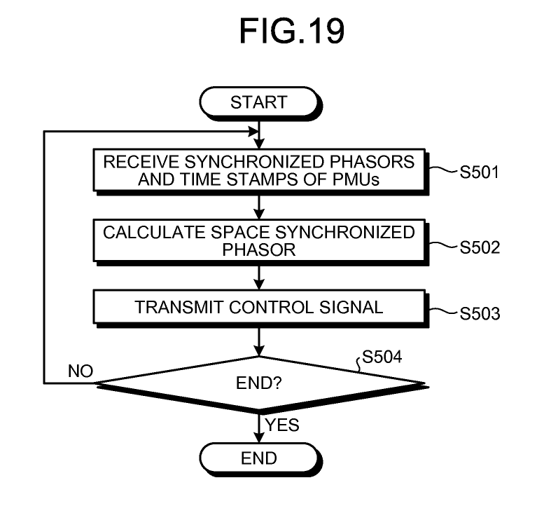

FIG. 18 is a diagram of a functional configuration of a space-synchronized-phasor measuring apparatus according to a fifth embodiment. FIG. 19 is a flowchart for explaining a flow of processing in the space-synchronized-phasor measuring apparatus.

As shown in FIG. 18, a space-synchronized-phasor measuring apparatus 502 according to the fifth embodiment includes a synchronized-phasor/time-stamp receiving unit 503, a space-synchronized-phasor calculating unit 504, a control-signal transmitting unit 505, an interface 506, and a storing unit 507. The space-synchronized-phasor measuring apparatus 502 is arranged in a power control place or the like. In FIG. 18, synchronized-phasor measuring apparatuses (Phasor Measurement Units: PMUs) 501 arranged in a transformer substation or the like are provided (PMU 1 and PMU 2). The space-synchronized-phasor measuring apparatus 502 is configured to receive information from these synchronized-phasor measuring apparatuses 501 through communication lines 508. The interface 506 performs processing for outputting a calculation result and the like to a display apparatus and an external apparatus. The storing unit 507 performs processing for storing measurement data, a calculation result, and the like.

In the configuration explained above, the synchronized-phasor/time-stamp receiving unit 503 receives synchronized phasors measured by the synchronized-phasor measuring apparatuses 501 arranged in other places and time stamps affixed to the synchronized phasors (step S501). The space-synchronized-phasor calculating unit 504 calculates a space synchronized phasor, which is a difference value between a synchronize phasor at an own end and a synchronized phasor at the other end (step S502). This space synchronized phasor φ_{SP} is calculated as indicated by the following formula:

$${φ}_{SP} = \{ \begin{matrix}{φ}_{1} - {φ}_{2} - 2 π , & {φ}_{1} - {φ}_{2} > π \\ {φ}_{1} - {φ}_{2} + 2 π , & {φ}_{1} - {φ}_{2} < - π \\ {φ}_{1} - {φ}_{2} , & others\end{matrix} \qquad ( 266 )$$

In the formula, φ₁ represents a synchronized phasor of a terminal 1 and φ₂ represents a synchronized phasor of a terminal 2 at the same time and is calculated as indicated by the following formula:

$${φ}_{2} = \{ \begin{matrix}{φ}_{2 t 2} + 2 π {f}_{2} ( {t}_{1} - {t}_{2} ) , & {φ}_{2 t 2} + 2 π {f}_{2} ( {t}_{1} - {t}_{2} ) \leq π \\ {φ}_{2 t 2} + 2 π {f}_{2} ( {t}_{1} - {t}_{2} ) - 2 π , & {φ}_{2 t 2} + 2 π {f}_{2} ( {t}_{1} - {t}_{2} ) > π\end{matrix} \qquad ( 267 )$$

In the formula, t₁ represents a time tag of the synchronized phasor of the terminal 1 and t₂ represents a time tag of the synchronized phasor of the terminal 2. As values of these time tags, it is desirable to use universal time coordinate called UTC making use of a GPS or the like.

The control-signal transmitting unit 505 determines stability/un-stability of a system using the space synchronized phasor calculated by the space-synchronized-phasor calculating unit 504. When the system becomes unstable because of out-of-step or the like, the control-signal transmitting unit 505 transmits a control signal (step S503).

At the last step S504, the space-synchronized-phasor measuring apparatus 502 performs determination processing for determining whether to end the entire flow explained above. If not to end the flow (No at step S504), the space-synchronized-phasor measuring apparatus 502 repeats the processing at steps S501 to S513.

### Sixth Embodiment

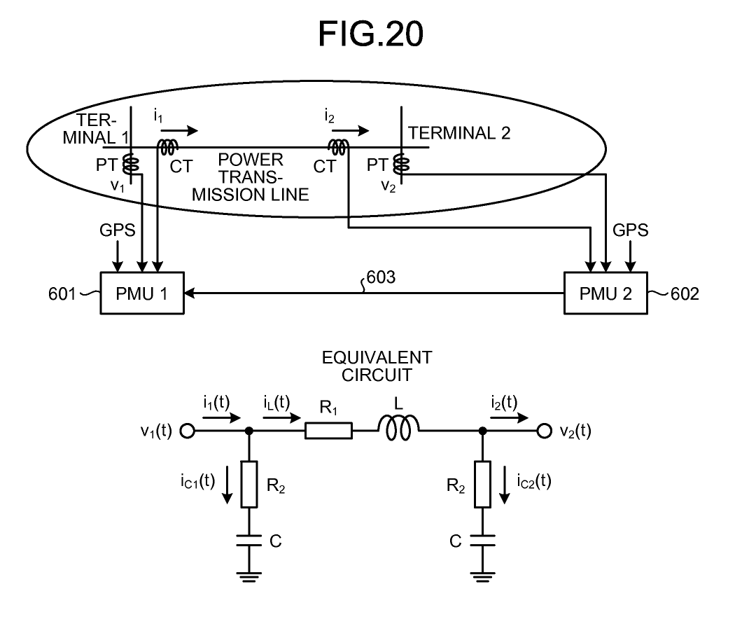

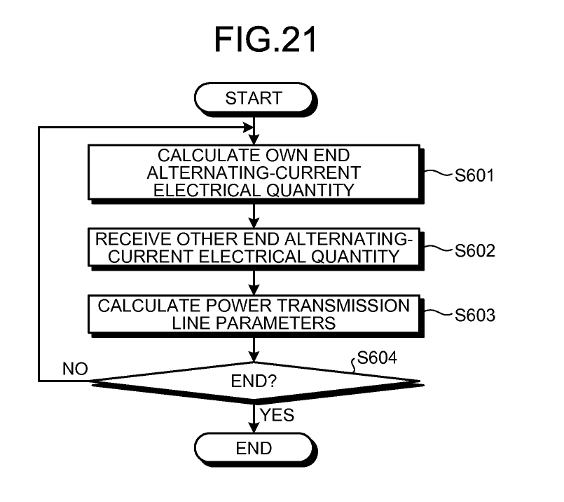

FIG. 20 is a diagram of a functional configuration of a power transmission line parameter measuring system according to a sixth embodiment. FIG. 21 is a flowchart for explaining a flow of processing in the power transmission line parameter measuring system.

As shown in FIG. 20, the power transmission line parameter measuring system according to the sixth embodiment includes two synchronized-phasor measuring apparatuses 601 (PMU 1) and 602 (PMU 2). Voltage instantaneous values and current instantaneous values from meter transformers (PT) and current transformers (CT) provided on a power transmission line, GPS time signals from GPS apparatuses, and the like are input to the synchronized-phasor measuring apparatuses 601 and 602. The synchronized-phasor measuring apparatus 602 present on the terminal 2 side measures a voltage amplitude and a synchronized phasor at the own end and notifies the synchronized-phasor measuring apparatus 601 present on the terminal 1 side of the voltage amplitude and the synchronized phasor through a communication line 603. The synchronized-phasor measuring apparatus 601 calculates a voltage amplitude and a synchronized phasor at the own end (step S601), receives a measurement result of the synchronized-phasor measuring apparatus 602 (step S602), and calculates power transmission line parameters using measurement results of the synchronized-phasor measuring apparatuses 601 and 602 (step S603). According to the technology proposed by the present invention, it is possible to measure voltage and current amplitudes and synchronized phasors at both the ends.

At the last step S604, the power transmission line parameter measuring system performs determination processing for determining whether to end the entire flow explained above. If not to end the flow (No at step S604), the power transmission line parameter measuring system repeats the processing at steps S601 to S603.

A flow of a procedure for calculating power transmission line parameters when a power transmission line is compared to a π type equivalent circuit as shown in a lower part of FIG. 20 is as explained below.

First, measurement results by a meter transformer (PT) and a current transformer (CT) are represented as indicated by the following formula:

$$\{ \begin{matrix}{v}_{1} ( t ) = {V}_{1} {e}^{j {φ}_{V 1}} \\ {i}_{1} ( t ) = {I}_{1} {e}^{j {φ}_{I 1}} \\ {v}_{2} ( t ) = {V}_{2} {e}^{j {φ}_{V 2}} \\ {i}_{2} ( t ) = {I}_{2} {e}^{j {φ}_{I 2}}\end{matrix} \qquad ( 268 )$$

In the formula, V₁, V₂, φ_{VI}, and φ_{V2} respectively represent voltage amplitudes and voltage synchronized phasors at the ends and I₁, I₂, φ_{I1}, and φ_{I2} respectively represent current amplitudes and current synchronized phasors at the ends. An admittance, which is a line parameter of the power transmission line, is represented as indicated by the following formula:

$$\{ \begin{matrix}{Y}_{1} = \frac{1}{{R}_{1} + j ω L} \\ {Y}_{2} = \frac{1}{{R}_{2} + \frac{1}{j ω C}}\end{matrix} \qquad ( 269 )$$

In the formula, R₁ and R₂ represent resistances, L represents inductance, and C represents capacitance. According to the Kirchhoff's law, a circuit equation is as indicated by the following formula:

$$\{ \begin{matrix}{i}_{1} ( t ) = {i}_{L} ( t ) + {i}_{C 1} ( t ) \\ {i}_{2} ( t ) = {i}_{L} ( t ) + {i}_{C 2} ( t ) \\ {i}_{L} ( t ) = [ {v}_{1} ( t ) - {v}_{2} ( t ) ] {Y}_{1} \\ {i}_{C 1} ( t ) = {v}_{1} ( t ) {Y}_{2} \\ {i}_{C 2} ( t ) = {v}_{2} ( t ) {Y}_{2}\end{matrix} \qquad ( 270 )$$

From Formula (270), the following solution is obtained:

$$\{ \begin{matrix}{Y}_{1} = \frac{{v}_{1} ( t ) {i}_{2} ( t ) + {v}_{2} ( t ) {i}_{1} ( t )}{{{v}_{1} ( t )}^{2} - {{v}_{2} ( t )}^{2}} \\ {Y}_{2} = \frac{{i}_{1} ( t ) - {i}_{2} ( t )}{{v}_{1} ( t ) + {v}_{2} ( t )}\end{matrix} \qquad ( 271 )$$

Therefore, from Formulas (269) and (271), power transmission line parameters are obtained as follows:

$$\{ \begin{matrix}{R}_{1} = Re ( \frac{1}{{Y}_{1}} ) \\ {R}_{2} = Re ( \frac{1}{{Y}_{2}} ) \\ L = \frac{1}{2 π f} Im ( \frac{1}{{Y}_{1}} ) \\ C = - \frac{1}{2 π f Im} ( \frac{1}{{Y}_{2}} )\end{matrix} \qquad ( 272 )$$

In the above formula, “Re” and “Im” respectively mean that a real part and an imaginary part of a complex number are calculated. In the above formula, f represents a real frequency.

### Seventh Embodiment

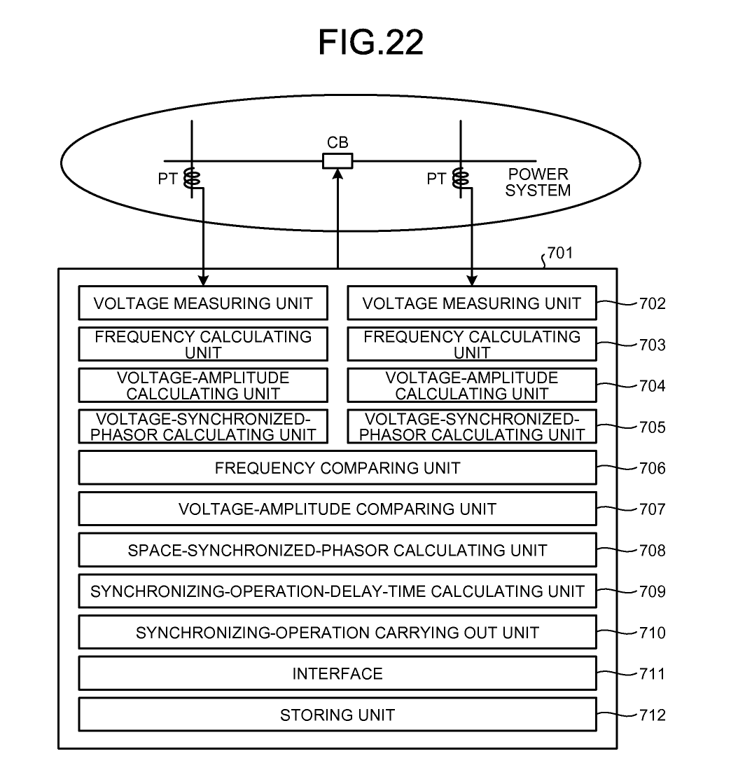

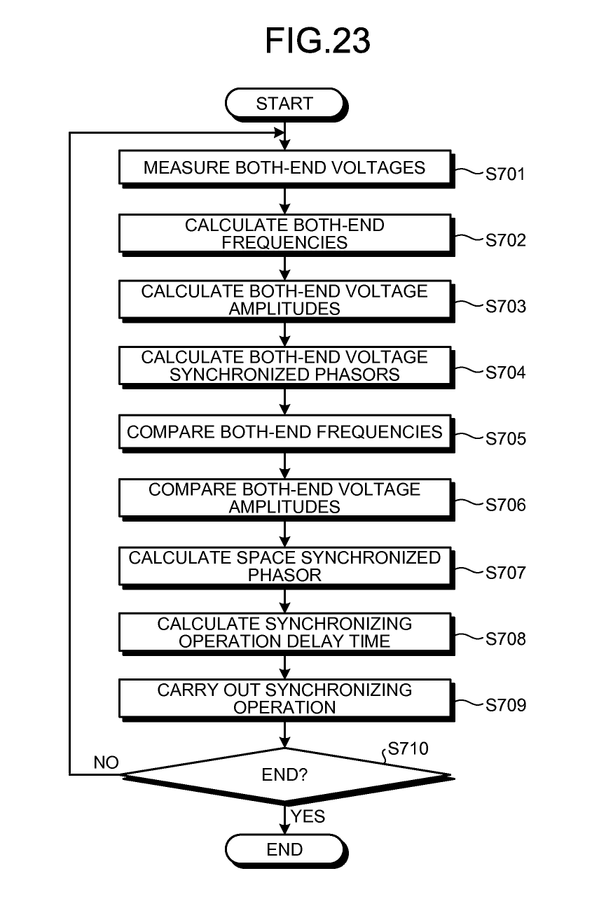

FIG. 22 is a diagram of a functional configuration of an automatic synchronizer according to a seventh embodiment. FIG. 23 is a flowchart for explaining a flow of processing in the automatic synchronizer.

As shown in FIG. 22, an automatic synchronizer 701 according to the seventh embodiment includes a voltage measuring unit 702, a frequency calculating unit 703, a voltage-amplitude calculating unit 704, a voltage-synchronized-phasor calculating unit 705, a frequency comparing unit 706, a voltage-amplitude comparing unit 707, a space-synchronized-phasor calculating unit 708, a synchronizing-operation-delay-time calculating unit 709, a synchronizing-operation carrying out unit 710, an interface 711, and a storing unit 712. The interface 711 performs processing for outputting a calculation result and the like to a display apparatus and an external apparatus. The storing unit 712 performs processing for storing measurement data, a calculation result, and the like.

A flow of processing by the automatic synchronizer 701 is explained with reference to FIGS. 22 and 23. Respective functions of the units are based on the calculation formulas explained above. Explanation of the functions duplicates the explanation in the apparatuses in the first to sixth embodiments. Therefore, only the flow of the processing and new matters are explained. Detailed explanation of the functions is omitted.

The voltage measuring unit 702 receives an input of voltage instantaneous values from meter transformers (PT) provided at one end and the other end of a power system and measures voltages at the ends (both-end voltages) (step S701). The frequency calculating unit 703 calculates frequencies in the terminals 1 and 2 (both-end frequencies) (step S702). The voltage-amplitude calculating unit 704 calculates voltage amplitudes in the terminals 1 and 2 (both-end voltage amplitudes) (step S703). When a power system is a separated system, a formula representing the voltages measured at the ends is as indicated by the following formula:

$$\{ \begin{matrix}{v}_{1} ( t ) = {V}_{1} {e}^{j {φ}_{1}} \\ {v}_{2} ( t ) = {V}_{2} {e}^{j {φ}_{2}}\end{matrix} \qquad ( 273 )$$

In the formula, V₁ and φ₁ respectively represent a voltage amplitude and a voltage synchronized phasor at the present point in the terminal 1. V₂ and φ₂ respectively represent a voltage amplitude and a voltage synchronized phasor at the present point in the terminal 2.

The voltage-synchronized-phasor calculating unit 705 calculates voltage synchronized phasors in the terminals 1 and 2 (both-end voltage synchronized phasors) (step S704). The frequency comparing unit 706 compares the both-end frequencies (step S705). In this comparison processing, determination processing indicated by the following formula is performed:

|f₁−f₂|<Δf_{SET} (274)

In the formula, f₁ represents the calculated frequency (real frequency) in the terminal 1 and f₂ represents the calculated frequency (real frequency) in the terminal 2. Δf_{SET} represents a designated value for determination.

The voltage-amplitude comparing unit 707 compares the both-end voltage amplitudes (step S706). In this comparison processing, determination processing indicated by the following formula is performed:

|V₁−V₂|<ΔV_{SET} (275)

In the formula, V₁ represents a voltage amplitude in the terminal 1 and V₂ represents a voltage amplitude in the terminal 2. ΔV_{SET} represents a designated value for determination.

When conditions of Formula (274) and Formula (275) are satisfied, the space-synchronized-phasor calculating unit 708 calculates a space synchronized phasor using the voltage synchronized phasors in the terminals 1 and 2 calculated by the voltage-synchronized-phasor calculating unit 705 (step S707).

The synchronizing-operation-delay-time calculating unit 709 calculates a synchronizing operation delay time (an automatic synchronizer operation delay time: T_{ASY}) (step S708). This processing at step S708 is executed in a procedure (sub-steps) explained below.

First, the synchronizing-operation-delay-time calculating unit 709 calculates a synchronizing estimated time Tₑₛₜ using the following formula:

$${T}_{est} = \frac{{φ}_{1} - {φ}_{2}}{2 π ( {f}_{1} - {f}_{2} )} \qquad ( 276 )$$

In the formula, f₁ and φ₁ respectively represent a real frequency and a voltage synchronized phasor at the present point in the terminal 1 and f₂ and φ₂ respectively represent a real frequency and a voltage synchronized phasor at the present point in the terminal 2. Therefore, the synchronizing estimated time Tₑₛₜ indicated by Formula (276) means a time difference corresponding to a space synchronized phasor between the terminals 1 and 2.

When a command is transmitted to the automatic synchronizer, a calculation time (a logic calculation time) of the apparatus and a transmission time of a control signal have to be taken into account. When the logic calculation time is represented as T_{CAL} and the control signal transmission time is represented as T_{COM}, there is a relation indicated by the following formula between the automatic synchronizer operation delay time T_{ASY} and synchronizing estimated time Tₑₛₜ and the logic calculation time T_{CAL} and control signal transmission time T_{COM}:

Tₑₛₜ=T_{cal}+T_{com}+T_{ASY} (277)

Therefore, the automatic synchronizer operation delay time T_{ASY} can be calculated based on the following formula:

T_{ASY}=Tₑₛₜ−T_{cal}−T_{com} (278)

Referring back to the flow, the synchronizing-operation carrying out unit 710 carries out synchronizing operation based on the automatic synchronizer operation delay time T_{ASY} indicated by Formula (279) (step S709).

At the last step S710, the automatic synchronizer 701 performs determination processing for determining whether to end the entire flow explained above. When not to end the flow (No at step S710), the automatic synchronizer 701 repeatedly performs the processing at steps S701 to S709.

### Eighth Embodiment

In an eighth embodiment, a frequency measuring apparatus and a frequency change ratio measuring apparatus are explained. In an example explained below, the frequency measuring method explained above is applied to a startup logic in starting up an islanding detecting apparatus, which is a kind of a monitoring control apparatus.

First, a typical frequency change ratio discrimination formula in the islanding detecting apparatus is explained. This discrimination formula is as indicated by the following formula:

$$\frac{{f}_{t} - {f}_{t - {T}_{0}}}{{T}_{0}} > {df}_{SET} \qquad ( 279 )$$

In the formula, fₜ, f_{t-T0}, and df_{SET} respectively represent the present point, a designated time T0 (e.g., three cycle time of a rated frequency), and a startup setting value for independent operation detection.

According to the frequency coefficient measuring method according to the present invention explained above, it is possible to determine symmetry breaking of a voltage waveform using various symmetry indexes such as the rotation phase angle symmetry index. It is possible to prevent the influence of a voltage flicker or the like on a measurement result by latching already-measured data. Therefore, it is possible to provide a highly accurate frequency measuring apparatus and a highly accurate frequency change ratio measuring apparatus.

The frequency coefficient measuring method according to the present invention is excellent in a detection function for a phase jump compared with the method in the past. Therefore, it is possible to prevent wrong startup due to the phase jump. In the apparatus in the past, a detection time is long because the apparatus carries out various measures to prevent wrong startup due to the phase jump. Therefore, by using the method of this application, it is possible to provide a high-speed and highly reliable islanding detecting apparatus with reduced wrong startup. Concerning detection of the phase jump, a detailed simulation result is presented in a case 4 explained below.

### Ninth Embodiment

In a ninth embodiment, an overvoltage protection apparatus and a low-voltage protection apparatus are explained. Many protection control apparatuses in Japan adopt 30° sampling (α=30°). Therefore, 30° sampling is explained below as an example. A frequency coefficient in the case of the 30° sampling is obtained as follows according to Formula (12):

f_{C}=cos 30°=0.866 (280)

The frequency coefficient f_{C} is substituted in Formula (22) and a calculation formula for overvoltage protection indicated by the following formula is proposed:

V=3.863717_{gd}>V_{high} (281)

In the formula, V represents a real voltage amplitude, V_{gd} represents a gauge differential voltage, and V_{high} represents a setting value.

Similarly, in the case of the 30° sampling, a calculation formula for low-voltage protection indicated by the following formula is proposed:

V=3.8637V_{gd}<V_{low} (282)

In the formula, V represents a real voltage amplitude, V_{gd} represents a gauge differential voltage, and V_{low} represents a setting value.

In the above two calculation formulas, only a differential voltage is used. Therefore, in the overvoltage protection apparatus and the low-voltage protection apparatus employing these calculation formulas, the influence of a direct-current offset is extremely small. Therefore, it is possible to reduce the influence of CT saturation and greatly contribute to a high-speed operation of overvoltage or low-voltage protection.

### Tenth Embodiment

In the ninth embodiment, the 30° sampling overvoltage protection apparatus is explained. In a tenth embodiment, a 30° sampling over-current protection apparatus is explained.

First, the frequency coefficient calculated by Formula (280) is substituted in Formula (28) and a calculation formula for over-current protection indicated by the following formula is proposed.

I=3.8637I_{gd}>I_{SET} (283)

In the formula, I represents a real current amplitude, I_{gd} represents a gauge differential current, and I_{SET} represents a setting value.

In the above calculation formulas, only a differential current is used. Therefore, in the over-current protection apparatus employing these calculation formulas, the influence of a direct-current offset is extremely small. Therefore, it is possible to reduce the influence of CT saturation and greatly contribute to a high-speed operation of over-current protection.

### Eleventh Embodiment

In an eleventh embodiment, a current differential protection apparatus is explained. Two methods, i.e., a current phase difference measuring method and a synchronized phasor measuring method are explained as an example.

(Current Phase Difference Measuring Method)

First, electric currents measured at ends (terminals 1 and 2) of a power transmission line or in electrical installations (transformers, generators, etc.) at ends located across a power transmission line can be represented as indicated by the following formula:

$$\{ \begin{matrix}{i}_{1} ( t ) = {I}_{1} \\ {i}_{2} ( t ) - {I}_{2} {e}^{j {φ}_{12}}\end{matrix} \qquad ( 284 )$$

In the formula, I₁ and I₂ respectively represent current amplitudes in the terminals 1 and 2 and φ₁₂ represents a phase difference of a current vector between the terminals 1 and 2. As the current vector, it is desirable to use a differential current on which the influence of CT saturation is small.

An instantaneous value comparison calculation formula for the current differential protection apparatus is as indicated by the following formula:

|I₁−I₂ cos φ₁₂|>ΔI_{SET} (285)

When the above formula is satisfied, it is possible to determine that an inter-section failure occurs. When a communication time is taken into account, the phase difference φ₁₂ of the current vector is corrected as indicated by the following formula:

φ₁₂ᵣₑₐₗ=φ₁₂−2πfT_{transfer} (286)

In the formula, f represents a measured frequency and T_{transfer} represents a communication time. A result of Formula (286) only has to be substituted in Formula (285) to perform calculation.

(Synchronized Phasor Measuring Method)

In this method, current amplitudes and current synchronized phasors at the ends (the terminals 1 and 2) of the power transmission line or the electrical installations (transformers, generators, etc.) at the ends located across the power transmission line are measured. Electric currents obtained using the current amplitudes and the current synchronized phasors can be represented by the following formula:

$$\{ \begin{matrix}{i}_{1} ( t ) = {I}_{1} {e}^{j {φ}_{I 1}} \\ {i}_{2} ( t ) - {I}_{2} {e}^{j {φ}_{I 2}}\end{matrix} \qquad ( 287 )$$

In the formula, I₂ and φ₁₁ respectively represent a current amplitude and a current synchronized phasor at the present point in the terminal 1. Similarly, I₂ and φ₁₂ respectively represent a current amplitude and a current synchronized phasor at the present point in the terminal 2. As a current vector to be used, it is desirable to use a differential current on which the influence of CT saturation is small.

An instantaneous value comparison calculation formula for the current differential protection apparatus is as indicated by the following formula:

|I₁ cos φ_{I1}−I₂ cos φ_{I2}|>ΔI_{SET} (288)

When the above formula is satisfied, it is possible to determine that an inter-section failure occurs.

An instantaneous value comparison calculation formula indicated by the following formula can be used for the current differential protection apparatus:

φ_{I1}−φ_{I2}|>Δφ_{ISET} (289)

When the above formula is satisfied, it is possible to determine that an inter-section failure occurs.

In these current differential protection apparatuses, it goes without saying that time synchronization between terminals 1 and 2 is necessary and instantaneous values or phase angles at the same time have to be compared. It goes without saying that, in synchronization, information transmission time between the terminals 1 and 2 has to be taken into account.

### Twelfth Embodiment

In a twelfth embodiment, several symmetrical component voltage measuring apparatuses, symmetrical component current measuring apparatuses, symmetrical component power measuring apparatuses, and symmetrical component impedance measuring apparatuses are explained.

(Symmetrical Component Voltage Measuring Apparatus 1)

Three-phase voltages of a power system are measured as follows:

$$\{ \begin{matrix}{v}_{A} ( t ) = {V}_{A} {e}^{j {φ}_{VA}} = {V}_{A} \\ {v}_{B} ( t ) = {V}_{B} {e}^{j {φ}_{VB}} = {V}_{B} cos {φ}_{VBA} + j {V}_{B} cos {φ}_{VBA} \\ {v}_{C} ( t ) = {V}_{C} {e}^{j {φ}_{VA}} = {V}_{C} cos {φ}_{VCA} + j {V}_{C} cos {φ}_{VCA}\end{matrix} \qquad ( 290 )$$

In the formula, V_{A}, V_{B}, and V_{C} respectively represent voltage amplitudes of an A phase, a B phase, and a C phase. φ_{VBA} and φ_{VCA} respectively represent a phase difference between a B-phase voltage and an A-phase voltage and a phase difference between a C-phase voltage and an A-phase voltage. The voltage amplitudes and the phase differences are measured by a proposed method of this application (an inter-bus phase angle difference calculating method with same both-end frequencies).

(Symmetrical Component Voltage Measuring Apparatus 2)

Three-phase voltages of a power system are measured as follows:

$$\{ \begin{matrix}{v}_{A} ( t ) = {V}_{A} {e}^{j {φ}_{VA}} = {V}_{A} cos {φ}_{VA} + j {V}_{A} cos {φ}_{VA} \\ {v}_{B} ( t ) = {V}_{B} {e}^{j {φ}_{VB}} = {V}_{B} cos {φ}_{VB} + j {V}_{B} cos {φ}_{VB} \\ {v}_{C} ( t ) = {V}_{C} {e}^{j {φ}_{VA}} = {V}_{C} cos {φ}_{VC} + j {V}_{C} cos {φ}_{VC}\end{matrix} \qquad ( 291 )$$

In the formula, V_{A}, V_{B}, V_{C}, φ_{VA}, φ_{VB}, and φ_{VC} respectively represent voltage amplitudes and synchronized phasors of the A phase, B phase, and the C phase. The voltage amplitudes and the phase differences are measured by the proposed method of this application.

Zero-phase, positive-phase, and negative-phase voltages are calculated as indicated by the following formula using a method of symmetrical coordinates:

$$[ \begin{matrix}{v}_{0} ( t ) \\ {v}_{1} ( t ) \\ {v}_{2} ( t )\end{matrix} ] = \frac{1}{3} [ \begin{matrix}1 & 1 & 1 \\ 1 & α & {α}^{2} \\ 1 & {α}^{2} & α\end{matrix} ] [ \begin{matrix}{v}_{A} ( t ) \\ {v}_{B} ( t ) \\ {v}_{C} ( t )\end{matrix} ] \qquad ( 292 )$$

In the formula, coefficients α and α₂ of a symmetrical transformation matrix are represented by the following formula:

α=e^{j2π/2}, α²=e^{-j2π/3}

Conventionally, in an apparatus that measures voltages of a zero phase, a positive phase, and a negative phase, a voltage of a symmetrical component is measured by the method of symmetrical coordinates. However, this is on the premise that a real frequency is a rated frequency. On the other hand, when the real frequency is not the rated frequency, an error of measurement occurs. On the other hand, in the present invention, a phase angle difference between the phases (between the B phase and the A phase and between the C phase and the A phase) is measured or a synchronized phasor is directly measured using a calculation (measurement) result of the real frequency. Therefore, even when the real frequency deviates from the rated frequency, for example, with reference to A phase, automatic frequency correction is performed and highly accurate measurement can be performed.

(Symmetrical Component Current Measuring Apparatus 1)

Three-phase currents of a power system are measured as follows:

$$\{ \begin{matrix}{i}_{A} ( t ) = {I}_{A} {e}^{j {φ}_{VA}} = {I}_{A} \\ {i}_{B} ( t ) = {I}_{B} {e}^{j {φ}_{VB}} = {I}_{B} cos {φ}_{IBA} + j {I}_{B} cos {φ}_{IBA} \\ {i}_{C} ( t ) = {I}_{C} {e}^{j {φ}_{VA}} = {I}_{C} cos {φ}_{ICA} + j {I}_{C} cos {φ}_{ICA}\end{matrix} \qquad ( 293 )$$

In the formula, I_{A}, I_{B}, and I_{C} respectively represent voltage amplitudes of the A phase, the B phase, and the C phase. φ_{IBA} and φ_{ICA} respectively represent a phase difference between a B-phase current and an A-phase current and a phase difference between a C-phase current and the A-phase current. The current amplitudes and the phase differences are measured by the proposed method of this application.

(Symmetrical Component Current Measuring Apparatus 2)

Three-phase currents of a power system are measured as follow:

$$\{ \begin{matrix}{i}_{A} ( t ) = {I}_{A} {e}^{j {φ}_{VA}} = {I}_{A} cos {φ}_{IA} + j {I}_{A} cos {φ}_{IA} \\ {i}_{B} ( t ) = {I}_{B} {e}^{j {φ}_{VB}} = {I}_{B} cos {φ}_{IB} + j {I}_{B} cos {φ}_{IB} \\ {i}_{C} ( t ) = {I}_{C} {e}^{j {φ}_{VA}} = {I}_{C} cos {φ}_{IC} + j {I}_{C} cos {φ}_{IC}\end{matrix} \qquad ( 294 )$$

In the formula, I_{A}, I_{B}, I_{C}, φ_{IA}, φ_{IB}, and φ_{IC} respectively represent current amplitudes and synchronized phasors of the A phase, the B phase, and the C phase. The current amplitudes and the synchronized phasors are measured by the proposed method of this application.

Zero-phase, positive-phase, and negative-phase currents are calculated as indicated by the following formula using the method of symmetrical coordinates:

$$[ \begin{matrix}{i}_{0} ( t ) \\ {i}_{1} ( t ) \\ {i}_{2} ( t )\end{matrix} ] = \frac{1}{3} [ \begin{matrix}1 & 1 & 1 \\ 1 & α & {α}^{2} \\ 1 & {α}^{2} & α\end{matrix} ] [ \begin{matrix}{i}_{A} ( t ) \\ {i}_{B} ( t ) \\ {i}_{C} ( t )\end{matrix} ] \qquad ( 295 )$$

The symmetrical component current measuring apparatus has a high accuracy characteristic same as that of the symmetrical component voltage measuring apparatus.

(Symmetrical Component Power Measuring Apparatus)

Symmetrical component power indicated by the following formula is calculated if a voltage and an electric current of a symmetrical component measured by the symmetrical component voltage measuring method and the symmetrical component current measuring method are used.

$$\{ \begin{matrix}{P}_{0} + {jQ}_{0} = {v}_{0} ( t ) {i}_{0} ( t ) \\ {P}_{1} + {jQ}_{1} = {v}_{1} ( t ) {i}_{1} ( t ) \\ {P}_{2} + {jQ}_{2} = {v}_{2} ( t ) {i}_{2} ( t )\end{matrix} \qquad ( 296 )$$

In the formula, P₂, P₂, and P₃ respectively represent active powers of a zero phase, a positive phase, and a negative phase and Q₁, Q₁, and Q₃ respectively represent reactive powers of the zero phase, the positive phase, and the negative phase.

(Symmetrical Component Impedance Measuring Apparatus)

Symmetrical component impedance indicated by the following formula can be calculated if a voltage and an electric current of a symmetrical component measured by the symmetrical component voltage measuring method and the symmetrical component current measuring method are used.

$$\{ \begin{matrix}{Z}_{0} = {R}_{0} + j 2 π {fL}_{0} = \frac{{v}_{0} ( t )}{{i}_{0} ( t )} \\ {Z}_{1} = {R}_{1} + j 2 π {fL}_{1} = \frac{{v}_{1} ( t )}{{i}_{1} ( t )} \\ {Z}_{2} = {R}_{2} + j2π {fL}_{2} = \frac{{v}_{2} ( t )}{{i}_{2} ( t )}\end{matrix} \qquad ( 297 )$$

In the formula, Z₀, Z₁, and Z₂ respectively represent impedances of a zero phase, a positive phase, and a negative phase, R₀, R₁, and R₂ respectively represent resistance components of the zero phase, the positive phase, and the negative phase, and L₀, L₁, and L₂ respectively represent IN-components of the zero phase, the positive phase, and the negative phase.

The above calculation formulas can be applied to all calculations of symmetrical components concerning the protection control apparatus of the power system.

### Thirteenth Embodiment

In a thirteenth embodiment, a high-speed instantaneous value estimating method suitable for a differential-type protection control apparatus is explained.

When differential protection is carried out, time series data of a partner terminal is received and a communication normal stamp is affixed to each point. When a differential protection calculation is carried out, time series data of several points (e.g., twelve points) stored in an AI table (AI: analog input data) is used. However, when an instantaneous failure or the like of a communication line occurs, data at the present point cannot be received. Therefore, all the data of the eleven points stored in the already-received AI table become ineffective. The differential protection calculation is locked until all data of the next AI table is normal. In such a logic of the differential protection calculation, quickness of a protection apparatus is spoiled. A method in this embodiment improves this point.

First, according to a frequency coefficient measuring method for measuring a frequency using a gauge voltage group, it is possible to calculate a frequency coefficient using the following formula:

$${f}_{C} = \frac{{v}_{t} + {v}_{t - 2 T}}{2 {v}_{t - T}} = cos α \qquad ( 298 )$$

In the formula, vₜ, v_{t-T}, and V_{t-2T} respectively represent voltage instantaneous values at the present point, at the immediately preceding step, and at the second immediately preceding step. Considering that a frequency coefficient does not suddenly change, a value calculated according to already-received data is used. Therefore, an instantaneous value estimated value at the present point can be estimated using the voltage instantaneous values at the immediately preceding step and at the second immediately preceding step as indicated by the following formula:

vₜ_{_{—}}ₑₛₜ=2v_{t-T}f_{C}−v_{t-2T} (299)

When an instantaneous failure of a communication line occurs, instantaneous value data at the present point is estimated making use of the above explanation and stored in the AI table. Quickness of the protection apparatus is guaranteed by this method.

### Fourteenth Embodiment

In a fourteenth embodiment, a harmonic current compensating apparatus is explained. In an example explained below, the harmonic current compensating apparatus is applied as an active filter of a power system.

First, an active filter output current in a single-phase circuit is calculated as indicated by the following formula:

i_{AF}=i_{L}−iᵣₑ=i_{L}−I cos φ_{I} (300)

In the formula, i_{AP} represents an active filter output current, i_{L} represents a real alternating current instantaneous value, iᵣₑ represents a fundamental wave instantaneous value, I represents a fundamental wave current amplitude, and φ_{I} represents a current synchronized phasor. When Formula (255) is substituted in the above formula, the above formula is represented as indicated by the following formula:

$${i}_{AF} = {i}_{L} - {i}_{re} = {i}_{L} - \frac{{SA}_{P} - {SA}_{Q} {f}_{C}}{1 - {f}_{C}^{2}} \qquad ( 301 )$$

In the formula, S_{AP} represents a gauge active synchronized phasor, S_{AQ} represents a gauge reactive synchronized phasor, and f_{C} represents a frequency coefficient. If the above formula is used, it is possible to directly calculate an active filter output current from time series input data.

Usefulness and an effect of the present invention are explained using numerical value examples of cases 1 to 6. First, parameters of the case 1 are as shown in Table 2 below.

TABLE 2
Parameters of case 1

| | | | | Alternating |
|---|---|---|---|---|
| | Number of | | Alternating | voltage |
| Sampling | sampling | Real | voltage | initial |
| frequency | points | frequency | amplitude | phase angle |
| 600 Hz | 4 | 0-600 Hz | 1 V | 0 deg |

First, when the parameters of the case 1 are used, an input waveform is represented by a cosine as indicated by the following formula:

v=cos(2πft) (302)

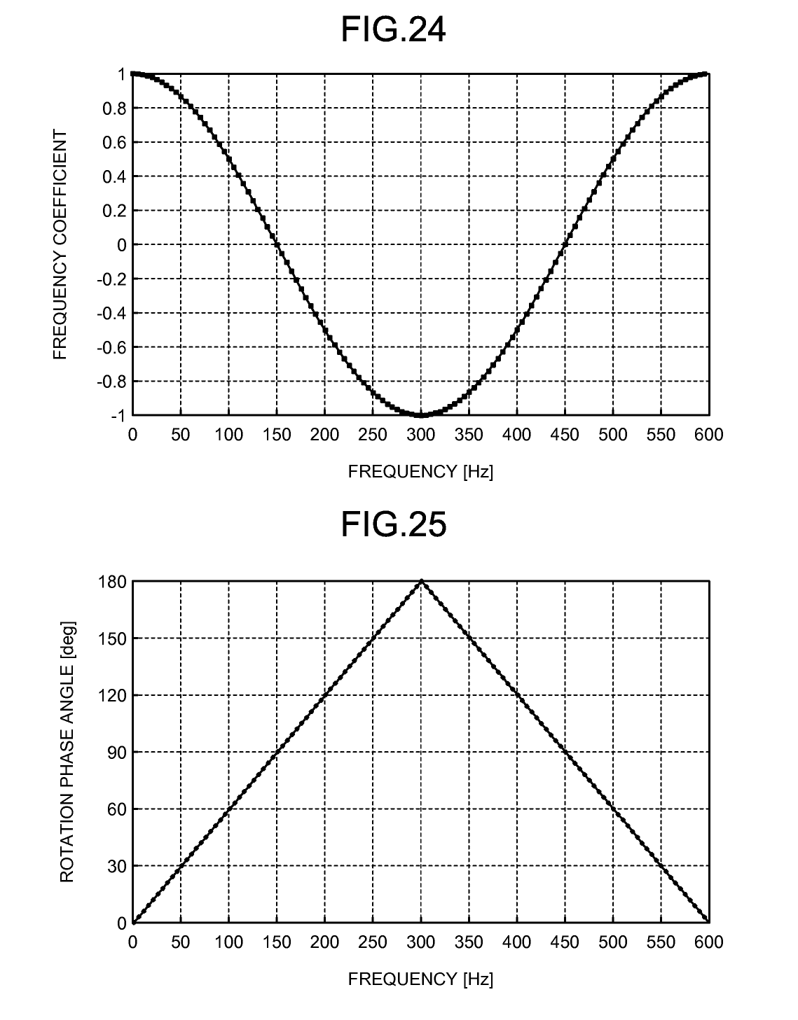

FIG. 24 is a graph of a frequency coefficient calculated using the parameters of the case 1. As it is seen from FIG. 24 and the following formula (Formula (8) is shown again), the frequency coefficient is a cosine.

$${f}_{C} = \frac{{v}_{21} + {v}_{23}}{2 {v}_{22}} = cos α \qquad ( 303 )$$

As shown in FIG. 24, as a frequency increases, the frequency coefficient decreases and fluctuates between 1 and −1. When the frequency coefficient is 1, the frequency is zero and is a so-called direct current. When the frequency coefficient is −1, the frequency is f_{S/2} and takes a half value of a sampling frequency.

Formula (13) representing a rotation phase angle is shown below again.

α=cos⁻¹f_{C} (304)

According to Formula (304), a rotation phase angle could take positive and negative values. However, actually, as shown in FIG. 25, the rotation phase angle is always positive and present between 0 to 180 degrees. When a real frequency is a half of the sampling frequency or lower, the magnitude of the rotation phase angle is in a direct proportional relation with the magnitude of the real frequency. When the real frequency is a quarter of the sampling frequency, the rotation phase angle is 90 degrees and the frequency coefficient is zero.

A sampling frequency optimum for a protection control apparatus of a power system is a quadruple of a rated frequency. “Optimum” means a reduction of a calculation load. Therefore, a sampling frequency of 200 Hz is recommended for a 50 Hz system. A sampling frequency of 240 Hz is recommended for a 60 Hz system.

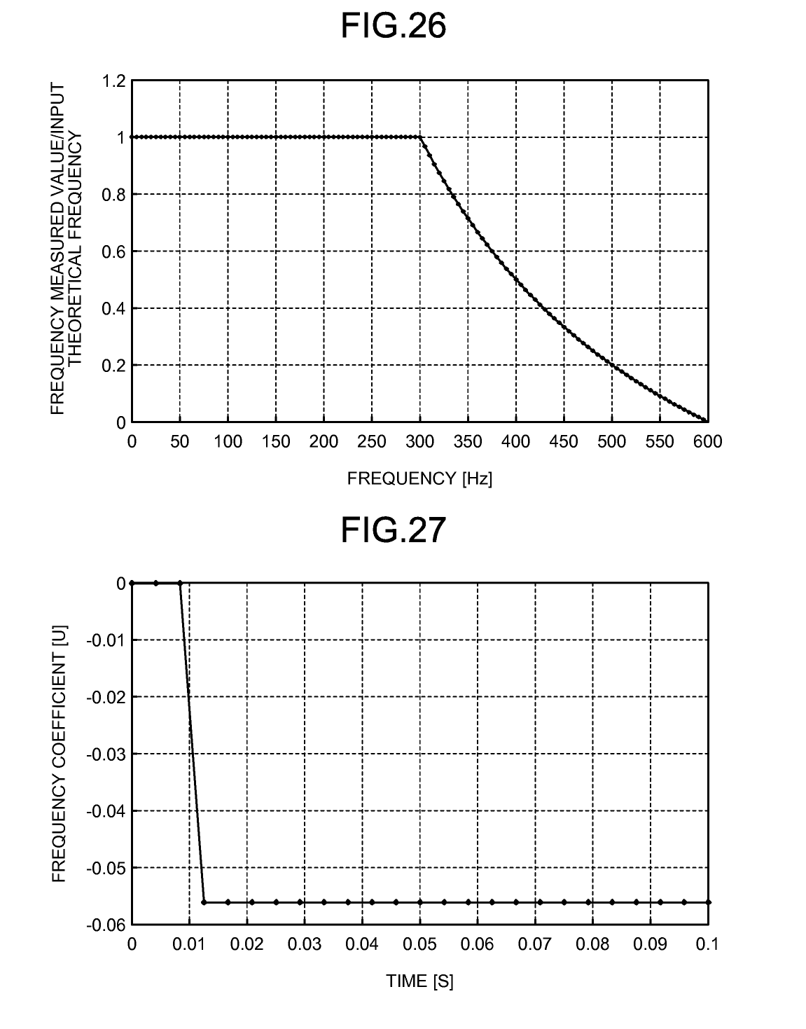

FIG. 26 is a gain graph of frequency measurement calculated using the parameters of the case 1. A formula for calculating a gain is indicated by the following formula:

$${K}_{Gain} = \frac{{f}_{1}}{{f}_{0}} \qquad ( 305 )$$

In the formula, f1 represents a frequency measured value and f0 represents an input logic frequency. If a measurement target frequency is equal to or lower than a half of a sampling frequency of 600 Hz (equal to or lower than 300 Hz), it is possible to perform frequency measurement without a logic error. It is seen that this result coincides with the sampling theorem.

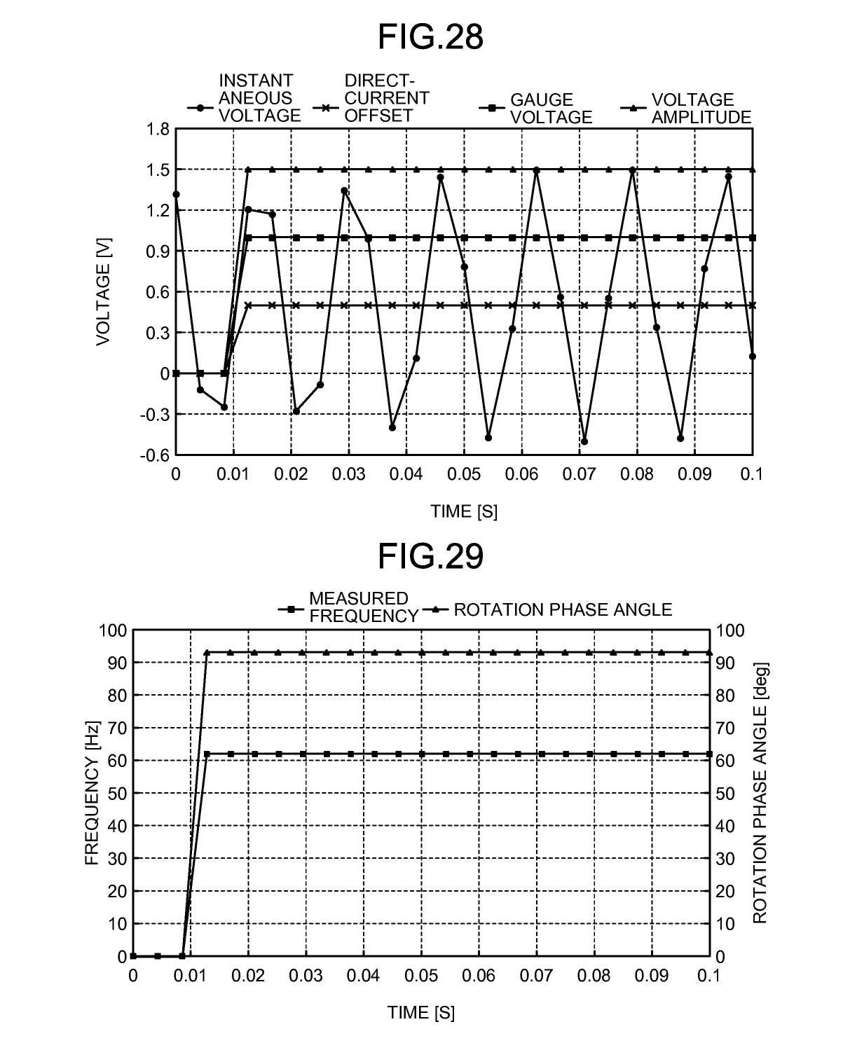

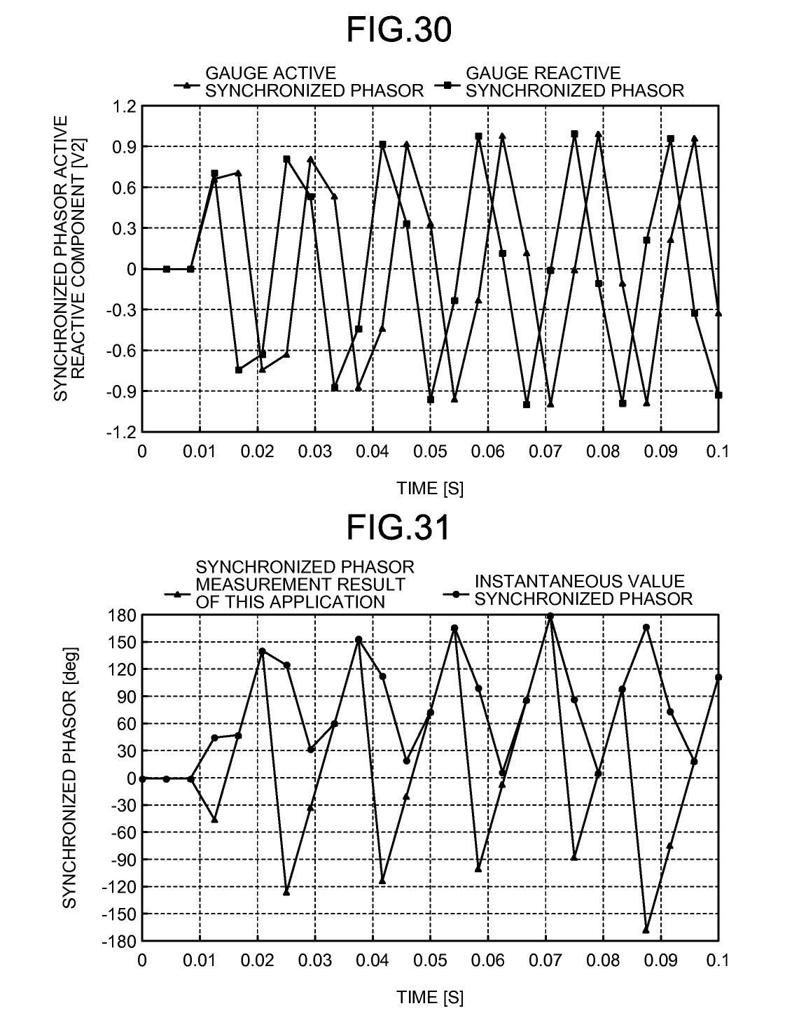

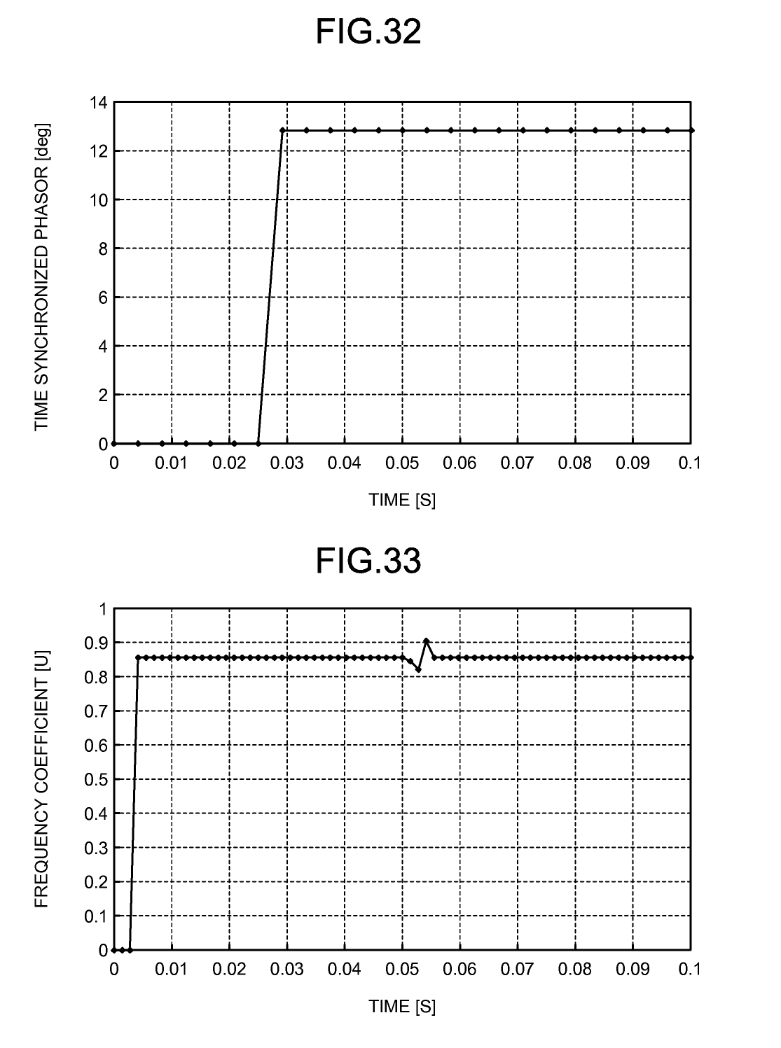

Measurement results (calculation results) obtained using parameters of the case 2 is explained with reference to graphs of FIGS. 27 to 32. FIGS. 27 to 32 are respectively measurement results calculated using the parameters of the case 2. A frequency coefficient is shown in FIG. 27, an instantaneous voltage, a direct-current offset, a gauge voltage, and a voltage amplitude are shown in FIG. 28, a rotation phase angle and a measured frequency are shown in FIG. 29, a gauge active synchronized phasor and a gauge reactive synchronized phasor are shown in FIG. 30, a synchronized phasor in this application and an instantaneous value synchronized phasor in the past are shown in FIG. 31, and a time synchronized phasor is shown in FIG. 32. The parameters of the case 2 are as shown in Table 3 below.

TABLE 3
Parameters of case 2

| | | | | Alternating | |
|---|---|---|---|---|---|
| | Number | | | voltage | |
| | of | | Alternating | initial | |
| Sampling | sampling | Real | voltage | phase | Current |
| frequency | points | frequency | amplitude | angel | offset |
| 240 Hz | 4 | 62.14 Hz | 1 V | 35.1 deg | 0.5 V |

According to Table 3, a real number instantaneous value function of an input waveform is represented as indicated by the following formula:

v=0.5+cos(390.437t+0.613) (306)

A frequency coefficient obtained when the input waveform indicated by Formula (306) is a voltage instantaneous value is obtained as follows:

$${f}_{C} = \frac{{v}_{21} + {v}_{23}}{2 {v}_{22}} = - 0.055996 \qquad ( 307 )$$

When the real frequency is higher than a quarter of the sampling frequency, a sign of the frequency component is minus. As shown in FIG. 27, it is seen that a measurement result and a theoretical value coincide with each other and the measurement is performed correctly.

A direct-current offset obtained when the input waveform indicated by Formula (306) is a voltage instantaneous value is obtained as follows:

$$d = \frac{{v}_{11} + {v}_{13} - 2 {v}_{12} {k}_{C}}{2 ( 1 - {k}_{C} )} = 0.5 ( V ) \qquad ( 308 )$$

As shown in FIG. 28, a calculated value of the direct-current offset coincides with an input value. The measurement is performed correctly.

Because the gauge voltage is a rotation invariable of an alternating voltage, a gauge voltage after subtraction of the direct-current offset from the voltage instantaneous value is calculated as follows:

V_{g}=\sqrt{(v₁₂−d)²−(v₁₁−d)(v₁₃−d)}=0.998431(V) (309)

From a result of the above formula, a voltage amplitude is obtained as follows:

$$V = \frac{{V}_{g}}{\sqrt{1 - {f}_{C}^{2}}} = 1.0 ( V ) \qquad ( 310 )$$

It is seen that the result of the above formula coincides with input data shown in FIG. 28 and Table 3 and the measurement is performed correctly. For easiness of understanding, a direct-current offset component is added to the voltage amplitude shown in FIG. 28.

From a result of Formula (307), a rotation phase angle is obtained as follows:

α=cos⁻¹ f_{C}=93.21 (deg) (311)

When the frequency coefficient is minus, the rotation phase angle is larger than 90 degrees. As shown in FIG. 29, it is seen that a measurement result and a theoretical value coincide with each other and the measurement is performed correctly.

From Formula (311), a real frequency is obtained as follows:

$$f = \frac{{f}_{S}}{2 π} α = 62.14 ( Hz ) \qquad ( 312 )$$

As shown in FIG. 29, it is seen that the measured frequency coincides with input data of Formula (312) and Table 2.

As shown in FIG. 30, it is seen that the gauge active synchronized phasor is equal to a gauge reactive synchronized phasor at the immediately preceding step.

FIG. 31 is a graph of a synchronized phasor of this application calculated using the parameters of the case 2 compared with an instantaneous value synchronized phasor in the past. In FIG. 31, the synchronized phasor of this application is indicated by a black triangle mark and the instantaneous value synchronized phasor disclosed in Patent Literature 3 is indicated by a black circle mark.

In FIG. 31, the synchronized phasor of this application is a time dependent amount and fluctuates in a range of −π to +π. When the synchronized phasor of this application is plus, the synchronized phasor of this application coincides with the instantaneous value synchronized phasor. When the synchronized phasor of this application is minus, the instantaneous value synchronized phasor is not minus. However, absolute values of the synchronized phasor of this application and the instantaneous value synchronized phasor are the same (sign inversion).

A calculation formula for the instantaneous value synchronized phasor described in Patent Literature 3 (hereinafter referred to as “conventional invention” in this section) is as follows:

$$φ = {cos}^{- 1} ( \frac{{v}_{re}}{V} ) \qquad ( 313 )$$

In this way, the instantaneous value synchronized phasor according to the conventional invention is always plus. Therefore, in the conventional invention, there is an inverting region of an own end absolute phase angle (the phase angle changes counterclockwise or clockwise between 0 and π). In the inverting region, it cannot be accurately set whether the absolute phase angle is rotating counter clockwise or rotating clockwise. In the conventional invention, when a time synchronized phasor or a space synchronized phasor, which is a difference between both absolute phase angles, is calculated, an accurate value is not obtained in the inverting region of the phase angle. Therefore, in the conventional invention, a value of the preceding step is latched.

On the other hand, in the present invention, because a method of using a symmetry group is adopted, an absolute phase angle in a group synchronized phasor measuring method always changes in one direction counterclockwise between −φπ and π and it is unnecessary to latch the phase angle. Therefore, it is possible to decide an accurate time synchronized phasor or space synchronized phasor. The present invention is extremely effective in high-speed protection control. Ideas of noise processing are also different between the present invention and the conventional invention. In the conventional invention, whereas the method of least squares is used, in the present invention, noise is reduced by increasing the number of symmetry groups.

A time synchronized phasor, which is a difference value between a synchronized phasor at the present point and a synchronized phasor at a point one cycle before the present point is obtained as follows when the rated frequency is set to 60 Hz:

$${φ}_{TP} = \frac{62.14 - 60}{60} \times 360 = 12.84 ( deg ) \qquad ( 314 )$$

As shown in FIG. 32, a measurement result of the time synchronized phasor coincides with the theoretical value.

Parameters of the cases 3 to 5 are explained. The cases 3 to 5 are Benchmark test cases described in pages 47 to 51 of Non-Patent Literature 1. For simplification, a direct-current offset in an input waveform in the cases 3 to 5 is set to zero.

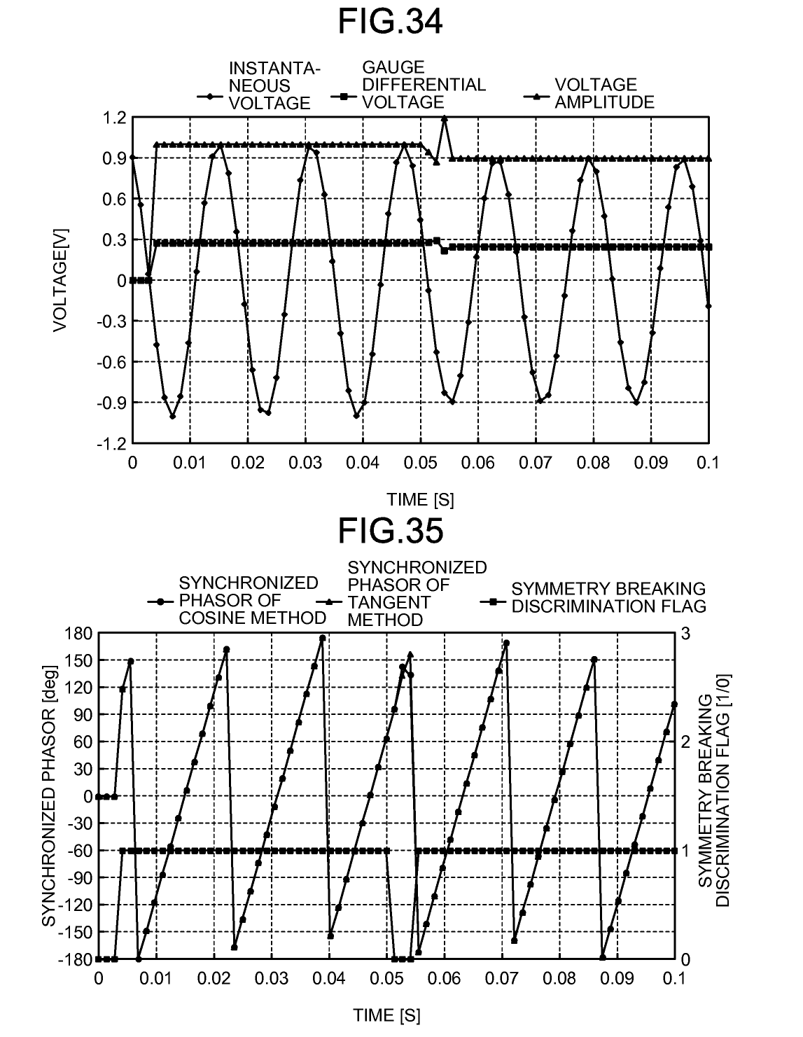

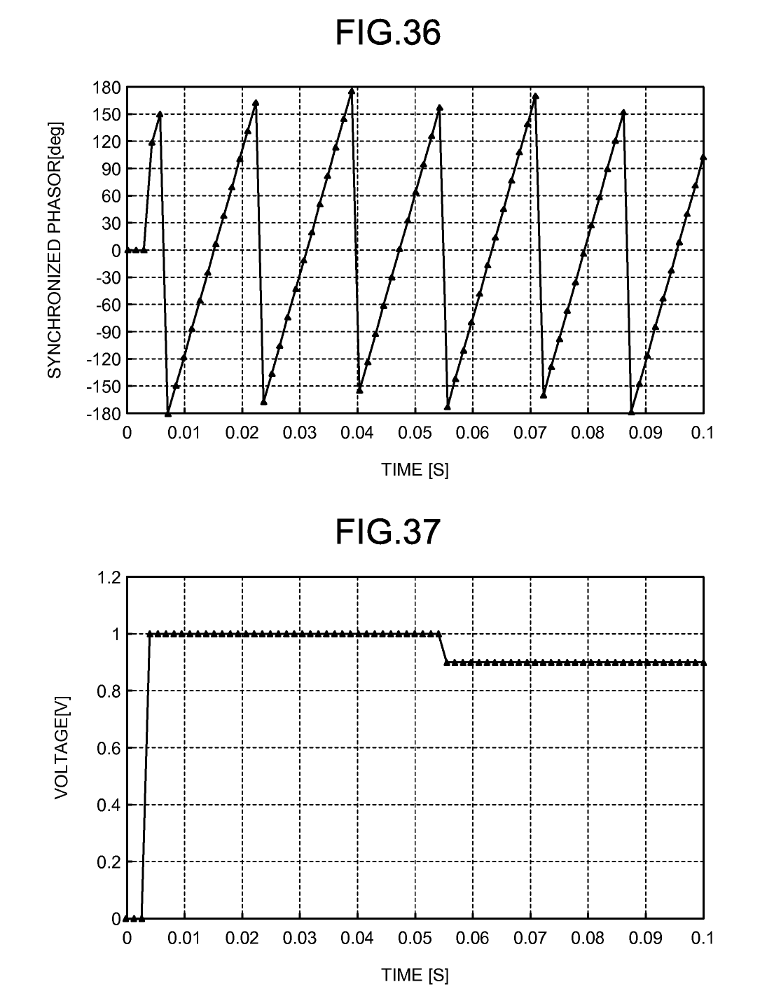

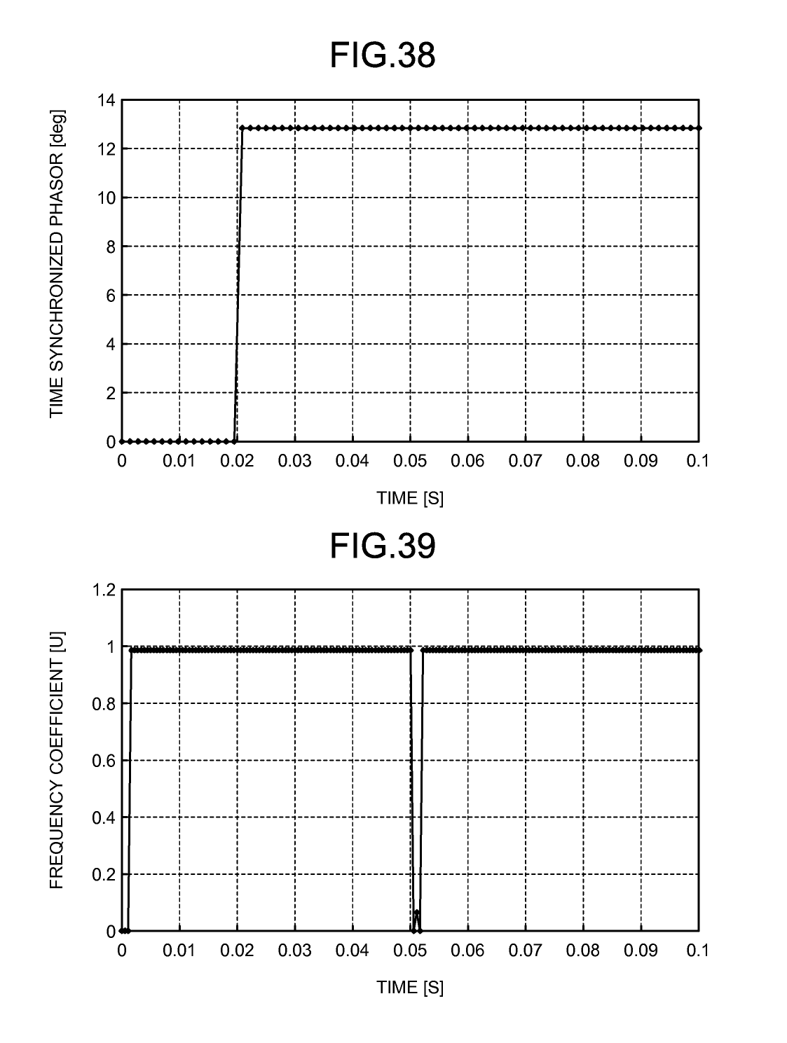

Measurement results obtained using the parameters of the case 3 are explained with reference to graphs of FIGS. 33 to 38. FIGS. 33 to 38 are respectively measurement results calculated using the parameters of the case 3. A frequency coefficient is shown in FIG. 33, an instantaneous voltage, a gauge differential voltage, and a voltage amplitude are shown in FIG. 34, a synchronized phasor of a cosine method, a synchronized phasor of a tangent method, and a symmetry breaking discrimination flag are shown in FIG. 35, a synchronized phasor is shown in FIG. 36, a voltage amplitude is shown in FIG. 37, and a time synchronized phasor is shown in FIG. 38. The parameters of the case 3 are as shown in Table 4 below. The parameters are specified as “G.2 Magnitude step test (10%)” included in the Benchmark test.

TABLE 4
Parameters of case 3

| | | | | Alter- | | |
|---|---|---|---|---|---|---|
| | Number | | | nating | | Ampli- |
| Sam- | of | | Alter- | voltage | | tude |
| pling | sam- | Real | nating | initial | Simu- | 10% |
| fre- | pling | fre- | voltage | phase | lation | decrease |
| quency | points | quency | amplitude | angle | time | time |
| 720 Hz | 4 | 62.14 Hz | 1 V | 25.1 deg | 0-0.1 | 0.05 |
| | | | | | second | second |

First, in the case 3, a real number instantaneous value function of an input waveform is represented as indicated by the following formula:

$$v = \{ \begin{matrix}1 \times cos ( 390.44 t + 0.4381 ) , t <= 0.5 \\ 0.9 \times cos ( 390.44 t + {φ}_{C} ) , t > 0.5\end{matrix} \qquad ( 315 )$$

In the formula, φ_{c} represents a phase angle of an alternating voltage before a state sudden change and is calculated on-line.

A frequency coefficient obtained when the input waveform indicated by Formula (315) is a voltage instantaneous value is obtained as follows:

$${f}_{C} = \frac{{v}_{21} + {v}_{23}}{2 {v}_{22}} = 0.85654 \qquad ( 316 )$$

As shown in FIG. 33, it is seen that stable values are obtained excluding several points after the state sudden change.

A gauge differential voltage in a steady state before an amplitude change is obtained as follows:

V_{gd}=\sqrt{v₂₂²−v₂₁v₂₃}=0.27644(V) (317)

Therefore, a voltage amplitude in the steady state before the amplitude change is obtained as follows:

$$V = \frac{\sqrt{2} {V}_{gd}}{2 ( 1 - {f}_{C} ) \sqrt{1 + {f}_{C}}} = 1.0 ( V ) \qquad ( 318 )$$

It is seen that a result of the above formula coincides with a measurement result shown in FIG. 34 and input data of Table 4 and the measurement is performed correctly.

A gauge differential voltage in a steady state after an amplitude change is obtained as follows:

V_{gd}=\sqrt{v₂₂²−v₂₁v₂₃}=0.24880(V) (319)

Therefore, a voltage amplitude in the steady state after the amplitude change is obtained as follows:

$$V = \frac{\sqrt{2} {V}_{gd}}{2 ( 1 - {f}_{C} ) \sqrt{1 + {f}_{C}}} = 0.9 ( V ) \qquad ( 320 )$$

It is seen that a result of the above formula coincides with the measurement result shown in FIG. 34 and the input data of Table 4.

When FIG. 35 is referred to, in the steady state, the alternating voltage has symmetry and the synchronized phasor of the cosine method and the synchronized phasor of the tangent method completely coincide with each other. It is indicated that, when the alternating voltage suddenly changes, results of the synchronized phasor of the cosine method and the synchronized phasor of the tangent method do not coincide with each other and the symmetry is broken.

By using the synchronized phasor measurement result of the cosine method and the tangent method in this way, it is possible to determine whether an input waveform has symmetry. When the symmetry is broken, it is possible to maintain a normal change by performing the synchronized phasor estimation calculation using Formula (206).

When the alternating voltage has symmetry, a voltage amplitude is calculated using the gauge differential voltage and the frequency coefficient. On the other hand, when the symmetry is broken, an already-calculated voltage amplitude is latched. Consequently, as shown in FIG. 37, it is possible to prevent an oscillatory transient state from occurring.

As a comparison target, Figure G.4-Magnitude step test example (simulation, 1 cycle FFT based algorithm) in P 51 of Non-Patent Literature 1 is referred to. In this simulation, because the Fourier transform is carried out, a voltage amplitude before occurrence of a sudden change of the voltage amplitude is changed. Further, in Non-Patent Literature 1, a real frequency before and after the occurrence of the sudden change of the voltage amplitude is a system rated frequency. On the other hand, in the present invention, although the real frequency is 62.14 Hz, a stable measurement result is obtained.

A synchronized phasor at the present point and a time synchronized phasor, which is a difference at a point one cycle before the present point of the rated frequency of 60 Hz, are obtained as follows:

$${φ}_{TP} = \frac{62.14 - 60}{60} \times 360 = 12.84 ( deg ) \qquad ( 321 )$$

As shown in FIG. 38, it is seen that a result (a theoretical value) of the above formula and a measurement result shown in FIG. 38 coincide with each other. The absence of the transient state means that a synchronized phasor estimation calculation is correct.

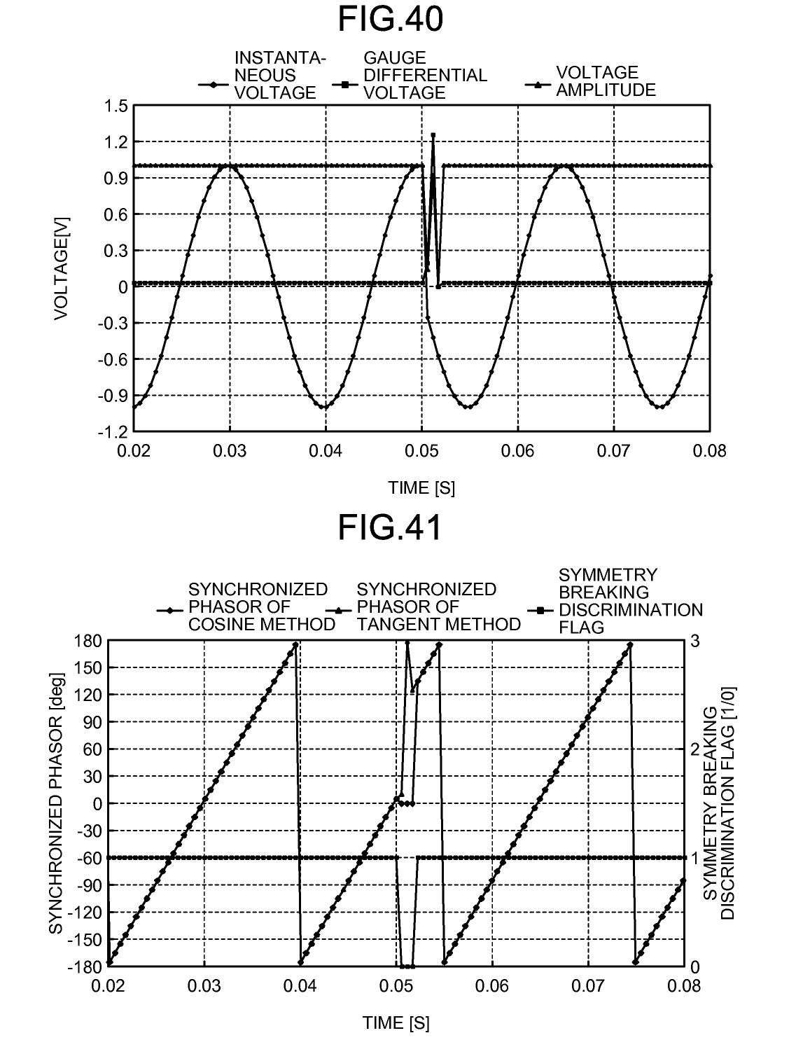

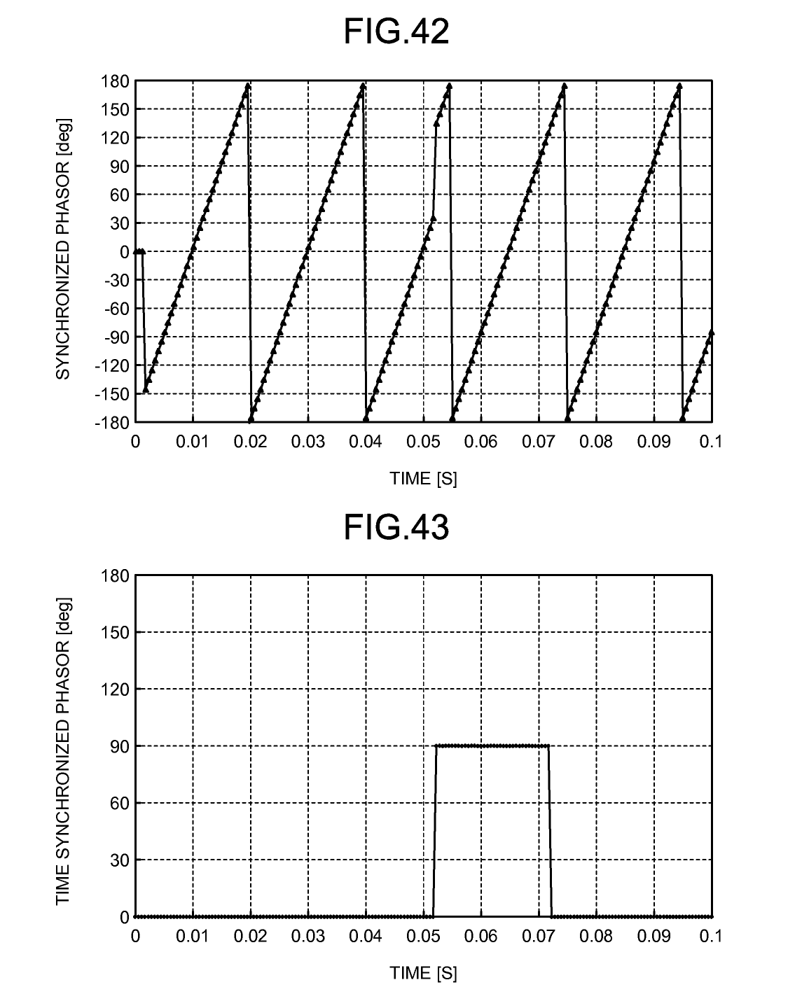

Measurement results obtained using the parameters of the case 4 are explained with reference to graphs of FIGS. 39 to 43. FIGS. 39 to 43 are respectively measurement results calculated using the parameters of the case 4. A frequency coefficient is shown in FIG. 39, an instantaneous voltage, a gauge differential voltage, and a voltage amplitude are shown in FIG. 40, a synchronized phasor of a cosine method, a synchronized phasor of a tangent method, and a symmetry breaking discrimination flag are shown in FIG. 41, a synchronized phasor is shown in FIG. 42, and a time synchronized phasor is shown in FIG. 43. The parameters of the case 4 are as shown in Table 5 below. The parameters are specified as “G.3 Phase step test (90°)” included in the Benchmark test.

TABLE 5
Parameters of case 4

| | | | | Alter- | | Phase |
|---|---|---|---|---|---|---|
| | Number | | | nating | | 90 |
| Sam- | of | | Alter- | voltage | | degree |
| pling | sam- | Real | nating | initial | Simu- | sudden |
| fre- | pling | fre- | voltage | phase | lation | change |
| quency | points | quency | amplitude | angle | time | time |
| 1800 Hz | 4 | 50 Hz | 1 V | −180 deg | 0-0.1 | 0.05 |
| | | | | | second | second |

First, in the case 4, a real number instantaneous value function of an input waveform is represented as indicated by the following formula:

$$v = \{ \begin{matrix}cos ( 314.16 t - π ) , & t <= 0.5 \\ cos ( 314.16 t + {φ}_{C} + π / 2 ) , & t > 0.5\end{matrix} \qquad ( 322 )$$

In the formula, φ_{c} is a phase angle of an alternating voltage before a state sudden change and is calculated on-line.

A frequency coefficient obtained when the input waveform indicated by Formula (322) is set as a voltage instantaneous value is obtained as follows:

$${f}_{C} = \frac{{v}_{21} + {v}_{23}}{2 {v}_{22}} = 0.98481 \qquad ( 323 )$$

As shown in FIG. 39, it is seen that stable values are obtained except several points after the state sudden change.

A gauge differential voltage in a steady state before an amplitude change is obtained as follows:

V_{gd}=\sqrt{v₂₂²−v₂₁v₂₃}=0.030269(V) (324)

Therefore, a voltage amplitude in the steady state before the amplitude change is obtained as follows:

$$V = \frac{\sqrt{2} {V}_{gd}}{2 ( 1 - {f}_{C} ) \sqrt{1 + {f}_{C}}} = 1.0 ( V ) \qquad ( 325 )$$

It is seen that a result of the above formula coincides with input data of Table 5.

When FIG. 41 is referred to, in the steady state, the alternating voltage has symmetry and the synchronized phasor of the cosine method and the synchronized phasor of the tangent method completely coincide with each other. It is indicated that, when the alternating voltage suddenly changes, results of the synchronized phasor of the cosine method and the synchronized phasor of the tangent method do not coincide with each other and the symmetry is broken.

As it is seen from FIG. 42, when the alternating voltage has symmetry, the synchronized phasor measurement result of the cosine method or the tangent method only has to be used. When the symmetry is broken, a synchronized phasor estimation calculation is performed according to Formula (206), whereby a normal change is maintained. Although a sudden change of 90 degrees is present between two steady states, there is no oscillatory transient state.

A synchronized phasor at the present point and a time synchronized phasor, which is a difference at a point one cycle before the present point of the rated frequency of 60 Hz, are obtained as follows:

$${φ}_{TP} = \frac{50 - 50}{50} \times 360 = 0 ( deg ) \qquad ( 326 )$$

However, after a phase 90 degree sudden change, the time synchronized phasor changes as follows during one cycle:

φ_{TP}=90 (deg) (327)

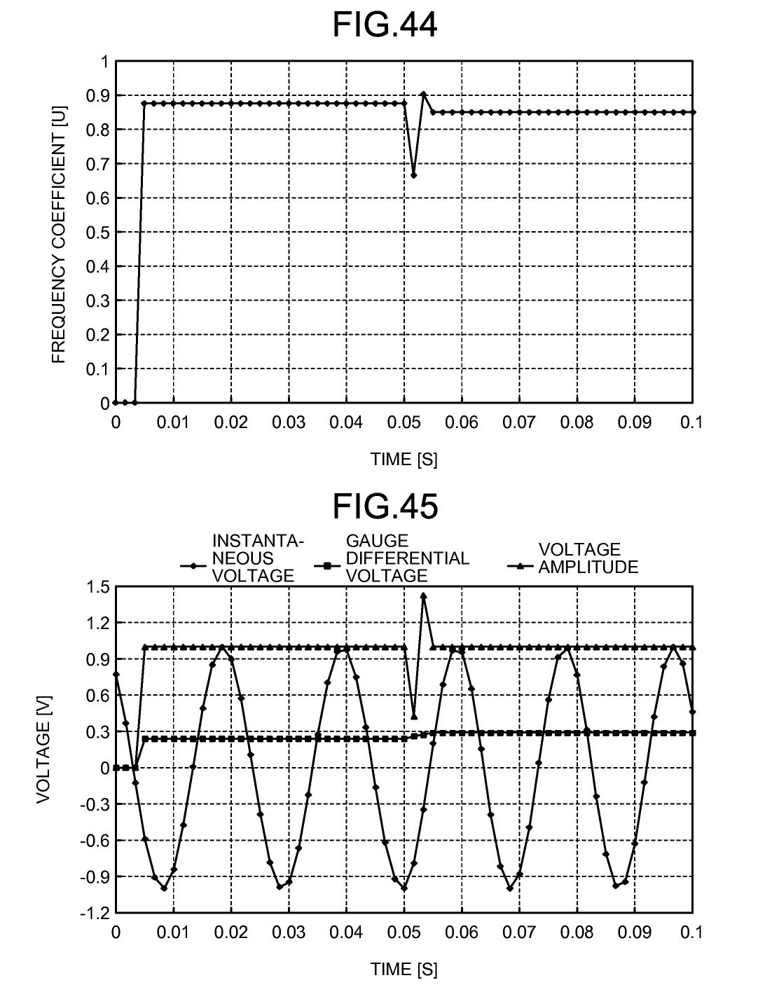

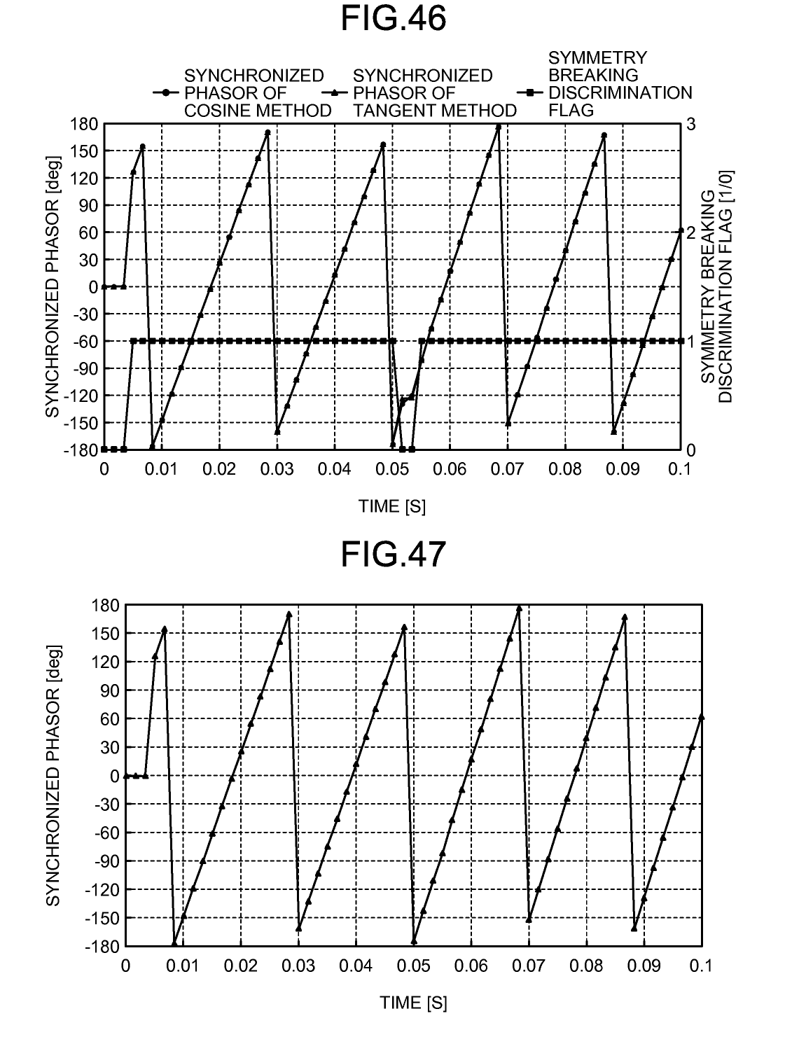

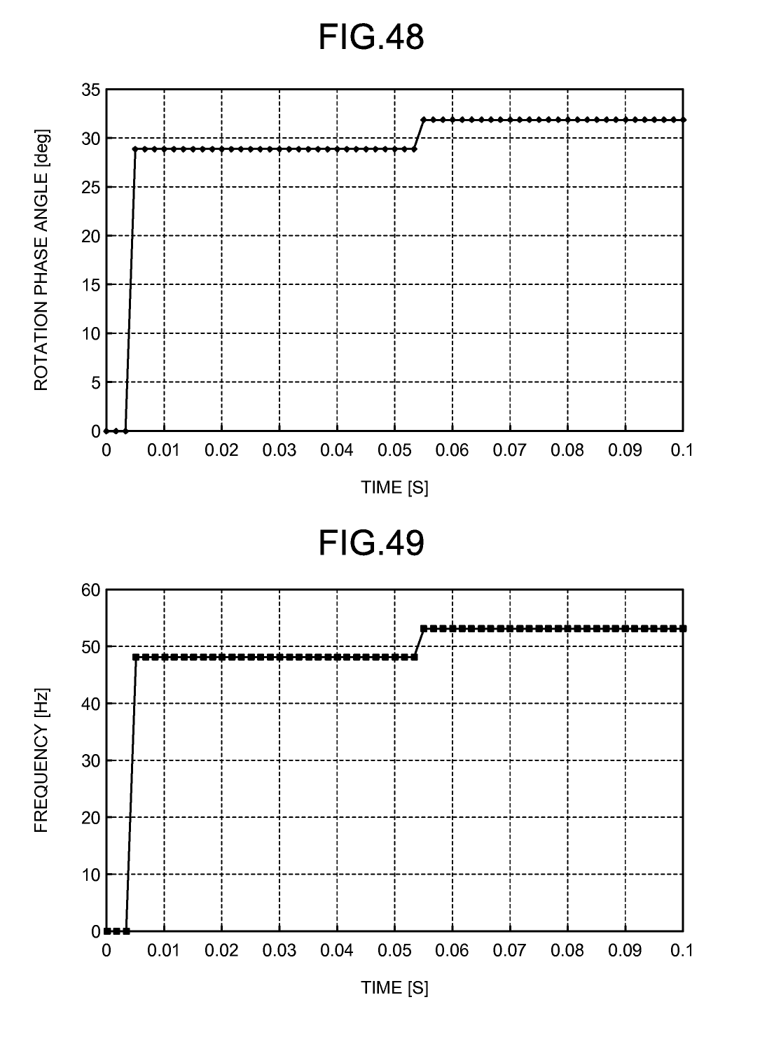

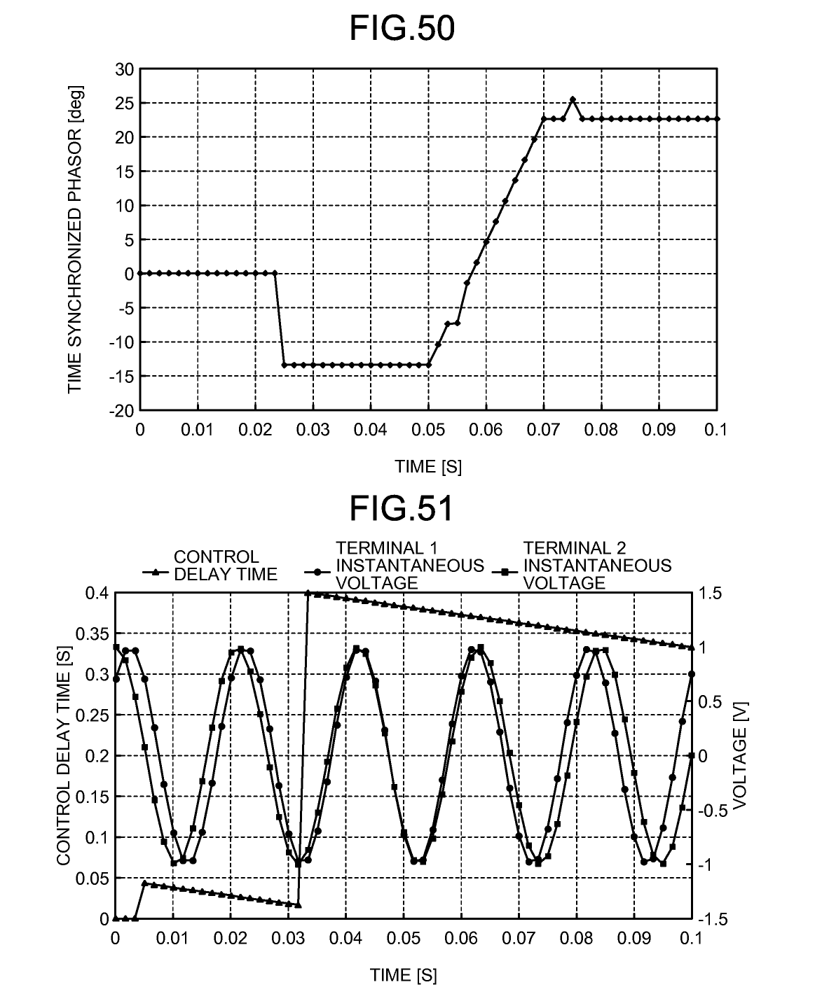

Measurement results obtained using the parameters of the case 5 are explained with reference to graphs of FIGS. 44 to 50. FIGS. 44 to 50 are respectively measurement results calculated using the parameters of the case 5. A frequency coefficient is shown in FIG. 44, an instantaneous voltage, a gauge differential voltage, and a voltage amplitude are shown in FIG. 45, a synchronized phasor of a cosine method, a synchronized phasor of a tangent method, and a symmetry breaking discrimination flag are shown in FIG. 46, a synchronized phasor is shown in FIG. 47, a rotation phase angle is shown in FIG. 48, a real frequency is shown in FIG. 49, and a time synchronized phasor is shown in FIG. 50. The parameters of the case 5 are as shown in Table 6 below. The parameters are specified as “G.4 Frequency step test (+5 Hz)” included in the Benchmark test.

TABLE 6
Parameters of case 5

| | | | | Alter- | | Fre- |
|---|---|---|---|---|---|---|
| | Number | | | nating | | quency |
| Sam- | of | | Alter- | voltage | | 5 Hz |
| pling | sam- | Real | nating | initial | Simu- | sudden |
| fre- | pling | fre- | voltage | phase | lation | increase |
| quency | points | quency | amplitude | angle | time | time |
| 600 Hz | 4 | 48.14 Hz | 1 V | 25.0 deg | 0-0.1 | 0.05 |
| | | | | | second | second |

First, in the case 5, a real number instantaneous value function of an input waveform is represented as indicated by the following formula:

$$v = \{ \begin{matrix}cos ( 2 \times π \times 48.14 \times t + 0.4363 ) , & t <= 0.5 \\ cos [ 2 \times π \times ( 48.14 + 5 ) \times t + {φ}_{C} ] , & t > 0.5\end{matrix} \qquad ( 328 )$$

In the formula, φ_{c} represents a phase angle of an alternating voltage before a state sudden change and is calculated on-line.

In a frequency coefficient obtained when the input waveform indicated by Formula (328), a frequency coefficient in a steady state before a frequency change is obtained as follows:

$${f}_{C} = \frac{{v}_{21} + {v}_{23}}{2 {v}_{22}} = 0.87560 \qquad ( 329 )$$

On the other hand, a frequency coefficient in a steady state after the frequency change is obtained as follows:

$${f}_{C} = \frac{{v}_{21} + {v}_{23}}{2 {v}_{22}} = 0.84912 \qquad ( 330 )$$

As shown in FIG. 44, it is seen that stable values are obtained excluding two points after the state sudden change.

A gauge differential voltage in the steady state before the frequency change is obtained as follows:

V_{gd}=\sqrt{v₂₂²−v₂₁v₂₃}=0.24094 (V) (331)

On the other hand, a gauge differential voltage in the steady state after the frequency change is obtained as follows:

V_{gd}=\sqrt{v₂₂²−v₂₁v₂₃}=0.29016(V) (332)

Therefore, a voltage amplitude is obtained as follows:

$$V = \frac{\sqrt{2} {V}_{gd}}{2 ( 1 - {f}_{C} ) \sqrt{1 + {f}_{C}}} = 1.0 ( V ) \qquad ( 333 )$$

It is seen that a result of the above formula coincides with input data of Table 6.

When FIG. 46 is referred to, in the steady state, the alternating voltage has symmetry and the synchronized phasor of the cosine method and the synchronized phasor of the tangent method completely coincide with each other. It is indicated that, when the alternating voltage suddenly changes, results of the synchronized phasor of the cosine method and the synchronized phasor of the tangent method do not coincide with each other and the symmetry is broken.

As it is seen from FIG. 47, when the alternating voltage has symmetry, a synchronized phasor measurement result of the cosine method or the tangent method only has to be used. When the symmetry is broken, a normal change is maintained by performing a synchronized phasor estimation calculation according to Formula (206).

When the alternating voltage has symmetry, a correct rotation phase angle is obtained by a frequency coefficient method. On the other hand, when the symmetry is broken, an already-calculated rotation phase angle is latched. Consequently, as shown in FIG. 48, it is possible to prevent an oscillatory transient state from occurring.

As shown in FIG. 49, it is seen that measurement results before and after a frequency sudden change coincide with input data of Table 6. When the alternating voltage has symmetry, a frequency is correctly calculated by a frequency coefficient method. On the other hand, when the symmetry is broken, an already-calculated frequency is latched. Consequently, as shown in FIG. 49, it is possible to prevent an oscillatory transient state from occurring.

In a steady state before a change, a time synchronized phasor, which is a difference value between a synchronized phasor at the present point and a synchronized phasor at a point one cycle before the present point is obtained as follows when the rated frequency is set to 60 Hz:

$${φ}_{TP} = \frac{48.14 - 50}{50} \times 360 = - 13.392 ( deg ) \qquad ( 334 )$$

In a stead state after the change, a time synchronized phasor, which is a difference value between a synchronized phasor at the present point and a synchronized phasor at a point one cycle before the present point is obtained as follows when the rated frequency is set to 60 Hz:

$${φ}_{TP} = \frac{53.14 - 50}{50} \times 360 = 22.608 ( deg ) \qquad ( 335 )$$

As shown in FIG. 50, measurement results of the time synchronized phasor before and after the change coincide with theoretical values.

A simulation result obtained using the parameters of the case 6 is explained with reference to a graph of FIG. 51. FIG. 51 is an automatic synchronizer operation graph during execution of a simulation performed using the parameters of a case 6. The parameters of the case 6 are as shown in Table 7 below. Basic parameters necessary for an operation analysis of an automatic synchronizer is shown.

TABLE 7
Parameters of case 6

| | Real | | Voltage |
|---|---|---|---|
| | frequency | Voltage | initial angle |
| | (Hz) | amplitude (V) | (deg) |
| Terminal 1 | 50.1 | 1 | −45.1 |
| Terminal 2 | 47.5 | 1 | 0 |

Sampling frequency: 600 Hz
Number of sampling points: 4
Logic calculation time + control signal transmission communication time: 15 ms

According to the parameters of the case 6 shown in Table 7, voltage real number instantaneous value functions at both ends are represented as indicated by the following formula:

$$\{ \begin{matrix}{v}_{1} = cos ( 314.79 t - 0.7871 ) \\ {v}_{2} = cos ( 298.45 t )\end{matrix} \qquad ( 336 )$$

According to Table 7, a frequency difference between both terminals can be calculated as follow:

Δf=50.1−47.5=2.6(Hz)

The synchronizing estimated time Tₑₛₜ can be calculated on-line using Formula (276).

Table 8 below is a table of a part of results of the simulation performed using the parameters of the case 6. FIG. 51 is a graph of the results. In this simulation, “T_{CAL}+T_{COM}” (logic calculation time+control signal transmission communication time) in Formula (278) is set to 15 ms.

TABLE 8
Part of results of simulation of automatic
synchronizer

| | | Terminal 1 | Terminol 1 | Space | Synchronizing |
|---|---|---|---|---|---|
| | Simulation | synchronized | synchronized | synchronized | control |
| Simulation | time | phasor | phasor | phasor | delay |
| step | (second) | (DEG) | (DEG) | (DEG) | time [S] |
| 17 | 0.028333 | 105.92 | 124.5 | −18.58 | 0.01985 |
| 18 | 0.03 | 135.98 | 153 | −17.02 | 0.018184 |
| 19 | 0.031667 | 166.04 | −178.5 | −15.46 | 0.016517 |
| 20 | 0.033333 | −163.9 | −150 | −13.9 | 0.399466 |
| 21 | 0.035 | −133.84 | −121.5 | −12.34 | 0.397799 |
| 22 | 0.036667 | −103.78 | −93 | −10.78 | 0.396132 |
| 23 | 0.038333 | −73.72 | −64.5 | −9.22 | 0.394466 |

In Table 8, the synchronizing control delay time T_{ASY} is about 16.5 ms in a simulation step 19 and is longer than 15 ms of “T_{CAL}+T_{COM}”. Therefore, the synchronizing estimated time Tₑₛₜ calculated from Formula (278) is a positive value and synchronizing is enabled. On the other hand, in a simulation step 20, a value of the synchronizing control delay time T_{ASY} is about 14.9 ms and the synchronizing estimated time Tₑₛₜ is a negative value. In this case, 2π is added to a space synchronized phasor to calculate the synchronizing estimated time Tₑₛₜ. In FIG. 51, a control delay time indicated by a black triangle mark greatly jumps at a point a little after 0.03 S (30 ms). This place corresponds to a place between simulation steps 19 and 20 in Table 8.

The automatic synchronizer in the past can perform synchronization only when a frequency difference between both ends is extremely small (e.g., within 0.5 Hz). However, in the present invention, synchronization is possible even when there is a large frequency difference such as 2.6 Hz. In this way, the automatic synchronizer according to the present invention can perform high-speed synchronization compared with the automatic synchronizer in the past.

### INDUSTRIAL APPLICABILITY

As explained above, the present invention is useful as an alternating-current electrical quantity measuring apparatus that enables highly accurate measurement of an alternating-current electrical quantity even when a measurement target is operating at a frequency deviating from a system rated frequency.

### REFERENCE SIGNS LIST

101 Power measuring apparatus
102, 202, 302 Alternating-voltage-and-current instantaneous-value-data input units
103, 203, 303, 403 Frequency-coefficient calculating units
104, 206, 305 Gauge-active-power calculating units
105, 207, 306 Gauge-reactive-power calculating units
106 Active-power-and-reactive-power calculating unit
107 Apparent-power calculating unit
108 Power-factor calculating unit
109, 213, 312, 413 Symmetry-breaking discriminating units
110, 216, 314, 419, 506, 711 Interfaces
111, 217, 315, 420, 507, 712 Storing units
201 Distance protection relay
204, 407, 703 Frequency calculating units
205, 304 Gauge-current calculating units
208, 212 Resistance-and-inductance calculating units
209, 308 Gauge-differential-current calculating units
210, 309 Gauge-differential-active-power calculating units
211, 310 Gauge-differential-reactive-power calculating units
214 Distance calculating unit
215 Breaker trip unit
301 Out-of-step protection relay
307, 311 Out-of-step-center-voltage calculating units
313 Breaker trip unit
401 Time-synchronized-phasor measuring apparatus
402 Alternating-voltage-instantaneous-value-data input unit
404 Gauge-differential-voltage calculating unit
405 Voltage-amplitude calculating unit
406 Rotation-phase-angle calculating unit
408 Direct-current-offset calculating unit
409 Gauge-active-synchronized-phasor calculating unit
410 Gauge-reactive-synchronized-phasor calculating unit
414 Synchronized-phasor estimating unit
415 Rotation-phase-angle latch unit
416 Frequency latch unit
417 Voltage-amplitude latch unit
418 Time-synchronized-phasor calculating unit
501 Synchronized-phasor measuring apparatus
502 Space-synchronized-phasor measuring apparatus
503 Synchronized-phasor/time-stamp receiving unit
504 Space-synchronize-phasor calculating unit
505 Control-signal transmitting unit
508, 603 Communication lines
601, 602 Synchronized-phasor measuring apparatuses
701 Automatic synchronizer
702 Voltage measuring unit
704 Voltage-amplitude calculating unit
705 Voltage-synchronized-phasor calculating unit
706 Frequency comparing unit
707 Voltage-amplitude comparing unit
708 Space-synchronized-phasor calculating unit
709 Synchronizing-operation-delay-time calculating unit
710 Synchronizing-operation carrying out unit

1. An alternating-current electrical quantity measuring apparatus comprising:
a frequency-coefficient calculating unit configured to calculate, as a frequency coefficient, a value obtained by normalizing, with a differential voltage instantaneous value at intermediate time, a mean value of a sums of differential voltage instantaneous values at times other than the intermediate time among differential voltage instantaneous value data at three points each representing an inter-point distance between voltage instantaneous value data at adjacent two points in voltage instantaneous value data at continuous at least four points obtained by sampling an alternating voltage set as a measurement target at a sampling frequency twice or more as high as a frequency of the alternating voltage; and
a frequency calculating unit configured to calculate a frequency of the alternating voltage using the sampling frequency and the frequency coefficient.

2. The alternating-current electrical quantity measuring apparatus according to claim 1, further comprising:
a gauge-differential-voltage calculating unit configured to calculate, as a gauge differential voltage, a value obtained by averaging differences between a square value of a differential voltage instantaneous value at intermediate time and a product of differential voltage instantaneous values at times other than the intermediate time among differential voltage instantaneous value data at three points each representing an inter-point distance between voltage instantaneous value data at adjacent two points in voltage instantaneous value data at continuous at least four points including the differential voltage instantaneous value data at the three points used in calculating the frequency coefficient; and
a voltage-amplitude calculating unit configured to calculate amplitude of the alternating voltage using the frequency coefficient and the gauge differential voltage.

3. The alternating-current electrical quantity measuring apparatus according to claim 1, further comprising a direct-current offset calculating unit configured to calculate a direct-current offset included in the alternating voltage using the frequency coefficient and voltage instantaneous value data at predetermined three points among the voltage instantaneous value data at the four points used in calculating the frequency coefficient.

4. The alternating-current electrical quantity measuring apparatus according to claim 1, further comprising:
a gauge-differential-voltage calculating unit configured to calculate, as a gauge differential voltage, a value obtained by averaging a difference between a square value of a differential voltage instantaneous value at intermediate time and differential voltage instantaneous value products at times other than the intermediate time among differential voltage instantaneous value data at three points each representing an inter-point distance between voltage instantaneous value data at adjacent two points in voltage instantaneous value data at continuous at least four points including the differential voltage instantaneous value data at the three points used in calculating the frequency coefficient; and
a direct-current offset calculating unit configured to calculate a direct-current offset included in the alternating voltage using the frequency coefficient calculated by the frequency-coefficient calculating unit and the gauge differential voltage calculated by the gauge-differential-voltage calculating unit and voltage instantaneous value data at predetermined three points among the voltage instantaneous value data at the four points used in calculating the frequency coefficient.

5. The alternating-current electrical quantity measuring apparatus according to claim 4, further comprising:
a gauge-voltage calculating unit configured to calculate, as a gauge voltage, a value obtained by averaging differences between a square value of a component obtained by subtracting the direct-current offset from a voltage instantaneous value at intermediate time and a product of components respectively obtained by subtracting the direct-current offset from two voltage instantaneous values at times other than the intermediate time among the voltage instantaneous value data at the three points used in calculating the frequency coefficient; and
a voltage-amplitude calculating unit configured to calculate amplitude of the alternating voltage using the frequency coefficient and the gauge voltage.

6. The alternating-current electrical quantity measuring apparatus according to claim 1, further comprising:
a gauge-voltage calculating unit configured to calculate, as a gauge voltage, a value obtained by averaging differences between a square value of a voltage instantaneous value at intermediate time and a product of voltage instantaneous values at times other than the intermediate time among the voltage instantaneous value data at the three points used in calculating the frequency coefficient;
a gauge-differential-voltage calculating unit configured to calculate, as a gauge differential voltage, a value obtained by averaging a difference between a square value of a differential voltage instantaneous value at intermediate time and a product of differential voltage instantaneous values at times other than the intermediate time among differential voltage instantaneous value data at three points each representing an inter-point distance between voltage instantaneous value data at adjacent two points in voltage instantaneous value data at continuous at least four points including the differential voltage instantaneous value data at the three points used in calculating the frequency coefficient; and
a symmetry-breaking discriminating unit configured to determine breaking of symmetry of the alternating voltage waveform using a determination index based on a deviation between a first rotation phase angle calculated using the frequency coefficient and a second rotation phase angle calculated using the gauge voltage and the gauge differential voltage.

7. The alternating-current electrical quantity measuring apparatus according to claim 1, further comprising:
a gauge-voltage calculating unit configured to calculate, as a gauge voltage, a value obtained by averaging a difference between a square value of a voltage instantaneous value at intermediate time and a product of voltage instantaneous values at times other than the intermediate time among the voltage instantaneous value data at the three points used in calculating the frequency coefficient;
a gauge-differential-voltage calculating unit configured to calculate, as a gauge differential voltage, a value obtained by averaging a difference between a square value of a differential voltage instantaneous value at intermediate time and a product of differential voltage instantaneous values at times other than the intermediate time among differential voltage instantaneous value data at three points each representing an inter-point distance between voltage instantaneous value data at adjacent two points in voltage instantaneous value data at continuous at least four points including the differential voltage instantaneous value data at the three points used in calculating the frequency coefficient; and
a symmetry-breaking discriminating unit configured to determine breaking of symmetry of the alternating voltage waveform using a determination index based on a deviation between a sine value of a half rotation phase angle that can be calculated using the frequency coefficient and a sine value of a half rotation phase angle that can be calculated using the gauge voltage and the gauge differential voltage.

8. The alternating-current electrical quantity measuring apparatus according to claim 1, further comprising:
a gauge-voltage calculating unit configured to calculate, as a gauge voltage, a value obtained by averaging a difference between a square value of a voltage instantaneous value at intermediate time and a product of voltage instantaneous values at times other than the intermediate time among the voltage instantaneous value data at the three points used in calculating the frequency coefficient;
a gauge-differential-voltage calculating unit configured to calculate, as a gauge differential voltage, a value obtained by averaging a difference between a square value of a differential voltage instantaneous value at intermediate time and a product of differential voltage instantaneous values at times other than the intermediate time among differential voltage instantaneous value data at three points each representing an inter-point distance between voltage instantaneous value data at adjacent two points in voltage instantaneous value data at continuous at least four points including the differential voltage instantaneous value data at the three points used in calculating the frequency coefficient; and
a symmetry-breaking discriminating unit configured to determine breaking of symmetry of the alternating voltage waveform using a determination index based on a deviation between a first voltage amplitude calculated using the frequency coefficient and the gauge voltage and a second voltage amplitude calculated using the frequency coefficient and the gauge differential voltage.

9. The alternating-current electrical quantity measuring apparatus according to claim 1, further comprising:
a gauge-voltage calculating unit configured to calculate, as a gauge voltage, a value obtained by averaging a difference between a square value of a voltage instantaneous value at intermediate time and a product of voltage instantaneous values at times other than the intermediate time among the voltage instantaneous value data at the three points used in calculating the frequency coefficient;
a gauge-differential-voltage calculating unit configured to calculate, as a gauge differential voltage, a value obtained by averaging a difference between a square value of a differential voltage instantaneous value at intermediate time and a product of differential voltage instantaneous values at times other than the intermediate time among differential voltage instantaneous value data at three points each representing an inter-point distance between voltage instantaneous value data at adjacent two points in voltage instantaneous value data at continuous at least four points including the differential voltage instantaneous value data at the three points used in calculating the frequency coefficient;
a gauge-active-synchronized-phasor calculating unit configured to calculate, as a gauge active synchronized phasor, a value calculated by a predetermined multiply-subtract operation using voltage instantaneous value data at two points measured at late times among the voltage instantaneous value data at the three points used in calculating the frequency coefficient, a first fixed unit vector present on a complex plane same as a complex plane of an alternating voltage set as a measurement target, and a second fixed unit vector delayed by a rotation phase angle determined based on the frequency coefficient with respect to the first fixed unit vector;
a gauge-reactive-synchronized-phasor calculating unit configured to calculate, as a gauge reactive synchronized phasor, a value calculated by a predetermined multiply-subtract operation using voltage instantaneous value data at two points measured at early times among the voltage instantaneous value data at the three points used in calculating the active synchronized phasor and the first and second fixed unit vectors used in calculating the gauge active synchronized phasor; and
a symmetry-breaking discriminating unit configured to determine breaking of symmetry of the alternating voltage waveform using a determination index based on a deviation between a first voltage amplitude calculated using the frequency coefficient, the gauge active synchronized phasor, and the gauge reactive synchronized phasor and a second voltage amplitude calculated using the frequency coefficient and the gauge differential voltage.

10. The alternating-current electrical quantity measuring apparatus according to claim 1, further comprising:
a gauge-voltage calculating unit configured to calculate, as a gauge voltage, a value obtained by averaging a difference between a square value of a voltage instantaneous value at intermediate time and a product of voltage instantaneous values at times other than the intermediate time among the voltage instantaneous value data at the three points used in calculating the frequency coefficient;
a gauge-differential-voltage calculating unit configured to calculate, as a gauge differential voltage, a value obtained by averaging a difference between a square value of a differential voltage instantaneous value at intermediate time and a product of differential voltage instantaneous values at times other than the intermediate time among differential voltage instantaneous value data at three points each representing an inter-point distance between voltage instantaneous value data at adjacent two points in voltage instantaneous value data at continuous at least four points including the differential voltage instantaneous value data at the three points used in calculating the frequency coefficient;
a gauge-differential-active-synchronized-phasor calculating unit configured to calculate, as a gauge differential active synchronized phasor, a value calculated by a predetermined multiply-subtract operation using differential voltage instantaneous value data at two points measured at late times among the differential voltage instantaneous value data at the three points used in calculating the frequency coefficient, a first fixed unit vector present on a complex plane same as a complex plane of an alternating voltage set as a measurement target, and a second fixed unit vector delayed by a rotation phase angle determined based on the frequency coefficient with respect to the first fixed unit vector;
a gauge-differential-reactive-synchronized-phasor calculating unit configured to calculate, as a gauge differential reactive synchronized phasor, a value calculated by a predetermined multiply-subtract operation using differential voltage instantaneous value data at two points measured at early times among the differential voltage instantaneous value data at the three points used in calculating the differential active synchronized phasor and the first and second fixed unit vectors used in calculating the gauge differential active synchronized phasor; and
a symmetry-breaking discriminating unit configured to determine breaking of symmetry of the alternating voltage waveform using a determination index based on a deviation between a first voltage amplitude calculated using the frequency coefficient, the gauge differential active synchronized phasor, and the gauge differential reactive synchronized phasor and a second voltage amplitude calculated using the frequency coefficient and the gauge differential voltage.

11. The alternating-current electrical quantity measuring apparatus according to claim 1, further comprising:
a gauge-voltage calculating unit configured to calculate, as a gauge voltage, a value obtained by averaging a difference between a square value of a voltage instantaneous value at intermediate time and a product of voltage instantaneous values at times other than the intermediate time among the voltage instantaneous value data at the three points used in calculating the frequency coefficient;
a gauge-differential-voltage calculating unit configured to calculate, as a gauge differential voltage, a value obtained by averaging a difference between a square value of a differential voltage instantaneous value at intermediate time and a product of differential voltage instantaneous values at times other than the intermediate time among differential voltage instantaneous value data at three points each representing an inter-point distance between voltage instantaneous value data at adjacent two points in voltage instantaneous value data at continuous at least four points including the differential voltage instantaneous value data at the three points used in calculating the frequency coefficient;
a gauge-active-synchronized-phasor calculating unit configured to calculate, as a gauge active synchronized phasor, a value calculated by a predetermined multiply-subtract operation using voltage instantaneous value data at two points measured at late times among the voltage instantaneous value data at the three points used in calculating the frequency coefficient, a first fixed unit vector present on a complex plane same as a complex plane of an alternating voltage set as a measurement target, and a second fixed unit vector delayed by a rotation phase angle determined based on the frequency coefficient with respect to the first fixed unit vector;
a gauge-reactive-synchronized-phasor calculating unit configured to calculate, as a gauge reactive synchronized phasor, a value calculated by a predetermined multiply-subtract operation using voltage instantaneous value data at two points measured at early times among the voltage instantaneous value data at the three points used in calculating the active synchronized phasor and the first and second fixed unit vectors used in calculating the gauge active synchronized phasor;
a gauge-differential-active-synchronized-phasor calculating unit configured to calculate, as a gauge differential active synchronized phasor, a value calculated by a predetermined multiply-subtract operation using differential voltage instantaneous value data at two points measured at late times among the differential voltage instantaneous value data at the three points used in calculating the gauge active synchronized phasor and the first and second fixed unit vectors used in calculating the gauge active synchronized phasor;
a gauge-differential-reactive-synchronized-phasor calculating unit configured to calculate, as a gauge differential reactive synchronized phasor, a value calculated by a predetermined multiply-subtract operation using differential voltage instantaneous value data at two points measured at early times among the differential voltage instantaneous value data at the three points used in calculating the differential active synchronized phasor and the first and second fixed unit vectors used in calculating the gauge differential active synchronized phasor; and
a symmetry-breaking discriminating unit configured to determine breaking of symmetry of the alternating voltage waveform using a determination index based on a deviation between a first voltage amplitude calculated using the frequency coefficient, the gauge active synchronized phasor, and the gauge reactive synchronized phasor and a second voltage amplitude calculated using the frequency coefficient, the gauge differential active synchronized phasor, and the gauge differential reactive synchronized phasor.

12. The alternating-current electrical quantity measuring apparatus according to claim 1, further comprising:
a gauge-voltage calculating unit configured to calculate, as a gauge voltage, a value obtained by averaging a difference between a square value of a voltage instantaneous value at intermediate time and a product of voltage instantaneous value at times other than the intermediate time among the voltage instantaneous value data at the three points used in calculating the frequency coefficient;
a gauge-current calculating unit configured to calculate, as a gauge current, a value obtained by averaging a difference between a square value of a current instantaneous value at intermediate time and a product of current instantaneous values at times other than the intermediate time among current instantaneous value data at three points sampled at same time as the voltage instantaneous value data at the three points used in calculating the frequency coefficient;
a gauge-active-power calculating unit configured to calculate, as gauge active power, a value calculated by a predetermined multiply-subtract operation using voltage instantaneous value data at two points measured at early times among the voltage instantaneous value data at the three points used in calculating the frequency coefficient and differential current instantaneous value data at two points measured at late times among current instantaneous value data at three points sampled at same time as the voltage instantaneous values at the three points;
a gauge-reactive-power calculating unit configured to calculate, as gauge reactive power, a value calculated by a predetermined multiply-subtract operation using voltage instantaneous value data at two points measured at late times among the voltage instantaneous value data at the three points used in calculating the gauge active power and differential current instantaneous value data at two points measured at late times among current instantaneous value data at three points sampled at same time as the voltage instantaneous values at the three points; and
a symmetry-breaking discriminating unit configured to determine breaking of symmetry of the alternating voltage waveform using a determination index based on a deviation between a first calculated value calculated using the frequency coefficient, the gauge voltage, the gauge current, the gauge active power, and the gauge reactive power and a second calculated value calculated using the frequency coefficient, the gauge active power, and the gauge reactive power.

13. The alternating-current electrical quantity measuring apparatus according to claim 1, further comprising:
a gauge-differential-voltage calculating unit configured to calculate, as a gauge differential voltage, a value obtained by averaging a difference between a square value of a differential voltage instantaneous value at intermediate time and a product of differential voltage instantaneous values at times other than the intermediate time among differential voltage instantaneous value data at three points each representing an inter-point distance between voltage instantaneous value data at adjacent two points in voltage instantaneous value data at continuous at least four points including the differential voltage instantaneous value data at the three points used in calculating the frequency coefficient;
a gauge-differential-current calculating unit configured to calculate, as a gauge differential current, a value obtained by averaging a difference between a square value of a differential current instantaneous value at intermediate time and a product of differential current instantaneous values at times other than the intermediate time among differential current instantaneous value data at three points each representing an inter-point distance between current instantaneous value data at adjacent two points in current instantaneous value data at continuous at four points sampled at same time as the voltage instantaneous value data at the four points used in calculating the frequency coefficient;
a gauge-differential-active-power calculating unit configured to calculate, as gauge differential active power, a value calculated by a predetermined multiply-subtract operation using differential voltage instantaneous value data at two points measured at early times among the differential voltage instantaneous value data at the three points used in calculating the gauge differential voltage and differential current instantaneous value data at two points measured at late times among the current instantaneous value data at the three points used in calculating the gauge differential current;
a gauge-differential-reactive-power calculating unit configured to calculate, as gauge differential reactive power, a value calculated by a predetermined multiply-subtract operation using differential voltage instantaneous value data at two points measured at late times among the differential voltage instantaneous value data at the three points used in calculating the gauge differential active power and differential current instantaneous value data at two points measured at late times among the differential current instantaneous value data at the three points used in calculating the gauge differential active power; and
a symmetry-breaking discriminating unit configured to determine breaking of symmetry of the alternating voltage waveform using a determination index based on a deviation between a first calculated value calculated using the frequency coefficient, the gauge differential voltage, the gauge differential current, the gauge differential active power, and the gauge differential reactive power and a second calculated value calculated using the frequency coefficient, the gauge differential active power, and the gauge differential reactive power.

14-17. (canceled)

18. An alternating-current electrical quantity measuring apparatus comprising a frequency-coefficient calculating unit configured to calculate, as a frequency coefficient, a value obtained by normalizing, with a differential voltage instantaneous value at intermediate time, a mean value of sums of differential voltage instantaneous values at times other than the intermediate time among differential voltage instantaneous value data at three points each representing an inter-point distance between voltage instantaneous value data at adjacent two points in voltage instantaneous value data at continuous at least four points obtained by sampling an alternating voltage set as a measurement target at a sampling frequency twice or more as high as a frequency of the alternating voltage.
